(19) United States
(12) Patent Application Publication
(10) Pub. No.: US 2024/0164144 A1
(43) Pub. Date: May 16, 2024

(54) DISPLAY SUBSTRATE AND MANUFACTURING METHOD THEREFOR, AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Wei ZHANG, Beijing (CN); Liang SONG, Beijing (CN); Zhiming REN, Beijing (CN); Chunfang FAN, Beijing (CN); Xiaoliang GUO, Beijing (CN); Donghua JIANG, Beijing (CN); Wuyang ZHAO, Beijing (CN); Weiyun HUANG, Beijing (CN); Zhen WANG, Beijing (CN); Zhongfei DONG, Beijing (CN); Hongguang YUAN, Beijing (CN); Pengyu LIAO, Beijing (CN); Li XIONG, Beijing (CN)

(21) Appl. No.: 18/279,631

(22) PCT Filed: Oct. 10, 2022
(86) PCT No.: PCT/CN2022/124301

§ 371 Date: Sep. 1, 2023

(30) Foreign Application Priority Data
Nov. 30, 2021 (CN) 202111444420.5

(51) Int. Cl. H10K 59/122; H10K 59/12

(52) U.S. Cl. CPC H10K 59/122; H10K 59/1201

(57) ABSTRACT

A display substrate, a manufacturing method therefor, and a display device are provided. The display substrate includes a base substrate, sub-pixels and an isolation portion, and each sub-pixel includes a light-emitting function layer. The isolation portion includes a first sub-isolation portion and a second sub-isolation portion. The first sub-isolation portion is between the second sub-isolation portion and the base substrate. The second sub-isolation portion includes a protrusion protruding relative to an edge of the first sub-isolation portion, the second sub-isolation portion facing one of adjacent sub-pixels is different in shape from the second sub-isolation portion facing the other one; or, a slope angle between a side surface of the first sub-isolation portion or the second sub-isolation portion facing one sub-pixel and a plane parallel to the base substrate is 60° to 120°. At least one film of the light-emitting function layer is disconnected at the isolation portion.

### CROSS-REFERENCE TO RELATED APPLICATION

The present application claims priority to Chinese patent application No. 202111444420.5, filed on Nov. 30, 2021, the disclosure of which is incorporated herein by reference in its entirety as part of the present application.

### TECHNICAL FIELD

At least one embodiment of the present disclosure relates to a display substrate, a manufacturing method therefor and a display device.

### BACKGROUND

With the development of display technology, users have higher and higher requirements for the performance of display devices. Isolating some material layers used for illumination between adjacent sub-pixels can reduce signal crosstalk, thus meeting the performance requirements of high brightness and low power consumption of display devices as much as possible.

### SUMMARY

At least one embodiment of the present disclosure provides a display substrate and a display device.

At least one embodiment of the present disclosure provides a display substrate, including: a base substrate, at least including a first display region; a plurality of sub-pixels, located in the first display region of the base substrate, each sub-pixel in at least part of the plurality of sub-pixels including a light-emitting element, the light-emitting element including a light-emitting functional layer and a first electrode and a second electrode located at both sides of the light-emitting functional layer along a direction perpendicular to the base substrate, the first electrode being located between the light-emitting functional layer and the base substrate, and the light-emitting functional layer including a plurality of film layers. The display substrate further includes an isolation portion, the isolation portion includes a first sub-isolation portion and a second sub-isolation portion which are stacked, the first sub-isolation portion is located between the second sub-isolation portion and the base substrate, a material of the first sub-isolation portion includes an inorganic material, and a material of the second sub-isolation portion includes an organic material; the second sub-isolation portion includes a protrusion protruding relative to an edge of the first sub-isolation portion, the protrusion is located between adjacent sub-pixels, at least a part of the second sub-isolation portion facing one of the adjacent sub-pixels is different in shape from at least a part of the second sub-pixel facing the other of the adjacent sub-pixels; or, a slope angle between at least part of a side surface of the isolation portion facing one of the adjacent sub-pixels and a plane parallel to a contact surface of the first sub-isolation portion and the second sub-isolation portion is greater than 60 degrees and less than 120 degrees, and/or a slope angle between at least part of a side surface of the isolation portion facing one of the adjacent sub-pixels and the plane parallel to the contact surface of the first sub-isolation portion and the second sub-isolation portion is greater than 60 degrees and less than 120 degrees; at least one film layer among the plurality of film layers is disconnected at the isolation portion.

For example, according to an embodiment of the present disclosure, at least one film layer among the plurality of film layers is disconnected at an edge of the isolation portion facing one of the adjacent sub-pixels, and is not disconnected at an edge of the isolation portion facing the other of the adjacent sub-pixels.

For example, according to an embodiment of the present disclosure, at least the part of the second sub-isolation portion facing one of the adjacent sub-pixels has a different slope angle from at least the part of the second sub-isolation portion facing the other of the adjacent sub-pixels; and/or, at least the part of the second sub-isolation portion facing one of the adjacent sub-pixels has the protrusion, and at least the part of the second sub-isolation portion facing the other of the adjacent sub-pixels does not have the protrusion.

For example, according to an embodiment of the present disclosure, at least in a part of the isolation portion where the protrusion is located, an orthographic projection of the first sub-isolation portion on the base substrate completely falls within an orthographic projection of the second sub-isolation portion on the base substrate.

For example, according to an embodiment of the present disclosure, at least one group of isolation portions arranged at interval are disposed between adjacent sub-pixels, each group of isolation portions includes two isolation portions, the two isolation portions are arranged along an arrangement direction of the adjacent sub-pixels, and the protrusions of the two isolation portions are close to each other.

For example, according to an embodiment of the present disclosure, in the arrangement direction of the adjacent sub-pixels, a distance between two first sub-isolation portions in the two isolation portions is greater than a distance between two second sub-isolation portions in the two isolation portions.

For example, according to an embodiment of the present disclosure, in the direction perpendicular to the base substrate, a maximum thickness of the second sub-isolation portion is greater than a maximum thickness of the first sub-isolation portion.

For example, according to an embodiment of the present disclosure, in the direction perpendicular to the base substrate, a thickness of the protrusion is less than a thickness of a part of the second sub-isolation portion other than the protrusion.

For example, according to an embodiment of the present disclosure, a surface of the protrusion away from the base substrate includes a curved surface, the curved surface is bent towards the first sub-isolation portion, and a slope angle of the curved surface of the protrusion is in a range of 15-70 degrees.

For example, according to an embodiment of the present disclosure, the first sub-isolation portion includes at least two film layers, the protrusion protrudes relative to an edge of one film layer, closest to the second sub-isolation portion, among the at least two film layers, the at least two film layers include two film layers with different patterns, and/or the at least two film layers include two film layers with different thicknesses.

For example, according to an embodiment of the present disclosure, the display substrate further includes: a pixel defining pattern, at least the pixel defining pattern located in the first display region includes a plurality of first openings, one sub-pixel corresponds to at least one first opening, and the light emitting element of the sub-pixel is at least partially located in the at least one first opening corresponding to the sub-pixel, and the at least one first opening is configured to expose the first electrode. At least part of a pixel defining portion of the pixel defining pattern is also used as the second sub-isolation portion.

For example, according to an embodiment of the present disclosure, the first electrode includes at least one electrode layer, the first sub-isolation portion includes at least one film layer, one film layer of the first sub-isolation portion is arranged in the same layer as one electrode layer of the first electrode, and the pixel defining portion is configured to separate the first sub-isolation portion from the first electrode.

For example, according to an embodiment of the present disclosure, a material of a certain electrode layer, which is arranged in the same layer as a certain film layer of the first sub-isolation portion, of the first electrode is the same as a material of the certain film layer.

For example, according to an embodiment of the present disclosure, a part of the first electrode covered by the second sub-isolation portion includes the first sub-isolation portion.

For example, according to an embodiment of the present disclosure, in each sub-pixel, the light-emitting functional layer includes a first light-emitting layer, a charge generation layer and a second light-emitting layer which are stacked, the charge generation layer is located between the first light-emitting layer and the second light-emitting layer, and the charge generation layer is disconnected at the isolation portion.

For example, according to an embodiment of the present disclosure, a film layer located at one side of the charge generation layer facing the base substrate and in the light-emitting functional layer is disconnected at the isolation portion.

For example, according to an embodiment of the present disclosure, a color of light emitted by the first light-emitting layer is the same as a color of light emitted by the second light-emitting layer.

For example, according to an embodiment of the present disclosure, the light-emitting functional layer includes a light-emitting layer, and an area of an orthographic projection of at least one disconnected film layer in the light-emitting functional layer on the base substrate is greater than an area of an orthographic projection of the light-emitting layer on the base substrate.

For example, according to an embodiment of the present disclosure, the light-emitting functional layer includes at least one light-emitting layer, and at least one light-emitting layer and at least one other film layer are included in film layers of the light-emitting functional layer disconnected at the isolation portion; an area of an orthographic projection of the at least one other film layer which is disconnected on the base substrate is greater than an area of an orthographic projection of the at least one light-emitting layer which is disconnected on the base substrate; or, an area of a part, of the at least one other film layer which is disconnected, covering the isolation portion is greater than an area of a part, of the at least one light-emitting layer which is disconnected, covering the isolation portion.

For example, according to an embodiment of the present disclosure, the second electrode and at least one film layer among the plurality of film layers included in the light-emitting functional layer overlap in projection on the base substrate with the isolation portion.

For example, according to an embodiment of the present disclosure, at least one film layer among the plurality of film layers included in the light emitting functional layer at least partially covers a part of a side surface of the isolation portion.

For example, according to an embodiment of the present disclosure, the base substrate further includes a second display region, and the first display region surrounds at least part of the second display region.

For example, according to an embodiment of the present disclosure, a ratio of a thickness of the first sub-isolation portion to a thickness of the light-emitting functional layer is in a range of 0.7-1.5.

For example, according to an embodiment of the present disclosure, the second electrode is continuous at the protrusion.

For example, according to an embodiment of the present disclosure, the second electrode is disconnected at the protrusion.

For example, according to an embodiment of the present disclosure, a spacing structure is arranged between two protrusions which are close to each other, the spacing structure is spaced apart from the protrusions, and a material of the spacing structure is the same as a material of the second sub-isolation portion.

For example, according to an embodiment of the present disclosure, there is a gap between the first sub-isolation portion and a film layer disconnected at the position between the two isolation portions, and an orthographic projection of the disconnected film layer on the base substrate overlaps or meets an orthographic projection of the second sub-isolation portion on the base substrate.

For example, according to an embodiment of the present disclosure, the pixel defining pattern includes a pixel defining portion located between the first opening and a second opening which are arranged adjacent to each other, one end of the pixel defining portion is configured to form the first opening, the other end of the pixel defining portion includes the second sub-isolation portion, and an included angle between a sidewall of the pixel defining portion formed as a sidewall of the first opening and a plane parallel to the base substrate is different from an included angle between a sidewall of the second sub-isolation portion and the plane parallel to the base substrate.

An embodiment of the present disclosure provides a display device, which includes the display substrate as mentioned above.

An embodiment of the present disclosure provides a manufacturing method of a display substrate, which includes: forming a plurality of sub-pixels on a base substrate, wherein forming the plurality of sub-pixels includes sequentially forming a first electrode, a light-emitting functional layer and a second electrode which are stacked in a direction perpendicular to the base substrate; forming an inorganic layer pattern by patterning on the base substrate; forming an organic layer on the inorganic layer pattern, and patterning the organic layer to form an opening pattern; etching the inorganic layer pattern to form a first sub-isolation portion, wherein an edge of the opening pattern includes a second sub-isolation portion stacked with the first sub-isolation portion, an edge of the first sub-isolation portion extends outward relative to an edge of the second sub-isolation portion so that the second sub-isolation portion includes a protrusion protruding relative to the edge of the first sub-isolation portion, and the protrusion is located between adjacent sub-pixels, or a slope angle between at least part of a side surface of the first sub-isolation portion and a plane parallel to a contact surface of the first sub-isolation portion and the second sub-isolation portion is greater than 60 degrees and less than 120 degrees, and/or a slope angle between at least part of a side surface of the second sub-isolation portion and the plane parallel to the contact surface of the first sub-isolation portion and the second sub-isolation portion is greater than 60 degrees and less than 120 degrees. The light-emitting functional layer is formed after the first sub-isolation portion is formed, the light-emitting functional layer includes a plurality of film layers, and at least one film layer among the plurality of film layers is disconnected at the isolation portion.

For example, according to an embodiment of the present disclosure, the inorganic layer pattern is located between adjacent sub-pixels, and the opening pattern which is formed exposes a part of the inorganic layer pattern, or an edge of the opening pattern which is formed is flush with an edge of the inorganic layer pattern; etching the inorganic layer pattern so that an edge of a retained part of the inorganic layer pattern extends outward relative to an edge of the opening pattern, the retained part of the inorganic layer being the first sub-isolation portion.

For example, according to an embodiment of the present disclosure, the inorganic layer pattern includes the first electrode, and the opening pattern is located between adjacent sub-pixels; etching the inorganic layer pattern includes: etching a part of the first electrode close to an edge of the opening pattern so that an edge of the first electrode extends outward relative to the edge of the opening pattern.

### BRIEF DESCRIPTION OF DRAWINGS

In order to clearly illustrate the technical solution of the embodiments of the invention, the drawings of the embodiments will be briefly described in the following; it is obvious that the described drawings are only related to some embodiments of the present disclosure and thus are not limitative of the present disclosure.

FIG. 1A is a partial cross-sectional structural view of a display substrate provided by an example of an embodiment of the present disclosure;

FIG. 1B is a partial cross-sectional structural view of a display substrate provided by another example of an embodiment of the present disclosure;

FIG. 1C is a planar view of a display substrate provided by an embodiment of the present disclosure;

FIG. 2 is a partial cross-sectional structural view of a display substrate provided by another example of an embodiment of the present disclosure;

FIG. 3 is a partial cross-sectional structural view of a display substrate provided by another example of an embodiment of the present disclosure;

FIG. 4A is a schematic diagram of a display substrate before the formation of the structure shown in FIG. 2;

FIG. 4B is a schematic diagram of the display substrate after the formation of the structure shown in FIG. 2;

FIGS. 5A-5D are flow charts of a manufacturing method of a display substrate before the formation of the structure shown in FIG. 3;

FIG. 6 is a partial cross-sectional structural view of a display substrate provided by another example of an embodiment of the present disclosure;

FIG. 7 is a schematic diagram showing a light-emitting functional layer and multi-layer film layers at a side of the light-emitting functional layer away from a base substrate on the basis of the display substrate shown in FIG. 6;

FIG. 8 is a partial cross-sectional structural view of a display substrate provided by another example of an embodiment of the present disclosure;

FIGS. 9A-9B are flow charts of a manufacturing method of a display substrate before the formation of the structure shown in FIG. 8;

FIGS. 10A-10E are planar structural views of a display substrate provided by an embodiment of the present disclosure;

FIG. 11A is a partial cross-sectional structural view of a display substrate provided by an example of another embodiment of the present disclosure;

FIG. 11B is a partial cross-sectional structural view of a display substrate provided by another example of another embodiment of the present disclosure;

FIG. 12 is a partial cross-sectional structural view of a display substrate provided by an example of another embodiment of the present disclosure;

FIGS. 13A-13F are flow charts of a manufacturing method of a display substrate before the formation of the structure shown in FIG. 11A;

FIG. 14 is a partial cross-sectional structural view of a display substrate provided by an example of another embodiment of the present disclosure;

FIGS. 15A-15B are flow charts of a manufacturing method of a display substrate before the formation of the structure shown in FIG. 14;

FIG. 16 is a partial cross-sectional structural view of a display substrate provided by an example of another embodiment of the present disclosure;

FIGS. 17A-17B are flow charts of a manufacturing method of a display substrate before the formation of the structure shown in FIG. 16;

FIG. 18 is a partial cross-sectional structural view of a display substrate provided by an example of another embodiment of the present disclosure;

FIGS. 19A-19B are flow charts of a manufacturing method of a display substrate before the formation of the structure shown in FIG. 18;

FIG. 20 is a partial cross-sectional structural view of a display substrate provided by an example of another embodiment of the present disclosure;

FIGS. 21A-21B are flow charts of a manufacturing method of a display substrate before the formation of the structure shown in FIG. 20;

FIGS. 22A-22C are flow charts of another manufacturing method of a display substrate before the formation of the structure shown in FIG. 20;

FIG. 23 is a partial cross-sectional structural view of a display substrate provided by an example of another embodiment of the present disclosure;

FIG. 24 is a flow chart of a manufacturing method of a display substrate before the formation of the structure shown in FIG. 23;

FIG. 25 is a partial cross-sectional structural view of a display substrate provided by an example of another embodiment of the present disclosure;

FIGS. 26A-26B are flow charts of a manufacturing method of a display substrate before the formation of the structure shown in FIG. 25;

FIG. 27 is a partial cross-sectional structural view of a display substrate provided by an example of another embodiment of the present disclosure;

FIG. 28A is a partial cross-sectional structural view of a display substrate provided by an example of another embodiment of the present disclosure;

FIG. 28B is a partial cross-sectional structural view of a display substrate provided by another example of another embodiment of the present disclosure;

FIGS. 29A-29D are flow charts of a manufacturing method of a display substrate before the formation of the structure shown in FIG. 27;

FIGS. 30A-30C are flow charts of a manufacturing method before forming the display substrate shown in FIG. 28A;

FIG. 31 is a partial cross-sectional structural view of a display substrate provided by an example of another embodiment of the present disclosure;

FIG. 32 is a partial cross-sectional structural view of a display substrate provided by an example of another embodiment of the present disclosure;

FIGS. 33A-33B are flow charts of a manufacturing method of a display substrate before the formation of the structure shown in FIG. 31;

FIGS. 34A-34B are flow charts of a manufacturing method of a display substrate before the formation of the structure shown in FIG. 32;

FIG. 35 is a structural view of another display substrate provided by an embodiment of the present disclosure;

FIG. 36 is a structural view of another display substrate provided by an embodiment of the present disclosure;

FIG. 37 is a structural view of another display substrate provided by an embodiment of the present disclosure;

FIG. 38 is a structural view of another display substrate provided by an embodiment of the present disclosure;

FIGS. 39A-39C are flow charts of another manufacturing method of a display substrate provided by an embodiment of the present disclosure;

FIG. 40 is a structural view of another display substrate provided by an embodiment of the present disclosure; and

FIGS. 41A-41C are flow charts of another manufacturing method of a display substrate provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

In the embodiment of the present disclosure, the features, “parallel to,” “perpendicular to,” “identical to,” etc., all include the features “parallel to,” “perpendicular to,” “identical to,” etc., in the strict sense, as well as the cases containing certain errors, such as “approximately parallel to,” “approximately perpendicular to,” “approximately identical to,” etc. Considering the measurement and the errors related to the measurement of a specific quantity (e.g., the limitation of the measurement system), they are within an acceptable deviation range for the specific quantity determined by those skilled in the art. For example, the term “approximately” can mean within one or more standard deviations, or within 10% or 5% deviation of the stated value. When the quantity of a component is not specified in the following description of the embodiments of the present disclosure, it means that the number of the component can be one or more, or can be understood as at least one. The phrase “at least one” means one or more, and the phrase “plurality of” means at least two. The feature “same layer” in the embodiment of the present disclosure refers to the relationship between multiple film layers formed by the same material after the same step (e.g., one-step patterning process). The feature “same layer” herein does not always mean that the thicknesses of multiple film layers are the same or the heights of multiple film layers in cross section are the same.

In research, the inventor(s) of the present application have noticed that: the light-emitting functional layer can include multi-layer light-emitting layers which are stacked, a charge generation layer (CGL) is disposed between at least two layers of the multi-layer light-emitting layers, and the charge generation layer has a relatively high conductivity; in the case where the charge generation layer is a whole-surface film layer, the charge generation layers of two adjacent organic light-emitting elements are a continuous film layer, which easily leads to crosstalk between adjacent sub-pixels.

At least one embodiment of the present disclosure provides a display substrate, a manufacturing method therefor, and a display device. The display substrate includes: a base substrate, at least including a first display region; a plurality of sub-pixels located in a first display region of the base substrate, each sub-pixel in at least art of the plurality of sub-pixels including a light-emitting element, the light-emitting element including a light-emitting functional layer and a first electrode and a second electrode located at both sides of the light-emitting functional layer along a direction perpendicular to the base substrate, the first electrode being located between the light-emitting functional layer and the base substrate, and the light-emitting functional layer including a plurality of film layers. The display substrate further includes an isolation portion, the isolation portion includes a first sub-isolation portion and a second sub-isolation portion which are stacked, the first sub-isolation portion is located between the second sub-isolation portion and the base substrate, a material of the first sub-isolation portion includes an inorganic material, and a material of the second sub-isolation portion includes an organic material; the second sub-isolation portion includes a protrusion protruding relative to an edge of the first sub-isolation portion, the protrusion is located between adjacent sub-pixels, at least a part of the second sub-isolation portion facing one of the adjacent sub-pixels is different in shape from at least a part of the second sub-pixel facing the other of the adjacent sub-pixels; or, a slope angle between at least part of a side surface of the isolation portion facing one of the adjacent sub-pixels and a plane parallel to a contact surface of the first sub-isolation portion and the second sub-isolation portion is greater than 60 degrees and less than 120 degrees, and/or a slope angle between at least part of a side surface of the isolation portion facing one of the adjacent sub-pixels and the plane parallel to the contact surface of the first sub-isolation portion and the second sub-isolation portion is greater than 60 degrees and less than 120 degrees; at least one film layer among the plurality of film layers is disconnected at the isolation portion. In the embodiment of the present disclosure, by arranging the isolation portion between adjacent sub-pixels in the display substrate, at least one film layer among the plurality of film layers of the light-emitting functional layer can be disconnected at the isolation portion, which is helpful to reduce the probability of crosstalk between adjacent sub-pixels.

The display substrate, the manufacturing method therefor and the display device provided by the embodiments of the present disclosure are described below with reference to the accompanying drawings.

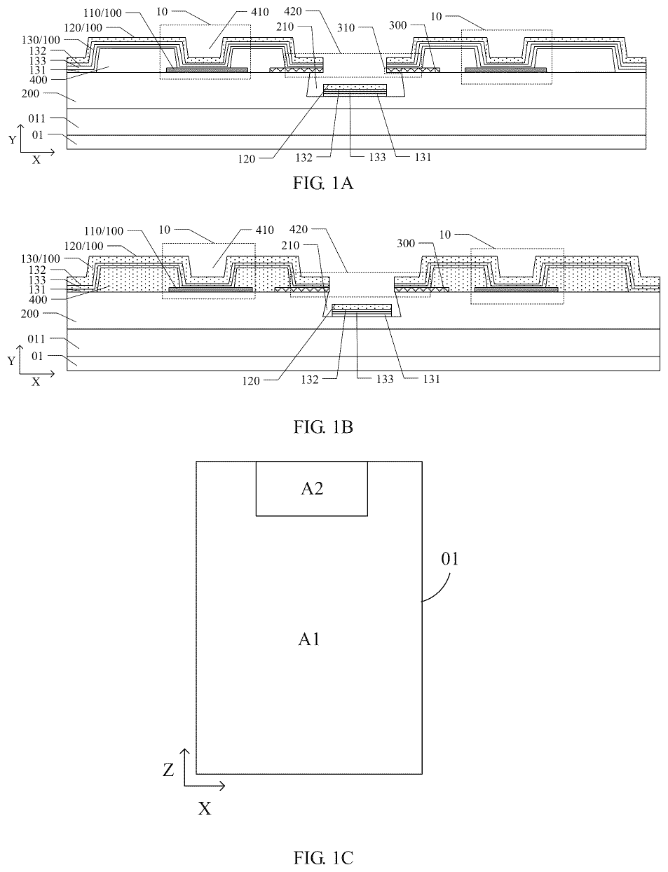

FIG. 1A is a partial cross-sectional structural view of a display substrate provided by an example of one embodiment of the present disclosure, FIG. 1B is a partial cross-sectional structural view of a display substrate provided by another example of one embodiment of the present disclosure, and FIG. 1C is a planar view of a display substrate provided by an embodiment of the present disclosure. As shown in FIGS. 1A-1C, the display substrate includes a first display region A1 and a second display region A2 located on a base substrate 01. For example, the first display region A1 surrounds at least part of the second display region A2. For example, the second display region A2 shown in FIG. 1B is located in the middle of the top of the base substrate 01. For example, the four sides of the rectangular first display region A1 can all surround the second display region A2, that is, the second display region A2 can be surrounded by the first display region A1. For example, the second display region A2 may not be located in the middle of the top of the base substrate 01 as shown in FIG. 1B, but at any other position. For example, the second display region A2 can be located at the upper left corner or the upper right corner of the base substrate 01. For example, the first display region A1 can be a non-light-transmitting display region and the second display region A2 can be a light-transmitting display region. Thus, a required hardware structure, such as a photosensitive sensor, can be directly arranged in the second display region A2 without digging a hole in the display substrate, which provides a basis for realizing a full screen.

As shown in FIGS. 1A-1C, the display substrate includes a base substrate 01, a plurality of sub-pixels 10 in the first display region A1 of the base substrate 01, and an insulating layer 200 on the base substrate 01. For example, the material of the insulating layer 200 can include an organic material, and the insulating layer 200 can be an organic layer.

As shown in FIGS. 1A-1C, the sub-pixel 10 includes an organic light-emitting element 100, the organic light-emitting element 100 includes a light-emitting functional layer 130 and a first electrode 110 and a second electrode 120 located at both sides of the light-emitting functional layer 130 along the direction perpendicular to the base substrate 01, the first electrode 110 is located between the light-emitting functional layer 130 and the base substrate 01, and the light-emitting functional layer 130 includes a plurality of film layers. For example, the light-emitting functional layer 130 includes a charge generation layer 133.

As shown in FIGS. 1A-1C, the display substrate further includes a shielding portion 300 located at one side of the insulating layer 200 away from the base substrate 01, and an orthographic projection of the shielding portion 300 on the base substrate 01 overlaps with an orthographic projection of the insulating layer 200 on the base substrate 01. The material of the shielding portion 300 is different from the material of the insulating layer 200. For example, the material of the shielding portion 300 includes an inorganic non-metallic material or a metallic material.

As shown in FIGS. 1A-1C, the insulating layer 200 includes a plurality of grooves 210. In the direction perpendicular to the base substrate 01, the thickness of the insulating layer 200 at a position other than the groove 210 is greater than the thickness of the shielding portion 300. The thickness of at least a part of the insulating layer 200 overlapping in projection on the base substrate 01 with the shielding portion 300 is greater than the thickness of the shielding portion 300.

As shown in FIG. 1B, the groove 210 and the shielding portion 300 are at least partially located between adjacent sub-pixels 10, and at least two shielding portions 300 are arranged between adjacent sub-pixels along an arrangement direction of the adjacent sub-pixels 10 and are spaced apart from each other. The shielding portion 300 is located at the edge of the groove 210 and protrudes into the groove 210 in the arrangement direction to form a protrusion 310 covering a part of the opening of the groove. The arrangement direction described above can be approximately the extending direction of the center connecting line or the nearest connecting line of the light-emitting regions of adjacent sub-pixels; or if the light-emitting regions of adjacent sub-pixels are distributed along the X direction, the arrangement direction is the X direction.

As shown in FIG. 1B, the slope angle between at least part of a side surface of the shielding portion 300 and a plane parallel to the surface of the insulating layer 200 away from the base substrate 01 is a first slope angle, the slope angle between at least part of a side surface of the groove 210 and the plane parallel to the surface of the insulating layer 200 away from the base substrate 01 is a second slope angle, and at least one of the first slope angle and the second slope angle is greater than 60 degrees.

As shown in FIG. 1B, the slope angle between at least part of the side surface of the shielding portion 300 and the plane parallel to a contact surface of the shielding portion 300 and the insulating layer 200 is the first slope angle, and the slope angle between at least part of the side surface of the groove 210 and the plane parallel to the contact surface of the shielding portion 300 and the insulating layer 200 is the second slope angle, and at least one of the first slope angle and the second slope angle is greater than 60 degrees. For example, at least one of the first slope angle and the second slope angle is in the range of 60-120 degrees. For example, at least one of the first slope angle and the second slope angle is in the range of 70-110 degrees. For example, at least one of the first slope angle and the second slope angle is in the range of 80-100 degrees. For example, at least one of the first slope angle and the second slope angle is greater than 70 degrees. For example, at least one of the first slope angle and the second slope angle is greater than 80 degrees. For example, at least one of the first slope angle and the second slope angle is greater than 70 degrees. For example, at least one of the first slope angle and the second slope angle is greater than 80 degrees. For example, at least one of the first slope angle and the second slope angle is greater than 90 degrees.

The first slope angle can be an included angle between the surface of the shielding portion away from the base substrate and the side surface of the shielding portion, and can also be an included angle between the surface of the shielding portion facing the base substrate and the side surface of the shielding portion; and the second slope angle can be an included angle between the surface of the insulating layer away from the base substrate and the side surface of the groove. The side surface of the shielding portion can refer to a surface of the shielding portion having a certain included angle with the base substrate, and the side surface of the groove can refer to the sidewall of the groove having a certain included angle with the base substrate.

The difference between the examples shown in FIG. 1B and FIG. 1A relates to the positional relationship and angular relationship between the shielding portion 300 and the sidewall of the groove 210.

As shown in FIGS. 1A-1C, at least one film layer of the light-emitting functional layer 130 is disconnected at at least part of the edge of the shielding portion 300.

In the embodiment of the present disclosure, the groove and the shielding portion are arranged between adjacent sub-pixels in the display substrate, the relative positional relationship between the shielding portion and the edge of the groove, or the angle of the side surface of the shielding portion and the angle of the sidewall of the groove are adjusted, so that at least one film layer of the light-emitting functional layer can be disconnected at the protrusion of the shielding portion relative to the edge of the groove or at the edges of the shielding portion and the sidewall of the groove, which is helpful to reduce the probability of crosstalk between adjacent sub-pixels.

For example, in the case where the materials of the insulating layer 200 and the shielding portion 300 are both light-transmitting materials, the refractive index of the insulating layer 200 is smaller than the refractive index of the shielding portion. For example, in the direction perpendicular to the base substrate 01, the shielding portion 300 can overlap with a transistor in the pixel circuit described later to play a shielding role.

The phrase “adjacent sub-pixels” in any one embodiment of the present disclosure means that there is not any other sub-pixel arranged between these two sub-pixels.

For example, as shown in FIG. 1A, the plurality of sub-pixels 10 can include two adjacent sub-pixels 10 arranged along the X direction. For example, the plurality of shielding portions 300 provided between two adjacent sub-pixels 10 are arranged along the X direction. For example, the shielding portion 300 arranged between two adjacent sub-pixels 10 protrudes into the groove 210 relative to the edge of the groove 210 in the X direction to form a protrusion 310. The protrusion 310 in the shielding portion 300 is suspended, the protrusion 310 shields a part of the edge of the opening of the groove 210, and the part of the shielding portion 300 other than the protrusion 310 is attached to the surface of the insulating layer 200 away from the base substrate 01. For example, the protrusion 310 extends in a direction parallel to the base substrate 01. For example, the orthographic projection of the protrusion 310 on the insulating layer 200 is located in the groove 210.

For example, as shown in FIG. 1A, a distance between a certain shielding portion 300 located between two adjacent sub-pixels 10 and one of the two adjacent sub-pixels 10 is less than a distance between the certain shielding portion 300 and the other of the two adjacent sub-pixels 10; in the two adjacent sub-pixels 10, the sub-pixel 10 that is closer to the shielding portion 300 is a sub-pixel P1, the protrusion 310 in the shielding portion 300 is farther away from the sub-pixel P1 than other parts of the shielding portion 300 is, and the center of the groove 210 is located at one side of the shielding portion 300 away from the sub-pixel P1.

For example, as shown in FIG. 1A, the light-emitting functional layer 130 can include a first light-emitting layer (EML) 131, a charge generation layer (CGL) 133 and a second light-emitting layer 132 which are stacked, and the charge generation layer 133 is located between the first light-emitting layer 131 and the second light-emitting layer 132. The charge generation layer has a high conductivity, which can make the light-emitting functional layer have the advantages of long life, low power consumption and high brightness. For example, compared with a light-emitting functional layer without the charge generation layer, the sub-pixel can nearly double the illuminous brightness by setting the charge generation layer in the light-emitting functional layer.

For example, the sub-pixel including the charge generation layer adopts Tandem technology, N/P-CGL is used as a heterojunction, and two light-emitting layers are connected in series. This technology realizes the series connection of dual light-emitting devices, which greatly reduces the light-emitting current of the light-emitting devices and prolongs the life of the organic light-emitting element under the same light-emitting intensity, thus facilitating applications in new technologies with long life, such as vehicles, etc.

For example, in each sub-pixel 10, the light-emitting functional layer 130 can further include a hole injection layer (HIL), a hole transport layer (HTL), an electron transport layer (ETL) and an electron injection layer (EIL). For example, the hole injection layer, the hole transport layer, the electron transport layer, the electron injection layer and the charge generation layer 133 are all common film layers for the plurality of sub-pixels 10, which can be called common layers. For example, at least one film layer, which is disconnected at the edge of the groove, of the light-emitting functional layer 130 can be at least one film layer of the common layers described above. By disconnecting at least one film layer of the common layers at the edge of the groove between adjacent sub-pixels, the probability of crosstalk between adjacent sub-pixels can be reduced.

For example, the second light-emitting layer 132 can be located between the first light-emitting layer 131 and the second electrode 120, and the hole injection layer can be located between the first electrode 110 and the first light-emitting layer 131. For example, an electron transport layer can be disposed between the charge generation layer 133 and the first light-emitting layer 131. For example, a hole transport layer can be disposed between the second light-emitting layer 132 and the charge generation layer 133. For example, an electron transport layer and an electron injection layer can be disposed between the second light-emitting layer 132 and the second electrode 120.

For example, in the same sub-pixel 10, the first light-emitting layer 131 and the second light-emitting layer 132 can be light-emitting layers emitting light of the same color. For example, the first light-emitting layers 131 (or the second light-emitting layers 132) in the sub-pixels 10 emitting light of different colors emit light of different colors. Of course, the embodiment of the present disclosure is not limited thereto. For example, in the same sub-pixel 10, the first light-emitting layer 131 and the second light-emitting layer 132 can be light-emitting layers emitting light of different colors. By setting the light-emitting layers emitting light of different colors in the same sub-pixel 10, the light emitted by the multiple light-emitting layers included in the sub-pixel 10 can be mixed into white light, and the color of the emergent light of each sub-pixel can be adjusted by setting a color filter layer.

For example, in adjacent sub-pixels 10, the light-emitting layers located at the same side of the charge generation layer 133 can be arranged at intervals from each other, or can overlap or meet at the gap between these two sub-pixels 10, which is not limited in the embodiment of the present disclosure.

For example, the first light-emitting layers 131 (the second light-emitting layers 132) of adjacent sub-pixels can overlap within the groove 210. However, it is not limited thereto. For example, the first light-emitting layers 131 (the second light-emitting layers 132) of adjacent sub-pixels can be arranged at intervals in the groove 210; alternatively, only the first light-emitting layer 131 (the second light-emitting layer 132) of one sub-pixel of the adjacent sub-pixels may be disposed in the groove 210.

For example, the material of the electron transport layer can include an aromatic heterocyclic compound, such as benzimidazole derivatives, imidazopyridine derivatives, benzimidazole phenanthridine derivatives or other imidazole derivatives; pyrimidine derivatives, triazine derivatives or other triazine derivatives; quinoline derivatives, isoquinoline derivatives, phenanthroline derivatives and other compounds containing nitrogen-containing six-membered ring structures (including compounds with phosphine oxide substituents on heterocyclic rings), and the like.

For example, the material of the charge generation layer 133 can be a material containing phosphorus oxide groups or a material containing triazine.

For example, in the case where the insulating layer 200 between two adjacent sub-pixels 10 is not provided with the groove 210 and the shielding portion 300 is not provided on the insulating layer 200, at least one film layer in the light-emitting functional layers 130 of the two adjacent sub-pixels 10 can be connected or be a whole-layer film layer. By setting the groove and the shielding portion between adjacent sub-pixels, at least one film layer (e.g., a charge generation layer) in the light-emitting functional layers of two adjacent sub-pixels is arranged at intervals, so that the resistance between the light-emitting functional layers of adjacent sub-pixels can be increased, thereby reducing the probability of crosstalk between the two adjacent sub-pixels without affecting the normal display of the sub-pixels.

In the display substrate provided by the embodiment of the present disclosure, by setting the groove in the organic layer between two adjacent sub-pixels, and setting the shielding portion at the edge of the groove and protruding inward relative to the edge of the groove, the charge generation layer formed at the protrusion of the shielding portion protruding into the groove can be disconnected. In this case, at least one film layer (e.g., the charge generation layer) in the light-emitting functional layers of two adjacent sub-pixels is arranged at intervals, so that the resistance between the light-emitting functional layers of adjacent sub-pixels can be increased, thereby reducing the probability of crosstalk between the two adjacent sub-pixels without affecting the normal display of the sub-pixels.

For example, the film layers between the second light-emitting layer 132 and the first electrode 110 are all disconnected at the protrusion 310 of the shielding portion 300.

For example, the depth of the groove 210 is greater than the thickness of the light-emitting functional layer 130, and all of the film layers included in the light-emitting functional layer 130 are disconnected at the protrusion 310. For example, the second electrode 120 and part of the film layers of the light-emitting functional layer 130 can be disposed in the groove 210. For example, all of the film layers of the light-emitting functional layer 130 and the second electrode 120 can be disposed in the groove 210.

For example, a first orthographic projection of at least one film layer in the light-emitting functional layer 130 on the base substrate 01 is continuous, and a second orthographic projection of the at least one film layer in the light-emitting functional layer 130 on a plane perpendicular to the base substrate 01 is discontinuous; alternatively, the first orthographic projection of at least one film layer in the light-emitting functional layer 130 on the base substrate 01 and the second orthographic projection of the at least one film layer in the light-emitting functional layer 130 on the plane perpendicular to the base substrate 01 are discontinuous, and the width of the gap at the discontinuous position of the first orthographic projection is less than the width of the gap at the discontinuous position of the second orthographic projection.

For example, at least one film layer in the light-emitting functional layer 130 can be a charge generation layer 133, and the first orthographic projection of the charge generation layer 133 on the base substrate 01 is continuous, and the second orthographic projection of the charge generation layer 133 on the plane perpendicular to the base substrate 01 is discontinuous. For example, the charge generation layer 133 can include a part located in the groove 210 and a part not located in the groove 210, and these two parts are disconnected at the edge of the groove 210. For example, the first orthographic projections of these two parts on the base substrate 01 can be connected or overlapped, and the first orthographic projections are continuous. For example, the distances between these two parts and the base substrate 01 are different, and the second orthographic projections of these two parts on the XY plane are discontinuous.

For example, at least one film layer in the light-emitting functional layer 130 can be a charge generation layer 133, the first orthographic projection of the charge generation layer 133 on the base substrate 01 and the second orthographic projection of the charge generation layer 133 on the plane perpendicular to the base substrate 01 are discontinuous, and the width of the gap at the discontinuous position of the first orthographic projection is less than the width of the gap at the discontinuous position of the second orthographic projection. For example, the charge generation layer 133 can include a part located in the groove 210 and a part not located in the groove 210, and these two parts are disconnected at the edge of the shielding portion 300. For example, there is a gap between the first orthographic projections of these two parts on the base substrate 01, and the first orthographic projections are disconnected. For example, the distances between these two parts and the base substrate 01 are different, the second orthographic projections of these two parts on the XY plane are discontinuous, and there is a gap between the second orthographic projections of these two parts on the XY plane.

For example, as shown in FIG. 1A, the insulating layer 200 is located between the first electrode 110 and the base substrate 01.

For example, the base substrate 01 can be made of one or more materials of glass, polyimide, polycarbonate, polyacrylate, polyetherimide and polyethersulfone, and the present embodiment includes but is not limited thereto.

For example, the insulating layer 200 includes an organic layer. For example, the organic layer includes a planarization (PLN) layer. For example, the first electrode 110 is in contact with the surface of the organic layer away from the base substrate 01. For example, the groove 210 is located in the organic layer, and the ratio of the depth of the groove 210 to the thickness of a planar part of the organic layer is greater than or equal to 0.2 and less than 1. For example, the groove 210 is located in the planarization layer, and the ratio of the depth of the groove 210 to the thickness of the planarization layer is in the range of 0.2-0.9. For example, the ratio of the depth of the groove 210 to the thickness of the planarization layer is in the range of 0.3-0.8. For example, the ratio of the depth of the groove 210 to the thickness of the planarization layer is in the range of 0.4-0.7. For example, the ratio of the depth of the groove 210 to the thickness of the planarization layer is in the range of 0.5-0.6. The thickness of the planarization layer can refer to the thickness at the position of the maximum thickness of the planarization layer, or the thickness at the position of the minimum thickness in the planarization layer other than the positions of the groove and a via hole hole, or the average thickness of the planarization layer. For example, the thickness of the planarization layer can be 1.5 microns, and the depth of the groove 210 can be 0.5 microns.

For example, the material of the planarization layer includes one or more of resin, acrylic or polyethylene terephthalate, polyimide, polyamide, polycarbonate, epoxy resin, etc.

For example, as shown in FIG. 1A, the second electrodes 120 of the plurality of sub-pixels 10 can be a common electrode shared by the plurality of sub-pixels. In the case where the insulating layer 200 between two adjacent sub-pixels 10 is not provided with the groove 210 and the shielding portion 300 is not provided on the insulating layer 200, the second electrode 120 is a whole layer; in the case where the insulating layer 200 between two adjacent sub-pixels 10 is provided with the groove 210 and the shielding portion 300 protruding inward relative to the edge of the groove 210 at the edge of the groove 210, both the light-emitting functional layer 130 and the second electrode 120 are disconnected at the protrusion 310 of the shielding portion 300.

For example, the orthographic projection of the second electrode 210 on the base substrate 01 is continuous. For example, the orthographic projection of the second electrode 120 on the plane perpendicular to the base substrate 01 can be discontinuous.

For example, the depth of the groove 210 can be greater than the thickness of the light-emitting functional layer 130, so that both the light-emitting functional layer 130 and the second electrode 120 are disconnected at the protrusion 310 of the shielding portion 300. For example, the depth of the groove 210 can also be set smaller, so that the light-emitting functional layer 130 is disconnected at the protrusion 310 of the shielding portion 300, while the second electrode 120 is not disconnected at the protrusion 310.

For example, the material of the shielding portion 300 can include any one or more of silicon nitride, silicon oxide or silicon oxynitride. For example, the shielding portion 300 can also include an inorganic material, such as metal or alloy, metal oxide, metal sulfide or metal nitride, etc., without being limited in the present embodiment. For example, the metal oxide can include calcium oxide, zinc oxide, copper oxide, titanium dioxide, tin dioxide, etc.; the metal sulfide can include iron sulfide, copper sulfide, zinc sulfide, tin disulfide, etc.; and the metal nitride can include silicon nitride, aluminum nitride, etc. The present embodiment includes but is not limited to these cases.

For example, as shown in FIG. 1A, the ratio of the size of the protrusion 310 of the shielding portion 300 protruding into the groove 210 to the size of the shielding portion 300 in the X direction can be in the range of 0.005-0.5. For example, the ratio of the size of the protrusion 310 of the shielding portion 300 protruding into the groove 210 to the size of the shielding portion 300 in the X direction can be in the range of 0.01-0.45. For example, the ratio of the size of the protrusion 310 of the shielding portion 300 protruding into the groove 210 to the size of the shielding portion 300 in the X direction can be in the range of 0.05-0.4. For example, the ratio of the size of the protrusion 310 of the shielding portion 300 protruding into the groove 210 to the size of the shielding portion 300 in the X direction can be in the range of 0.1-0.35. For example, the ratio of the size of the protrusion 310 of the shielding portion 300 protruding into the groove 210 to the size of the shielding portion 300 in the X direction can be in the range of 0.2-0.3. For example, the size of the protrusion 310 of the shielding portion 300 protruding into the groove 210 can be in the range of 0.1-5 microns. For example, the size of the protrusion 310 of the shielding portion 300 protruding into the groove 210 can be in the range of 0.2-2 microns.

For example, as shown in FIG. 1A, the display substrate further includes a pixel defining pattern 400 located at one side of the first electrode 110 away from the base substrate 01, the pixel defining pattern 400 at least located in the first display region A1 includes a plurality of first openings 410, one sub-pixel corresponds to at least one first opening 410, and the light-emitting element of the sub-pixel is at least partially located in the first opening 410 corresponding to the sub-pixel, and the first opening 410 is configured to expose the first electrode 110. For example, at least part of the first electrode 110 is located between the pixel defining pattern 400 and the base substrate 01. For example, in the case where the light-emitting functional layer 130 is formed in the first opening 410 of the pixel defining pattern 400, the first electrode 110 and the second electrode 120 located at both sides of the light-emitting functional layer 130 can drive the light-emitting functional layer 130 in the first opening 410 of the pixel defining pattern 400 to emit light. For example, the light-emitting region described above can refer to a region where the sub-pixel effectively emits light, and the shape of the light-emitting region refers to a two-dimensional shape; for example, the shape of the light-emitting region can be the same as the shape of the first opening 410 of the pixel defining pattern 400.

For example, the part of the pixel defining pattern 400 other than the first opening 410 includes a pixel defining portion, and the material of the pixel defining portion can include polyimide, acrylic or polyethylene terephthalate, etc.

For example, as shown in FIG. 1A, the pixel defining portion covers at least a part of the shielding portion 300. For example, the pixel defining portion does not cover the protrusion 310 of the shielding portion 300.

For example, as shown in FIG. 1A, the pixel defining portion is arranged between the shielding portion 300 and the first electrode 110 along a direction parallel to the base substrate 01, that is, the pixel defining portion can separate the shielding portion 300 from the first electrode 110.

For example, the first electrode 110 includes at least one film layer, and the shielding portion 300 is arranged in the same layer as a certain film layer of the first electrode 110. For example, the material of a certain film layer in the first electrode 110 is the same as the material of the shielding portion 300. For example, the first electrode includes at least one film layer, and the shielding portion is arranged in the same layer as at least a certain film layer of the first electrode. For example, at least a certain film layer of the first electrode and the shielding portion are arranged on the same surface of the same film layer.

For example, the first electrode 110 can be an anode and the second electrode 120 can be a cathode. For example, the cathode can be made of a material with high conductivity and low work function, and for example, the cathode can be made of a metallic material. For example, the anode can be formed of a transparent conductive material with a high work function.

For example, the shielding portion 300 can have an integrated structure with a film layer, closest to the base substrate 01, of the first electrode 110 closest to the shielding portion 300. For example, by setting the size of the first electrode in the X direction shown in, for example, FIG. 1A, to be long enough to include the protrusion 310 extending to the edge of the groove 210, the patterning process for manufacturing the shielding portion can be saved.

For example, in the X direction shown in FIG. 1A, the size of the first electrode 110 can be greater than the size of the pixel defining portion. For example, the first electrode 110 can include a part exposed by the first opening 410, a part covered by the pixel defining portion, and a protrusion 310 extending to the edge of the groove 210.

For example, as shown in FIG. 1A, along the arrangement direction of adjacent sub-pixels 10 (X direction in the figure), the pixel defining portion located between the centers of the light-emitting region of adjacent sub-pixels 10 is referred to as a first pixel defining portion, and the pixel defining portion located at both sides of the centers of the light-emitting region of the adjacent sub-pixels 10 is referred to as a second pixel defining portion. The size of the first pixel defining portion in the X direction can be less than the size of the second pixel defining portion in the X direction, so that the distance between two first pixel defining portions can be increased to set the groove 210 and the shielding portion 300 between these two first pixel defining portions.

For example, as shown in FIG. 1A, the pixel defining pattern 400 further includes a second opening 420, and the second opening 420 is configured to expose at least part of the groove 210. For example, the second opening 420 can expose part of the shielding portion 300. For example, the second opening 420 can completely expose the groove 210.

For example, as shown in FIG. 1A, in the X direction, the distance between the edges, close to each other, of two shielding portions 300 (i.e., the edges, close to each other, of the protrusions 310) is smaller than the opening of the groove 210.

For example, as shown in FIG. 1A, the cross section of the groove 210, which is cut by a plane parallel to the XY plane, can include a pattern with an opening encircled by three straight sides, wherein two straight sides that are intersected can form a right angle, an acute angle or an obtuse angle. And the cross section of the groove 210, which is cut by a plane parallel to the XY plane, can include a pattern with an opening encircled by arc edges, and along a direction opposite to the direction indicated by the arrow of the Y direction shown in FIG. 1A, the size of the pattern in the X direction can gradually increase, or firstly increase and then decrease.

For example, as shown in FIG. 1A, other film layers 011 are arranged between the insulating layer 200 and the base substrate 01, which may include film layers or structures, such as a gate insulator layer, an interlayer dielectric layer, various film layers in pixel circuits (e.g., including a thin film transistor, a storage capacitor, and other structures), a data line, a gate line, a power signal line, a reset power signal line, a reset control signal line, and a light-emitting control signal line, etc. For example, only one layer of power signal lines is included in the other film layers 011. For example, the surface of the insulating layer 200 facing the base substrate 01 can be in contact with the interlayer dielectric layer.

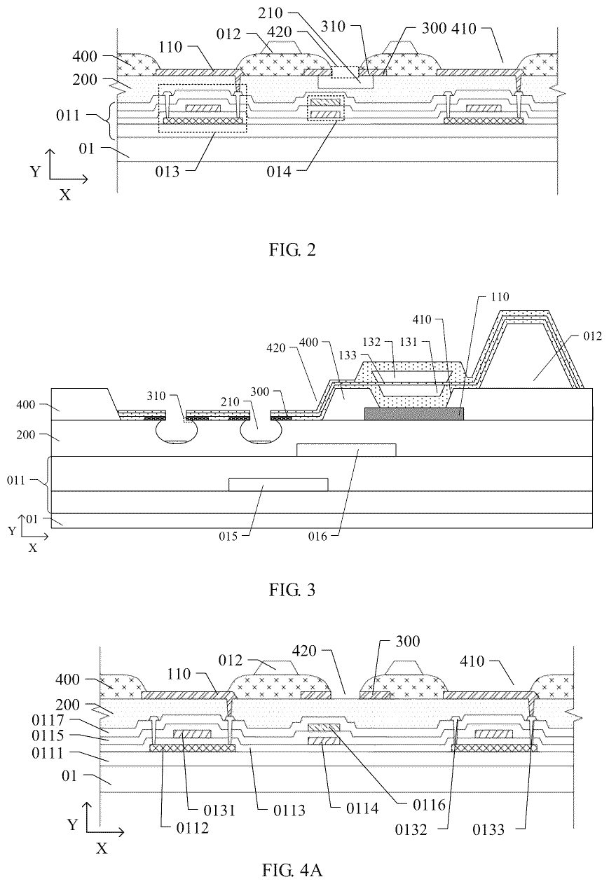

For example, FIG. 2 is a partial cross-sectional structural view of a display substrate provided by another example of one embodiment of the present disclosure. The base substrate 01, the insulating layer 200, the shielding portion 300, other film layers 011 and various film layers included in the organic light-emitting element as shown in FIG. 2 can be the same as the corresponding structures in the display substrate as shown in FIG. 1A, and details will not be repeated here. For example, as shown in FIG. 2, the first electrode 110 of the organic light-emitting element can be connected to one of the source electrode and the drain electrode of the thin film transistor in the pixel circuit through a via hole penetrating the insulating layer 200. For example, the pixel circuit further includes a storage capacitor 014.

For example, as shown in FIG. 2, spacers 012 are further provided on the pixel defining portion of the pixel defining pattern 400, which are configured to support an evaporation mask plate for manufacturing the light-emitting layer.

For example, as shown in FIG. 2, the orthographic projection of the shielding portion 300 on the base substrate 01 is completely within the orthographic projection of the pixel defining portion on the base substrate 01. For example, the pixel defining portion covers the protrusion 310 of the shielding portion 300.

For example, as shown in FIG. 2, the pixel defining portion of the pixel defining pattern 400 covers part of the opening of the groove 210, and the second opening 420 of the pixel defining pattern 400 only exposes part of the opening of the groove 210.

For example, as shown in FIG. 2, the distance between two shielding portions 300 located between adjacent sub-pixels can be in the range of 2-15 microns. For example, the distance between two shielding portions 300 located between adjacent sub-pixels can be in the range of 5-10 microns. For example, the distance between two shielding portions 300 located between adjacent sub-pixels can be in the range of 3-7 microns. For example, the distance between two shielding portions 300 located between adjacent sub-pixels can be in the range of 4-12 microns.

For example, the other film layer 011 shown in FIGS. 1A-2 can include a source-drain metal layer SD (i.e., a film layer where the data line and the power signal line are located) or two source-drain metal layers SD1 and SD2 (for example, other film layers can include two layers of power signal lines, and these two layers of power signal lines can be electrically connected).

For example, FIG. 3 is a partial cross-sectional structural view of a display substrate provided by another example of one embodiment of the present disclosure. The base substrate 01, the shielding portion 300, various film layers included in the organic light-emitting element, and the spacers 012 as shown in FIG. 3 can be the same as the corresponding structures in the display substrate as shown in FIG. 2, and details will not be repeated here. For example, as shown in FIG. 3, the orthographic projection of the pixel defining portion of the pixel defining pattern 400 on the base substrate 01 may not overlap with the orthographic projection of the shielding portion 300 on the base substrate 01. For example, the second opening 420 of the pixel defining pattern 400 can completely expose the shielding portion 300.

For example, as shown in FIG. 3, two grooves 210 can be arranged between adjacent sub-pixels, and shielding portions 300 are arranged at both sides of the opening of each groove 210 in the X direction. Of course, the embodiment of the present disclosure is not limited to the case in which one or two grooves are arranged between adjacent sub-pixels, but can also include the case in which three or more grooves are arranged between adjacent sub-pixels, and the number of grooves can be set according to the distance between adjacent sub-pixels and the size of the grooves.

For example, as shown in FIG. 3, two shielding portions 300 between two adjacent grooves 210 can be arranged at intervals. The embodiment of the present disclosure is not limited thereto. In the case where the distance between two adjacent grooves 210 is relatively small, one shielding portion 300 may be arranged between the two adjacent grooves 210, and both ends of the shielding portion 300 extend to the openings of the two grooves 210 to form two protrusions 310.

For example, as shown in FIG. 3, in the case where two grooves 210 are arranged between two adjacent sub-pixels, at least one of the two shielding portions 300 located at both sides of the two grooves 210 can also be a part of at least one of the two first electrodes 110 of the two adjacent sub-pixels. For example, a part of the first electrode 110 is exposed by the first opening 410 of the pixel definition pattern 400 for driving the light-emitting functional layer to emit light, and another part of the first electrode 110 is exposed by the second opening 420 of the pixel defining pattern 400 and extends to the opening edge of the groove 210 for disconnecting the charge generation layer 133, thus saving process steps.

For example, as shown in FIG. 3, the display substrate includes a first conductive layer pattern 015 and a second conductive layer pattern 016 located between the first electrode 110 and the base substrate 01, and the first conductive layer pattern 015 is located between the base substrate 01 and the second conductive layer pattern 016. For example, the first conductive layer pattern 015 can include a data line and a first power signal line, the second conductive layer pattern 016 can include a second power signal line, and the first power signal line is electrically connected to the second power signal line. For example, the data line is configured to be electrically connected to the pixel circuit to provide a data signal Data for the pixel circuit, and the first power signal line is electrically connected to the pixel circuit to provide a power signal Vdd for the pixel circuit.

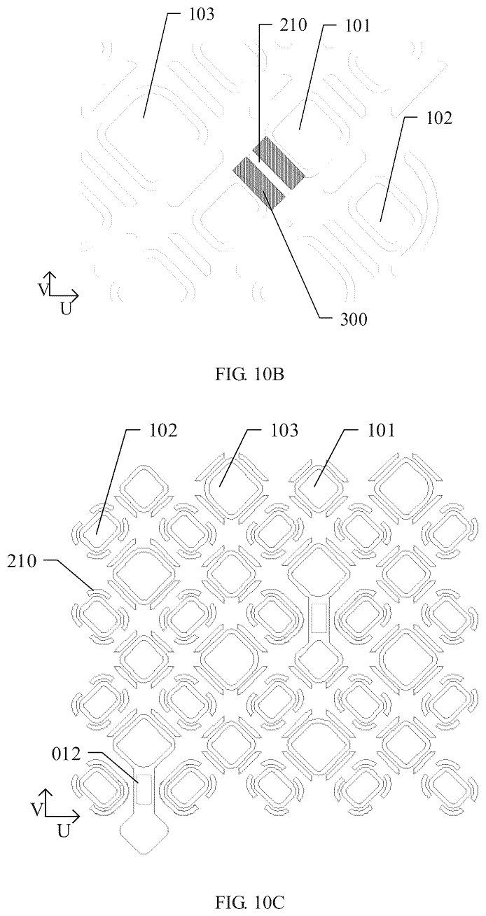

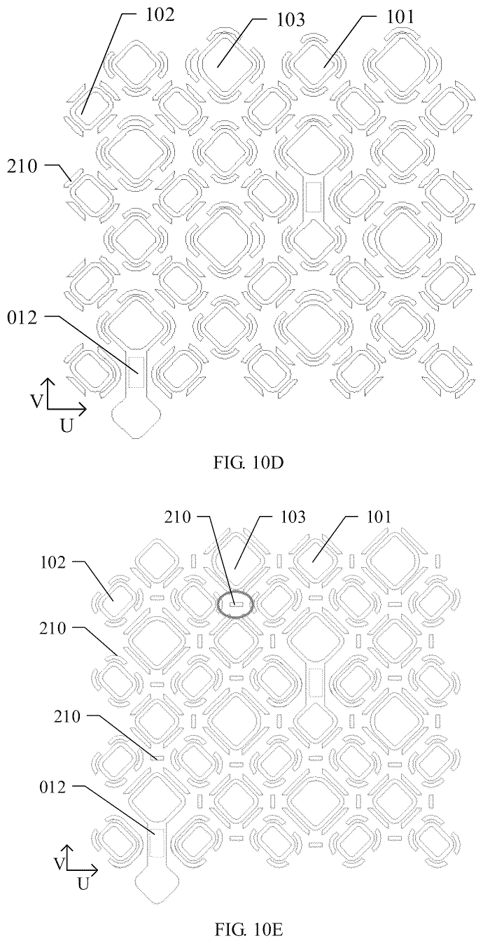

For example, in the direction perpendicular to the base substrate 01, the groove 210 overlaps with the first conductive layer pattern 015. For example, in the direction perpendicular to the base substrate 01, the groove 210 overlaps with at least one of the data line and the power line. For example, the extending direction of the orthographic projection of the groove 210 on the base substrate 01 is different from the extending direction of at least one of the data line and the power line. For example, the extending direction of the data line can be the V direction or the U direction shown in FIG. 10A. For example, the extending direction of the power line can be the V direction or the U direction shown in FIG. 10A.

For example, as shown in FIG. 3, the cross section of the groove 210, which is cut by a plane parallel to the XY plane, can include a pattern with an opening encircled by arc edges, and along a direction opposite to the direction indicated by the arrow of the Y direction shown in FIG. 3, the size of the pattern in the X direction can firstly increase and then decrease.

For example, as shown in FIG. 3, the sizes of the first light-emitting layer 131 and the second light-emitting layer 132 in the sub-pixel in the direction parallel to the base substrate 01 can be set relatively small, and the first light-emitting layer 131 and the second light-emitting layer 132 may not extend to the opening edge of the groove 210.

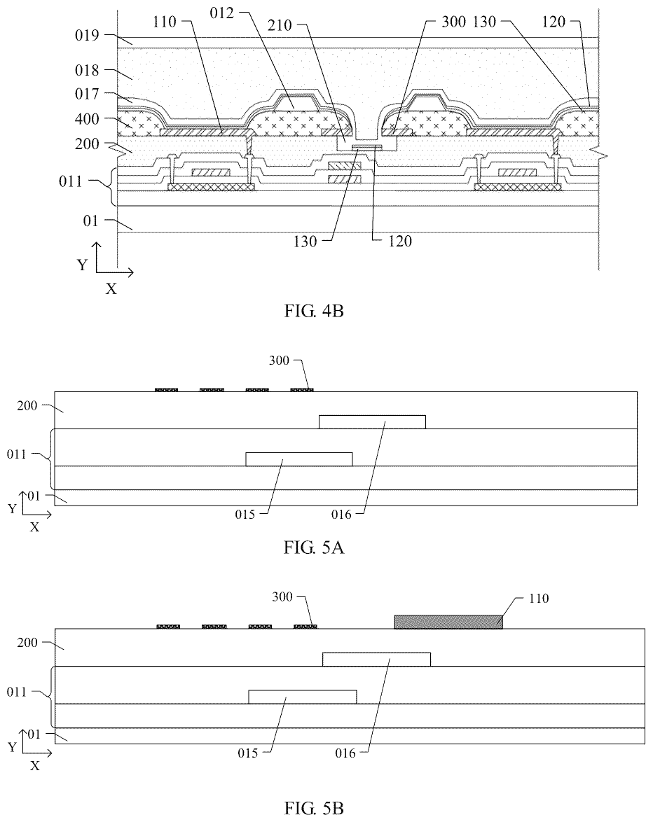

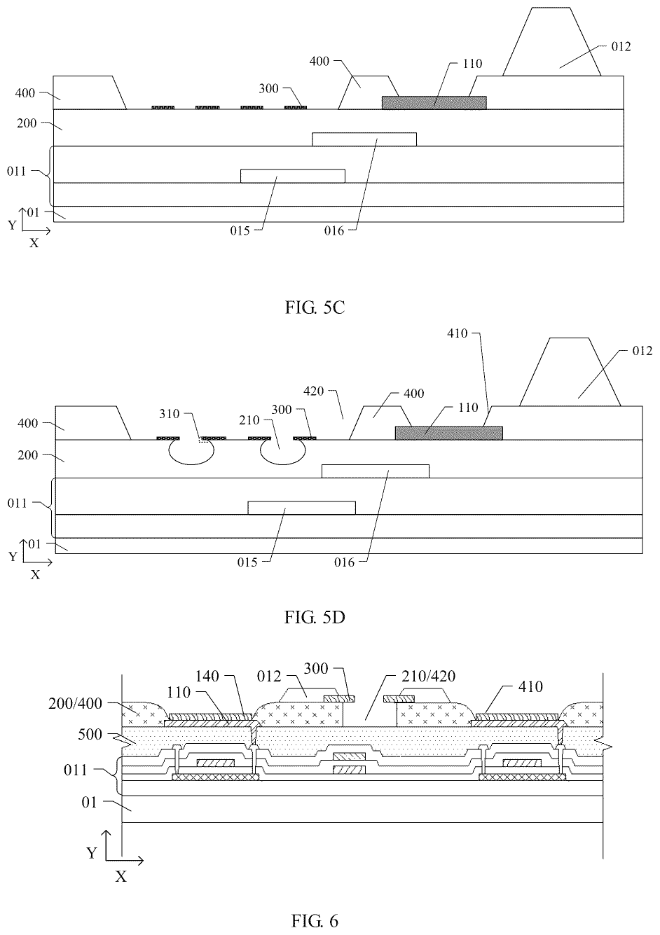

For example, FIG. 4A is a schematic diagram of the display substrate before the formation of the structure shown in FIG. 2, FIG. 4B is a schematic diagram of the display substrate after the formation of the structure shown in FIG. 2, and FIGS. 5A-5D are flow charts of a manufacturing method of the display substrate before the formation of the structure shown in FIG. 3. For example, as shown in FIGS. 2-3, 4A and 5A-5D, the manufacturing method of the display substrate includes: forming a plurality of sub-pixels on a base substrate 01, wherein forming the sub-pixels includes sequentially forming a first electrode 110, a light-emitting functional layer 130 and a second electrode 120 which are stacked in a direction perpendicular to the base substrate 01; forming an insulating layer 200 on the base substrate 01; forming a shielding portion material layer on the insulating layer 200, and patterning the shielding portion material layer to form a plurality of shielding portions 300, wherein the shielding portion 300 is located between adjacent sub-pixels, and at least two shielding portions 300 are arranged between adjacent sub-pixels along an arrangement direction of the adjacent sub-pixels; and etching the insulating layer 200 to form a groove 210. The opening edge of the groove 210 extends outward relative to the edges, close to each other, of two adjacent shielding portions 300, so that the shielding portion 300 includes a protrusion 310 protruding into the groove 210 in the arrangement direction; alternatively, a slope angle between at least part of a side surface of the shielding portion 300 and a plane parallel to a contact surface of the shielding portion 300 and the insulating layer 200 is a first slope angle, a slope angle between at least part of a side surface of the groove 210 and the plane parallel to the contact surface of the shielding portion 300 and the insulating layer 200 is a second slope angle, and at least one of the first slope angle and the second slope angle is greater than 60 degrees.

The material of the insulating layer 200 is different from the material of the shielding portion 300, and in the direction perpendicular to the base substrate 01, the thickness of the insulating layer 200 at a position other than the groove 210 is greater than the thickness of the shielding portion 300. For example, the material of the insulating layer 200 can include an organic material, and the shielding portion material layer can be an inorganic non-metallic material layer or a metallic material layer.

The light-emitting functional layer 130 is formed after the groove 210 is formed, the light-emitting functional layer 130 includes a plurality of film layers, at least one film layer among the plurality of film layers is disconnected at the edge of the shielding portion 300 close to the groove 210.

For example, after the insulating layer 200 is formed and before the groove 210 is formed, the manufacturing method further includes: forming an electrode layer on the insulating layer 200 and patterning the electrode layer to form the first electrode 110.

For example, as shown in FIGS. 2 and 4A, the manufacturing method of the display substrate can include manufacturing a base substrate 01 on a glass carrier. For example, the base substrate 01 can be a flexible base substrate. For example, forming the base substrate 01 can include sequentially forming a first flexible material layer, a first inorganic material layer, a semiconductor layer, a second flexible material layer and a second inorganic material layer which are stacked on a glass carrier. The materials of the first flexible material layer and the second flexible material layer are polyimide (PI), polyethylene terephthalate (PET) or polymer soft film with surface treatment, etc. The materials of the first inorganic material layer and the second inorganic material layer are silicon nitride (SiNx) or silicon oxide (SiOx), etc., which are configured to improve the water-oxygen resistance of the base substrate. The first inorganic material layer and the second inorganic material layer are also referred to as barrier layers. The material of the semiconductor layer is amorphous silicon (a-si). For example, taking a laminated structure PI1/Barrier1/a-si/PI2/Barrier2 as an example, a manufacturing process thereof includes: firstly, coating a layer of polyimide on a glass carrier, and curing to form a first flexible (PI1) layer; subsequently, depositing a barrier film on the first flexible layer to form a first barrier (Barrier1) layer covering the first flexible layer; then, depositing an amorphous silicon film on the first barrier layer to form an amorphous silicon (a-si) layer covering the first barrier layer; then, coating a layer of polyimide on the amorphous silicon layer, and curing to form a second flexible (PI2) layer; then, depositing a barrier film on the second flexible layer to form a second barrier (Barrier2) layer covering the second flexible layer, and finally completing the manufacture of the base substrate 01.

For example, as shown in FIGS. 2 and 4A, forming other film layers 011 on the base substrate 01 includes forming a driving structure layer on the base substrate 01. The driving structure layer includes a plurality of driving circuits, and each driving circuit includes a plurality of transistors 013 and at least one storage capacitor 014. For example, the driving circuit can adopt a 2T1C design, a 3T1C design or a 7T1C design. For example, forming the driving structure layer can include depositing a first insulating film and an active layer film sequentially on the base substrate 01, and patterning the active layer film through a patterning process, so as to form a first insulating layer 0111 covering the entire base substrate 01 and an active layer pattern 0112 arranged on the first insulating layer 0111. The active layer pattern 0112 at least includes a first active layer.

For example, as shown in FIGS. 2 and 4A, a second insulating film and a first metal film are sequentially deposited, and the first metal film is patterned by a patterning process, so as to form a second insulating layer 0113 covering the active layer pattern and a first gate metal layer pattern 0114 arranged on the second insulating layer 0113. The first gate metal layer pattern 0114 includes at least a first gate electrode 0131 and a first capacitor electrode.

For example, as shown in FIGS. 2 and 4A, a third insulating film and a second metal film are sequentially deposited, and the second metal film is patterned by a patterning process, so as to form a third insulating layer 0115 covering the first gate metal layer and a second gate metal layer pattern 0116 arranged on the third insulating layer 0115. The second gate metal layer pattern 0116 at least includes a second capacitor electrode, and the position of the second capacitor electrode corresponds to the position of the first capacitor electrode.

Subsequently, a fourth insulating film is deposited, and the fourth insulating film is patterned by a patterning process, so as to form a fourth insulating layer 0117 covering the second gate metal layer. At least two first via holes are formed in the fourth insulating layer 0117, and the fourth insulating layer 0117, the third insulating layer 0115 and the second insulating layer 0113 in the two first via holes are etched away to expose the surface of the first active layer of the active layer pattern 0112.

Subsequently, a third metal film is deposited, and the third metal film is patterned by a patterning process, so as to form a source-drain metal layer pattern on the fourth insulating layer 0117. The source-drain metal layer pattern at least includes a first source electrode 0132 and a first drain electrode 0133 located in the display region. The first source electrode 0132 and the first drain electrode 0133 can be connected to the first active layer in the active layer pattern 0112 through the first via holes, respectively.

For example, as shown in FIGS. 2 and 4A, in the driving circuit, the first active layer in the active layer pattern 0112, the first gate electrode 0131, the first source electrode 0132 and the first drain electrode 0133 can form a transistor 013, and the first capacitor electrode and the second capacitor electrode can form a storage capacitor 014. In the above manufacturing process, the driving circuit of a green sub-pixel and the driving circuit of a blue sub-pixel can be formed at the same time.

For example, as shown in FIGS. 2 and 4A, the first insulating layer, the second insulating layer, the third insulating layer and the fourth insulating layer are made of any one or more of silicon oxide (SiOx), silicon nitride (SiNx) or silicon oxynitride (SiON), and can be single-layered, multi-layered or composite-layered. The first insulating layer 0111 is referred to as a buffer layer, which is configured to improve the water-oxygen resistance of the base substrate 01; the second insulating layer 0113 and the third insulating layer 0115 are referred to as gate insulator (GI) layers; and the fourth insulating layer 0117 is referred to as an interlayer dielectric (ILD) layer. The first metal film, the second metal film and the third metal film are made of a metallic material, such as any one or more of silver (Ag), copper (Cu), aluminum (Al), titanium (Ti) or molybdenum (Mo), or any alloy material of the above metals, such as aluminum-neodymium alloy (AlNd) or molybdenum-niobium alloy (MoNb), and can be single-layer structures or multi-layer composite structures. The active layer film is made of one or more materials of amorphous indium gallium zinc Oxide (a-IGZO), zinc oxynitride (ZnON), indium zinc tin oxide (IZTO), amorphous silicon (a-Si), polysilicon (p-Si), hexathiophene, polythiophene, etc., that is, the present disclosure is applicable for transistors manufactured based on oxide technology, silicon technology or organic technology.

For example, as shown in FIGS. 2 and 4A, an insulating layer 200, such as a planarization layer, is formed on the base substrate 01 which is formed with the aforementioned patterns. For example, a planarization film made of an organic material is coated on the base substrate 01 which is formed with the aforementioned patterns, so as to form a planarization (PLN) layer 200 covering the entire base substrate 01, and a plurality of second via holes are formed in the planarization layer 200 in the display region by means of mask, exposure and development processes. The planarization layer 200 in the plurality of second via holes are developed to expose the surfaces of the first drain electrodes 0133 of the transistors 013 in the driving circuits of the sub-pixels.

For example, as shown in FIGS. 2 and 4A, an inorganic material layer is formed on the planarization layer 200, and the shielding portion 300 is formed by patterning the inorganic material layer. For example, the material of the shielding portion 300 can include any one or more of silicon nitride, silicon oxide or silicon oxynitride.

For example, as shown in FIGS. 2 and 4A, in an example of the embodiment of the present disclosure, after the shielding portion 300 is formed, the first electrode 110 of the sub-pixel is formed on the planarization layer 200 by patterning. For example, the first electrode 110 is connected to the first drain electrode 0133 of the transistor 013 through the second via hole in the planarization layer 200.

For example, as shown in FIGS. 2 and 4A, the first electrode 110 can be made of a metallic material, such as any one or more of magnesium (Mg), silver (Ag), copper (Cu), aluminum (Al), titanium (Ti) or molybdenum (Mo), or any alloy material of the above metals, such as aluminum-neodymium alloy (AlNd) or molybdenum-niobium alloy (MoNb); and the first electrode 110 can be a single-layer structure, or a multi-layer composite structure, such as Ti/Al/Ti or the like, or a laminated structure formed by metal and a transparent conductive material, such as a reflective material made of ITO/Ag/ITO, Mo/AlNd/ITO, etc.

Of course, the embodiment of the present disclosure is not limited to the case in which the first electrode 110 is formed after the shielding portion 300 is formed. The first electrode 110 can be formed before the shielding portion 300 is formed.

For example, in another example of the embodiment of the present disclosure, the shielding portion 300 can be formed with the first electrode 110 by the same step patterning process. For example, a material layer is formed on the insulating layer 200, and the shielding portion 300 and the first electrode 110 can be formed simultaneously by patterning the material layer. For example, the first electrode 110 and the shielding portion 300 can both have a single-layer structure. For example, the first electrode 110 can have a multi-layer composite structure, such as ITO/Ag/ITO, and the shielding portion 300 can have a single-layer structure; and the material of the shielding portion 300 can be the same as the material of one film layer of the first electrode 110, such as ITO. For example, both the first electrode 110 and the shielding portion 300 can have a single-layer structure, and the shielding portion 300 is made of the same material as the first electrode 110.

For example, the material of the shielding portion 300 can be ITO, and the thickness of the shielding portion 300 can be in the range of 1000-5000 angstroms, so that the organic light-emitting functional layer 130 can be isolated, while the second electrode 120 can be continuous and not partitioned; therefore, crosstalk between adjacent sub-pixels can be prevented, and at the same time, the second electrode is not partitioned, thus ensuring the uniformity of display.

For example, as shown in FIGS. 2 and 4A, after the first electrode 110 and the shielding portion 300 are formed, a pixel defining pattern 400 can be formed. For example, a pixel defining film is coated on the base substrate 01 which is formed with the aforementioned patterns, and the pixel defining pattern 400 is formed by means of mask, exposure and development processes. For example, the pixel defining pattern 400 in the display region includes a plurality of pixel defining portions, a plurality of first openings 410 and a plurality of second openings 420 are formed between adjacent pixel defining portions, and the pixel defining film in the first openings 410 and the second openings 420 are developed to expose at least part of the surfaces of the first electrodes 110 of the plurality of sub-pixels and the insulating layer 200, respectively.

For example, as shown in FIGS. 2 and 4A, the pixel defining portion of the pixel defining pattern 400 can completely cover the shielding portion 300. But not limited thereto, the pixel defining portion of the pixel defining pattern 400 can cover part of the shielding portion 300, or the pixel defining portion of the pixel defining pattern 400 may not cover the shielding portion 300.

For example, as shown in FIGS. 2 and 4A, after the pixel defining pattern 400 is formed, spacers 012 can be formed on the pixel defining portions. For example, an organic material film is coated on the base substrate 01 formed with the aforementioned patterns, and the spacers 012 are formed by means of mask, exposure and development processes. The spacers 012 can serve as a support layer and be configured to support FMM (Fine Metal Mask) during evaporation.

For example, as shown in FIGS. 2 and 4A, after the spacers 012 are formed, the part other than the second opening 420 can be masked to dry etch the insulating layer 200 in the second opening 420, so as to form a groove 210, and the edge of the shielding portion 300 and the edge of the groove 210 form an undercut structure. In this case, the shielding portion 300 includes a protrusion 310 protruding into the groove 210.

For example, as shown in FIGS. 2 and 4B, after the groove 210 is formed, the light-emitting functional layer 130 and the second electrode 120 are sequentially formed. For example, the second electrode 120 can be a transparent cathode. The light-emitting functional layer 130 can emit light from a side away from the base substrate 010 through the transparent cathode, so as to realize top emitting. For example, the second electrode 120 can be made of any one or more of magnesium (Mg), silver (Ag) and aluminum (Al), or an alloy made of any one or more of the above metals, or a transparent conductive material, such as indium tin oxide (ITO), or a multi-layer composite structure of metal and a transparent conductive material.

For example, after forming the second electrode 120, forming the display substrate includes: sequentially evaporating, by using an open mask, to form a hole injection layer and a hole transport layer; sequentially evaporating, by using FMM, to form first light-emitting layers 131 emitting light of different colors, e.g., a blue light-emitting layer, a green light-emitting layer and a red light-emitting layer; sequentially evaporating, by using an open mask, to form an electron transport layer, a charge generation layer 133 and a hole transport layer; sequentially evaporating, by using FMM, to form second light-emitting layer 132 emitting light of different colors, e.g., a blue light-emitting layer, a green light-emitting layer and a red light-emitting layer; sequentially evaporating, by using an open mask, to form an electron transport layer, a second electrode and an optical coupling layer. For example, the hole injection layer, the hole transport layer, the electron transport layer, the charge generation layer, the second electrode and the optical coupling layer are all common layers of the plurality of sub-pixels.

For example, as shown in FIG. 4B, the light-emitting functional layer 130 being formed will be disconnected at the protrusion 310 of the shielding portion 300, so that a part of the light-emitting functional layer 130 is located at the edge of the shielding portion 300, and another part of the light-emitting functional layer 130 is deposited in the groove 210. For example, as shown in FIG. 4B, the second electrode 120 being formed will be disconnected at the protrusion 310 of the shielding portion 300, so that a part of the second electrode 120 is located at the edge of the shielding portion 300, and another part of the second electrode 120 is deposited in the groove 210.

For example, as shown in FIGS. 2 and 4B, after forming the second electrode 120, the manufacturing method of the display substrate further includes forming an encapsulation layer, and the encapsulation layer can include a first encapsulation layer 017, a second encapsulation layer 018 and a third encapsulation layer 019 which are stacked. The first encapsulation layer 017 is made of an inorganic material and covers the second electrode 120 in the display region. The second encapsulation layer 018 is made of an organic material. The third encapsulation layer 019 is made of an inorganic material and covers the first encapsulation layer 017 and the second encapsulation layer 018. However, the present embodiment is not limited thereto. For example, the encapsulation layer can also adopt a five-layer structure of inorganic/organic/inorganic/organic/inorganic materials. For example, both the first encapsulation layer 017 and the second encapsulation layer 018 fill the groove 210. For example, in the direction perpendicular to the base substrate 01, the thickness of the second encapsulation layer 018 at the position of the groove 210 is greater than the thickness of the second encapsulation layer 018 at the position of the light-emitting region of the light-emitting element.

For example, as shown in FIGS. 3 and 5A-5D, the display substrate formed in the present example is different from the display substrate shown in FIGS. 2 and 4A-4B in that the display substrate in the present example includes two layers of source-drain metal layer patterns 015 and 016 (a first conductive layer pattern 015 and a second conductive layer pattern 016).

For example, as shown in FIGS. 3 and 5A-5D, after forming the insulating layer 200, the manufacturing method of the display substrate includes: patterning to form a plurality of shielding portions 300 on the surface of the insulating layer 200 away from the base substrate 01; and patterning to form the first electrode 110 after the shielding portions 300 are formed. The present example illustratively shows that the shielding portion 300 and the first electrode 110 are made of different materials and are formed by a two-step patterning process, but it is not limited thereto. For example, after forming the insulating layer 200, the manufacturing method of the display substrate can include forming a plurality of shielding portions 300 and a plurality of first electrodes 110 on a surface of the insulating layer 200 away from the base substrate 01 by a one-step patterning process.

For example, as shown in FIGS. 3 and 5A-5D, after the first electrode 110 is formed, a pixel defining pattern 400 can be formed. For example, a pixel defining film is coated on the base substrate 01 which is formed with the aforementioned patterns, and the pixel defining pattern 400 is formed by means of mask, exposure and development processes. For example, the pixel defining pattern 400 in the display region includes a plurality of pixel defining portions, a plurality of first openings 410 and a plurality of second openings 420 are formed between adjacent pixel defining portions, and the pixel defining film in the first openings 410 and the second openings 420 are developed to expose at least part of the surfaces of the first electrodes 110 of the plurality of sub-pixels, the shielding portions 300 and part of the insulating layer 200, respectively.

For example, as shown in FIGS. 3 and 5A-5D, the pixel defining portion of the pixel defining pattern 400 may not overlap with the shielding portion 300. But not limited thereto, the pixel defining portion of the pixel defining pattern 400 may cover part of the shielding portion 300, or the pixel defining portion of the pixel defining pattern 400 may completely cover the shielding portion 300.

For example, as shown in FIGS. 3 and 5A-5D, after the pixel defining pattern 400 is formed, spacers 012 can be formed on the pixel defining portions, and the forming method of the spacers 012 can be the same as that shown in FIG. 4B, and details will not be repeated here.

For example, as shown in FIGS. 3 and 5A-5D, after the spacers 012 are formed, the part other than the second opening 420 can be masked to dry etch the insulating layer 200 in the second opening 420, so as to form a groove 210, and the edge of the shielding portion 300 and the edge of the groove 210 form an undercut structure. In this case, the shielding portion 300 includes a protrusion 310 protruding into the groove 210.

For example, as shown in FIGS. 3 and 5A-5D, after the groove 210 is formed, a light-emitting functional layer 130 and a second electrode 120 are sequentially formed. For example, the light-emitting functional layer 130 being formed will be disconnected at the protrusion 310 of the shielding portion 300, so that a part of the light-emitting functional layer 130 is located at the edge of the shielding portion 300, and another part of the light-emitting functional layer 130 is deposited in the groove 210. For example, as shown in FIG. 4B, the second electrode 120 being formed will be disconnected at the protrusion 310 of the shielding portion 300, so that a part of the second electrode 120 is located at the edge of the shielding portion 300, and another part of the second electrode 120 is deposited in the groove 210.

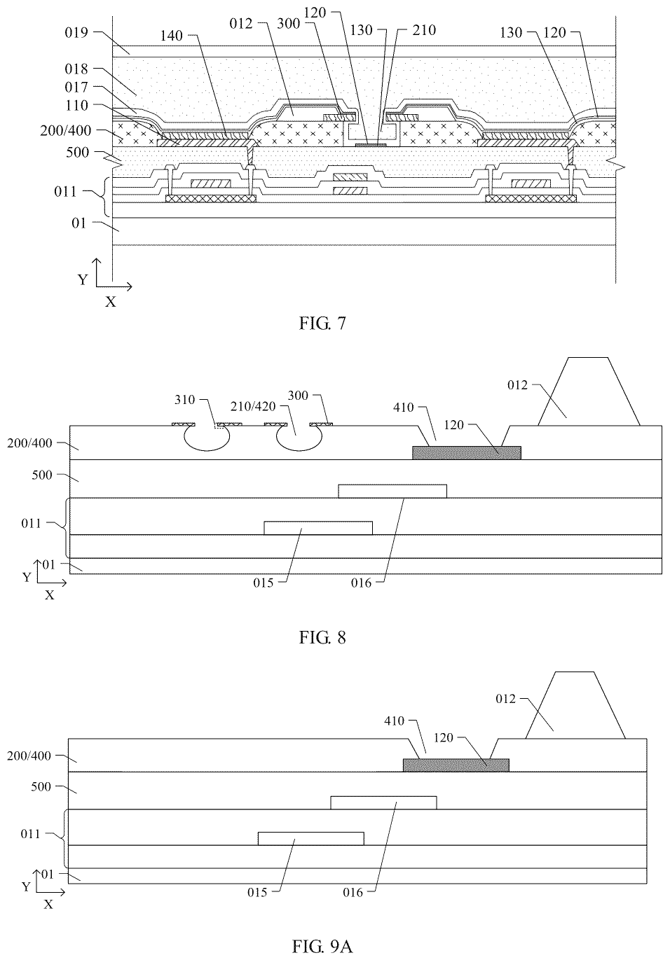

For example, FIG. 6 is a partial cross-sectional structural view of a display substrate provided by another example of one embodiment of the present disclosure, and FIG. 7 is a schematic diagram showing a light-emitting functional layer and multi-layer film layers at one side of the light-emitting functional layer away from a base substrate on the basis of the display substrate shown in FIG. 6. The film layers, such as the base substrate 01, other film layers 011, the light-emitting functional layer 130, the second electrode 120, the spacers 012 and the encapsulation layer, etc., in the display substrate shown in FIGS. 6 and 7 can have the same features as the film layers, such as the base substrate 01, other film layers 011, the light-emitting functional layer 130, the second electrode 120, the spacers 012 and the encapsulation layer, etc., shown in FIGS. 2 and 4A-4B. The display substrate in the example shown in FIG. 6 is different from the display substrates shown in FIGS. 1A-5D in that the insulating layer 200 shown in FIG. 6 includes the pixel defining pattern 400, that is, the pixel defining pattern 400 includes the groove 210, while the planarization layer 500 does not include the groove 210.

For example, as shown in FIGS. 6 and 7, along the X direction, the size of the groove 210 can be less than the size of the first opening 410.

For example, as shown in FIGS. 6 and 7, the shielding portion 300 is located at one side of the pixel defining pattern 400 away from the base substrate 01. For example, as shown in FIGS. 6 and 7, the groove 210 includes a second opening 420 penetrating the pixel defining portion of the pixel defining pattern 400. But it is not limited thereto. For example, the ratio of the depth of the groove 210 to the thickness of a planar part of the pixel defining portion in the pixel defining pattern 400 is greater than or equal to 0.2 and less than 1. For example, the ratio of the depth of the groove 210 to the thickness of a planar part of the pixel defining portion in the pixel defining pattern 400 is in the range of 0.1-1. For example, the ratio of the depth of the groove 210 to the thickness of the pixel defining portion in the pixel defining pattern 400 can be in the range of 0.2-0.9. For example, the ratio of the depth of the groove 210 to the thickness of the pixel defining portion in the pixel defining pattern 400 can be in the range of 0.3-0.8. For example, the ratio of the depth of the groove 210 to the thickness of the pixel defining portion in the pixel defining pattern 400 can be in the range of 0.4-0.7. For example, the ratio of the depth of the groove 210 to the thickness of the pixel defining portion in the pixel defining pattern 400 can be in the range of 0.5-0.6. The thickness of the pixel defining portion in the embodiment of the present disclosure can refer to the average thickness of the pixel defining portion, but not limited thereto, and can also refer to the thickness at the position of the maximum thickness of the pixel defining portion or the thickness at the position of the minimum thickness of the pixel defining portion.

For example, the depth of the groove 210 in the pixel defining pattern 400 can be greater than the thickness of the light-emitting functional layer 130, so that both the light-emitting functional layer 130 and the second electrode 120 are disconnected at the protrusion 310 of the shielding portion 300. For example, the depth of the groove 210 can also be set smaller, so that the light-emitting functional layer 130 is disconnected at the protrusion 310 of the shielding portion 300, while the second electrode 120 is not disconnected at the protrusion 310.

For example, as shown in FIGS. 6 and 7, the spacer 012 can cover a part of the shielding portion 300. But it is not limited thereto. For example, the spacer 012 can completely cover the shielding portion 300, or the spacer 012 may not overlap with the shielding portion 300.

For example, as shown in FIGS. 6 and 7, a conductive layer 140 is disposed between the first electrode 110 and the light-emitting functional layer 130, and the material of the conductive layer 140 is the same as the material of the shielding portion 300. For example, the material of the conductive layer 140 can be the same as the material of the first electrode 110. For example, the conductive layer 140 located between the first electrode 110 and the light-emitting functional layer 130 can be electrically connected to the first electrode 110, so as to work together with the first electrode 110 to excite the light-emitting functional layer to emit light.

Of course, the embodiment of the present disclosure is not limited thereto, and there may be no film layer provided between the first electrode 110 and the light-emitting functional layer 130, and the first electrode 110 is in contact with the light-emitting functional layer 130.

For example, the materials of the conductive layer 140 and the shielding portion 300 can include a metallic material (e.g., titanium, aluminum, silver, etc.) or a metal oxide (e.g., indium tin oxide), etc.

For example, FIG. 8 is a partial cross-sectional structural view of a display substrate provided by another example of one embodiment of the present disclosure. The base substrate 01 and other film layers 011 in the display substrate shown in the example of FIG. 8 can have the same features as the base substrate 01 and other film layers 011 shown in FIG. 3, and details will not be repeated here. The display substrate in the example shown in FIG. 8 is different from the display substrates shown in FIGS. 1A-5D in that the insulating layer 200 shown in FIG. 8 includes a pixel defining pattern 400, that is, the pixel defining pattern 400 includes the groove 210, while the planarization layer 500 does not include the groove 210. The groove 210 in the pixel defining pattern 400 as shown in FIG. 8 can have the same features, such as shape, size, etc., as the groove 210 in the planarization layer as shown in FIG. 3, and details will not be repeated here.

For example, as shown in FIG. 8, in the X direction, the size of the groove 210 can be less than the size of the first opening 410.

For example, as shown in FIG. 8, the shielding portion 300 is located at one side of the pixel defining pattern 400 away from the base substrate 01. For example, as shown in FIG. 8, the ratio of the depth of the groove 210 to the thickness of the pixel defining portion in the pixel defining pattern 400 can be in the range of 0.2-0.9. For example, the ratio of the depth of the groove 210 to the thickness of the pixel defining portion in the pixel defining pattern 400 can be in the range of 0.4-0.7. For example, the ratio of the depth of the groove 210 to the thickness of the pixel defining portion in the pixel defining pattern 400 can be in the range of 0.5-0.6. The thickness of the pixel defining portion in the embodiment of the present disclosure can refer to the average thickness of the pixel defining portion, but not limited thereto, and can also refer to the thickness at the position of the maximum thickness of the pixel defining portion or the thickness at the position of the minimum thickness of the pixel defining portion.

In the present example, the groove 210 may not be an opening penetrating the pixel defining portion, so as to avoid etching the planarization layer and avoid the second conductive layer pattern 016 from being influenced.

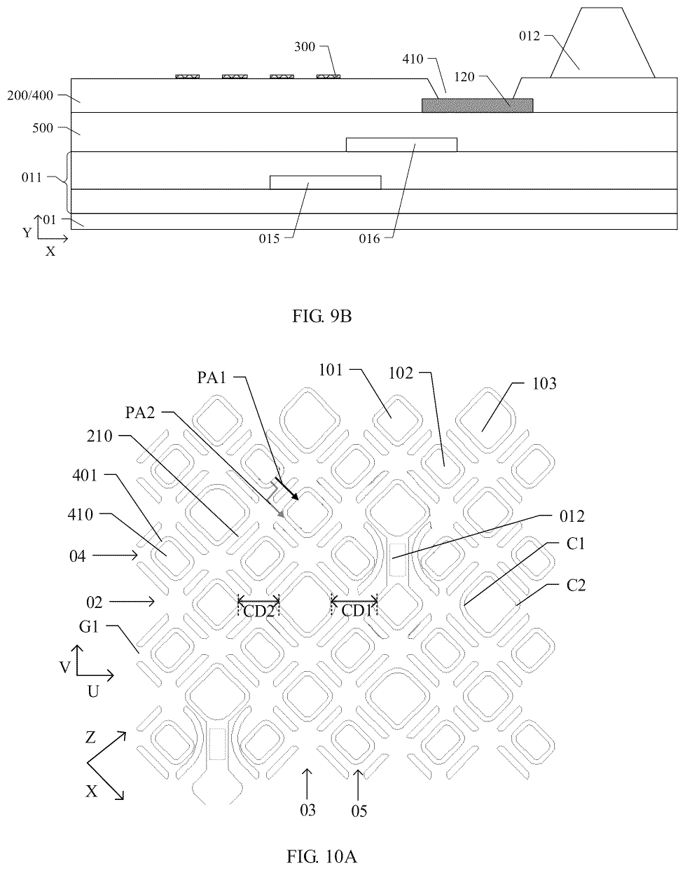

For example, FIGS. 9A-9B are flow charts of a manufacturing method of a display substrate before the formation of the structure shown in FIG. 8. For example, as shown in FIGS. 8-9B, the manufacturing method of the display substrate includes: forming a plurality of sub-pixels on a base substrate 01, wherein forming the sub-pixels includes sequentially forming a first electrode 110, a light-emitting functional layer 130 and a second electrode 120 which are stacked in a direction perpendicular to the base substrate 01; forming an insulating layer 200 on the base substrate 01; forming a shielding portion material layer on the insulating layer 200, and patterning the shielding portion material layer to form a plurality of shielding portions 300, wherein the shielding portion 300 is located between adjacent sub-pixels, and at least two shielding portions 300 are arranged between adjacent sub-pixels along an arrangement direction of the adjacent sub-pixels and spaced apart from each other; and etching the insulating layer 200 to form a groove 210. The opening edge of the groove 210 extends outward relative to the edges, close to each other, of two adjacent shielding portions 300, so that the shielding portion 300 includes a protrusion 310 protruding into the groove 210 in the arrangement direction. After the groove 210 is formed, a light-emitting functional layer 130 is formed on the insulating layer 200, the light-emitting functional layer 130 includes a charge generation layer 133, and the charge generation layer 133 is disconnected at the protrusion 310 of the shielding portion 300.

For example, as shown in FIGS. 8-9B, before the insulating layer 200 is formed, the manufacturing method further includes: forming an electrode layer on the base substrate 01 and patterning the electrode layer to form the first electrode 110; forming the insulating layer 200 includes: forming a pixel defining film (i.e., the insulating layer 200) on the first electrode 110, and patterning the pixel defining film to form a groove 210 and a first opening 410 exposing the first electrode 110, the first opening 410 is configured to define a light-emitting region of the sub-pixel.

For example, as shown in FIGS. 8-9B, after the first opening 410 is formed, spacers 012 are formed on the insulating layer 200.

For example, as shown in FIGS. 8-9B, after the spacers 012 are formed, a shielding portion material layer is formed on the insulating layer 200, and the shielding portion material layer is patterned to form a shielding portion 300. For example, the material of the shielding portion 300 can include any one or more of silicon nitride, silicon oxide or silicon oxynitride.

For example, as shown in FIGS. 8-9B, after the shielding portion 300 is formed, a region at the outer side of the shielding portion 300 is covered by a mask to dry etch the insulating layer 200 between adjacent shielding portions 300, so as to form a groove 210, and the edge of the shielding portion 300 and the edge of the groove 210 form an undercut structure. In this case, the shielding portion 300 includes a protrusion 310 protruding into the groove 210.

For example, FIGS. 10A-10E are planar structural views of a display substrate provided by an embodiment of the present disclosure. The groove 210 and the shielding portion 300 in the above-mentioned embodiments shown in FIGS. 1A-9B form an isolation structure, which is configured to isolate the charge generation layer 133 in the light-emitting functional layer 130.

For example, as shown in FIGS. 10A-10E, the plurality of sub-pixels 10 includes a plurality of first color sub-pixels 101, a plurality of second color sub-pixels 102, and a plurality of third color sub-pixels 103. For example, one of the first color sub-pixel 101 and the third color sub-pixel 103 emits red light and the other emits blue light; and the second color sub-pixel 102 emits green light. FIGS. 10A-10E illustratively show that the first color sub-pixel 101 emits red light and is a red sub-pixel; the third color sub-pixel 103 emits blue light and is a blue sub-pixel; and the second color sub-pixel 102 emits green light and is a green sub-pixel.

For example, as shown in FIGS. 10A-10E, the plurality of first color sub-pixels 101 and the plurality of third color sub-pixels 103 are alternately arranged along a first direction and a second direction parallel to the base substrate 01 (for example, one of the first direction and the second direction can be the U direction shown in the figure and the other is the V direction shown in the figure) to form a plurality of first pixel rows 02 and a plurality of first pixel columns 03, the plurality of second color sub-pixels 101 are arrayed along the first direction and the second direction to form a plurality of second pixel rows 04 and a plurality of second pixel columns 05, the plurality of first pixel rows 02 and the plurality of second pixel rows 04 are alternately arranged along the second direction and shifted from each other in the first direction, and the plurality of first pixel columns 03 and the plurality of second pixel columns 05 are alternately arranged along the first direction and shifted from each other in the second direction.

For example, the groove 210 includes an annular groove, and the annular groove surrounds one first color sub-pixel 101, one second color sub-pixel 102, or one third color sub-pixel 103. For example, at least some annular grooves include at least one notch G1, and orthographic projections of the shielding portions 300 on the base substrate are located on both sides of the groove 210 in a direction perpendicular to the extending direction of the orthographic projection of the groove 210 on the base substrate 01. For example, in the case where the shape of the orthographic projection of the groove 210 on the base substrate 01 is a stripe shape, the extending direction of the orthographic projection refers to the extending direction of the stripe shape; in the case where the shape of the orthographic projection of the groove 210 on the base substrate 01 is an arc shape, the extending direction of the orthographic projection refers to the extending direction of the edge of the arc shape; in the case where the shape of the orthographic projection of the groove 210 on the base substrate 01 is an annular shape, the extending direction of the orthographic projection refers to the extending direction of the edge of the annular shape.

For example, at least a part of the boundary of the groove 210 has approximately the same contour as the boundary of the light-emitting region of the sub-pixel 10 immediately adjacent thereto. For example, the boundary contour of the light-emitting region of the sub-pixel 10 can include a plurality of straight edges and/or arc edges connecting adjacent straight edges, and the boundary contour of the groove 210 surrounding the light-emitting region can include straight edge contours corresponding to the straight edges of the light-emitting region and/or arc edge contours corresponding to the arc edges of the light-emitting region.

For example, along the direction perpendicular to the extending direction of the orthographic projection of the groove 210 on the base substrate 01, the ratio of the size of the orthographic projection of the protrusion of the shielding portion 300 protruding into the groove 210 on the base substrate 01 to the size of the orthographic projection of the shielding portion 300 on the base substrate 01 is in the range of 0.005-0.5. For example, the ratio of the above sizes can be in the range of 0.01-0.4. For example, the ratio of the above sizes can be in the range of 0.05-3. For example, the ratio of the above sizes can be in the range of 0.1-2. For example, the ratio of the above sizes can be in the range of 0.5-1.

For example, along a direction perpendicular to the extending direction of the orthographic projection of the groove 210 and parallel to the base substrate 01, two shielding portions 300 located at both sides of the edges of the groove 210 have the same size, and the two shielding portions 300 protrude into the groove 210 with the same size.

For example, as shown in FIGS. 10A-10E, the groove 210 is located between the first color sub-pixel 101 and the third color sub-pixel 103 adjacent to each other, and/or the groove 210 is located between the second color sub-pixel 102 and the third color sub-pixel 103 adjacent to each other, and/or the groove 210 is located between the first color sub-pixel 101 and the second color sub-pixel 102 adjacent to each other.

For example, as shown in FIG. 10A, in an example of one embodiment of the present disclosure, the pixel defining portion 401 of the pixel defining pattern includes a circle of structure surrounding each first opening 410 and a structure between the spacer 012 and the base substrate 01, and part of the pixel defining portion between adjacent first openings 410 is removed to facilitate the formation of the groove 210 in the planarization layer. However, it is not limited thereto, and the pixel defining portion can also be provided at positions other than the position corresponding to the groove 210 and the first opening 410. For example, in the case where the groove is located in the pixel defining pattern, the pixel defining portion between adjacent first openings 410 cannot be removed.

For example, two adjacent sub-pixels 10 shown in FIG. 1A can be arranged along the X direction shown in FIG. 10A. For example, the two adjacent sub-pixels 10 shown in FIG. 1A can be the second color sub-pixel 102 and the first color sub-pixel 101, or can be third color sub-pixel 103 and the second color sub-pixel 102.

For example, as shown in FIGS. 1A-3, 6, 7 and 10A-10B, in the case where there is no groove 210 between two adjacent sub-pixels arranged along the X direction, such as the first color sub-pixel 101 and the second color sub-pixel 102, the charge generation layers 133 of these two sub-pixels will be conducted along the path PA1 which is short in size, thus easily causing crosstalk between these two sub-pixels; in the case where the groove 210 and the shielding portion 300 are arranged between the first color sub-pixel 101 and the second color sub-pixel 102 so that the charge generation layer 133 is disconnected in the X direction, the charge generation layers 133 of these two sub-pixels will be conducted along the path PA2 which is longer than the path PA1 (for example, the path PA2 can be increased by 0.5 times compared with the path PA1), thus increasing the resistance of the charge generation layer 133 at the gap between these two sub-pixels and being helpful to reduce the probability of crosstalk between two adjacent sub-pixels.

For example, as shown in FIGS. 1A-3, 6, 7 and 10A-10B, the shapes of the light-emitting regions of at least some sub-pixels are rectangular shapes, and the shapes of at least some grooves 210 are long-stripe shape, the extending direction (X direction or Z direction) of the long-strip shape is parallel to the extending direction of a side of the rectangular shape of the light-emitting region of the sub-pixel adjacent thereto, and the shielding portions 300 are located on both sides of the groove 210 in a direction perpendicular to the extending direction of the groove 210. For example, the groove 210 located between two adjacent sub-pixels 10 arranged along the X direction can extend in the Z direction, and the groove 210 located between two adjacent sub-pixels 10 arranged along the Z direction can extend in the X direction.

For example, as shown in FIGS. 1A-3, 6, 7 and 10A-10B, the grooves 210 can be arranged around the sub-pixel 10, and have a fracture at the corner position of the light-emitting region of the sub-pixel 10. For example, the distance between the light-emitting regions of two adjacent sub-pixels arranged along the X direction or the Z direction is less than the distance between the light-emitting regions of two adjacent sub-pixels arranged along the U direction or the V direction, so a groove 210 can be arranged between the light-emitting regions of two adjacent sub-pixels arranged along the X direction or the Z direction, and no groove 210 may be arranged between two adjacent sub-pixels arranged along the U direction or the V direction, thus ensuring the connection of the second electrodes of the sub-pixels and reducing the resistance of the second electrodes to reduce power consumption.

For example, as shown in as shown in FIGS. 1A-3, 6, 7 and 10A-10B, the number of grooves 210 surrounding the light-emitting region of one sub-pixel can be four, and the four grooves 210 are parallel to the four sides of the light-emitting region respectively.

For example, as shown in FIGS. 10A-10B, the corners of the light-emitting region of the third color sub-pixel 103 includes a first corner C1 and a second corner C2 which are oppositely arranged, and the distance from the intersection point of the extension lines or tangents of two edges constituting the first corner C1 to the center of the sub-pixel is greater than the distance from the intersection point of the extension lines or tangents of two edges constituting the second corner C2 to the center of the sub-pixel. The third sub-pixel 103 includes a first type sub-pixel and a second type sub-pixel, and in different types of sub-pixels, the directions in which the vertex of the first corner C1 points to the vertex of the second corner C2 are different. In the first type sub-pixel and the second type sub-pixel, the directions in which the vertex of the first corner C1 points to the vertex of the second corner C2 are respectively a first pointing direction and a second pointing direction, and the first pointing direction and the second pointing direction are opposite to each other. For example, the first pointing direction can be the direction indicated by the arrow of the U direction, the second pointing direction can be a direction opposite to the direction indicated by the arrow of the U direction, and the first pointing direction and the second pointing direction can be interchanged; for example, the first pointing direction can also be the direction indicated by the arrow of the V direction, the second pointing direction can also be a direction opposite to the direction indicated by the arrow of the V direction, and the first pointing direction and the second pointing direction can be interchanged.

For example, as shown in FIGS. 10A-10B, the first corner C1 of the light-emitting region of the third color sub-pixel 103 can be a rounded corner, and the distance between the first corner C1 of the light-emitting region of the third color sub-pixel 103 and a corner of the light-emitting region of the first color sub-pixel 101 opposite to the first corner C1 is a first corner distance CD1, the distance between the second corner C2 of the light-emitting region of the third color sub-pixel 103 and a corner of the light-emitting region of the first color sub-pixel 101 opposite to the second corner C2 is a second corner distance CD2, and the first corner distance CD1 is greater than the second corner distance CD2. Therefore, the spacer 012 can be arranged at the position of the gap corresponding to the first corner.

For example, as shown in FIGS. 10A-10B, the shape of the groove 210 near the spacer 012 can be different from the shape of the groove 210 at other positions. For example, the planar shape of the groove 210 arranged between the spacer 012 and the second color sub-pixel 102 on both sides of the spacer 012 can be arc-shaped, and this groove 210 surrounds a corner of the light-emitting region of a corresponding second color sub-pixel. For example, the groove 210 between a certain second color sub-pixel 102 and a first color sub-pixel 101 adjacent to the certain second color sub-pixel 102 is a first sub-groove, and the groove 210 between the certain second color sub-pixel 102 and a third color sub-pixel 103 adjacent to the certain second color sub-pixel 102 is a second sub-groove. The first sub-groove and the second sub-groove can be integrated into a curved groove 210, and the curved groove 210 is located between the spacer 012 and the second color sub-pixel 102 and is bent towards the second color sub pixel 102.

The rounder corner described above can refer to a corner formed by a curved line, and the curved line can be an arc or an irregular curved line, such as a curved line cut in an ellipse, a wavy line, etc. The embodiment of the present disclosure illustratively shows that the curved line has an outward convex shape relative to the center of the sub-pixel, but not limited thereto, and the curved line can also have an inward concave shape relative to the center of the sub-pixel. For example, in the case where the curved line is an arc, the central angle of the arc can range from 10 degrees to 150 degrees. For example, the central angle of the arc can range from 60 degrees to 120 degrees. For example, the central angle of the arc can be 90 degrees. For example, the length of the curved line of the round corner included in the first corner C1 can be in the range of 10-60 microns.

For example, as shown in FIGS. 10A-10B, a plurality of shielding portions 300 are arranged between adjacent sub-pixels along the arrangement direction of the two adjacent sub-pixels and spaced apart from each other, one groove 210 is arranged between two adjacent shielding portions 300 among the plurality of shielding portions 300 arranged between adjacent sub-pixels, and two shielding portions 300 located at both sides of the edges of the groove 210 protrude into the groove 210.

For example, as shown in FIGS. 10A-10B, the distance between the light-emitting regions of the first color sub-pixel 101 and the second color sub-pixel 102 which are arranged along the Z direction and adjacent to each other is relatively small, the groove 210 between the two light-emitting regions extends in the X direction, and the shielding portions 300 can be located at both sides of the groove 210 in the Z direction and protrude into the groove 210 to form a protrusion (the edge of the shielding portion 300 and the edge of the groove 210 jointly form an undercut structure). Therefore, the charge generation layers of the first color sub-pixel 101 and the second color sub-pixel 102 will be disconnected at the protrusion, so as to avoid crosstalk between the two sub-pixels.

For example, as shown in FIGS. 10A-10B, the groove 210 between the first color sub-pixels 101 and the second color sub-pixels 102 which are arranged along the Z direction and adjacent to each other extends in the X direction, the shielding portions 300 can be located at both sides of the groove 210 in the Z direction, and the shielding portions may not be provided at both sides of the groove 210 in the X direction, so that the light-emitting functional layer and the second electrode passing through only the groove 210 in the X direction will not be disconnected, thus ensuring the connection of the second electrode in the X direction and reducing the resistance of the second electrode.

For example, as shown in FIGS. 10A-10B, because the distance between the light-emitting regions of two adjacent sub-pixels arranged along at least one direction of the U direction and the V direction is greater than the distance between the light-emitting regions of two adjacent sub-pixels arranged along the X direction (or the Y direction), grooves and shielding portions may not be provided between the light-emitting regions of two adjacent sub-pixels arranged along at least one direction of the U direction and the V direction.

For example, as shown in FIGS. 10C-10E, at least one sub-pixel is surrounded by one circle of discontinuous grooves 210. For example, as shown in FIGS. 10C-10E, each sub-pixel is surrounded by one circle of discontinuous grooves 210. FIGS. 10A and 10C-10E only illustratively show the groove 210, and the shielding portion in each figure can be set according to the positional relationship between the shielding portion 300 and the groove 210 as shown in FIG. 10B.

For example, as shown in FIG. 10C, in two adjacent sub-pixels arranged along the X direction or the Z direction, the corner of the light-emitting region of one sub-pixel is surrounded by the groove 210, and the edge of the light-emitting region of the other sub-pixel is surrounded by the groove 210. For example, in the first color sub-pixel 101 and the second color sub-pixel 102 arranged along the X direction or the Z direction, the corner of the light-emitting region of the second color sub-pixel 102 is surrounded by the groove 210, and the edge of the light-emitting region of the first color sub-pixel 101 is surrounded by the groove 210. For example, in the third color sub-pixel 103 and the second color sub-pixel 102 arranged along the X direction or the Z direction, the corner of the light-emitting region of the second color sub-pixel 102 is surrounded by the groove 210, and the edge of the light-emitting region of the third color sub-pixel 103 is surrounded by the groove 210. In the display substrate provided by an example of one embodiment of the present disclosure, in the light-emitting regions of two adjacent sub-pixels arranged along the X direction or the Z direction, a groove is arranged corresponding to the edge of one light-emitting region, and a groove is arranged corresponding to the corner of the other light-emitting region, so that not only the charge generation layer in the shortest interval (having the path PA1 shown in FIG. 10A) between the two light-emitting regions can be disconnected, but also the charge generation layer in the longer interval (having the path PA2 shown in FIG. 10A) between the two light-emitting regions can also be disconnected.

For example, as shown in FIG. 10C, the grooves 210 at the edges of the light-emitting regions of the second color sub-pixels 102 located at both sides of the spacer 012 can be continuously curved grooves 210 surrounding three corners and two edges of the light-emitting region of the second color sub-pixel.

For example, the display substrate shown in FIG. 10D is different from the display substrate shown in FIG. 10C in that the edge of the light-emitting region of the second color sub-pixel 102 is surrounded by the groove 210, and the corners of the light-emitting regions of the first color sub-pixel 101 and the third color sub-pixel 103 are surrounded by the grooves 210.

For example, the display substrate shown in FIG. 10E is different from the display substrate shown in FIG. 10C in that a groove 210 is added at the gap between the first color sub-pixel 101 and the third color sub-pixels 103 which are adjacent to each other along at least one direction of the U direction and the V direction, so that the charge generation layers of two adjacent sub-pixels arranged along different directions are disconnected as much as possible under the combined action of the groove 210 and the shielding portion. For example, in each direction of the U direction and the V direction, a groove is added at the gap between the first color sub-pixel 101 and the third color sub-pixels 103 which are adjacent to each other.

Another embodiment of the present disclosure provides a display device, which includes any of the display substrates shown in FIGS. 1A-10E. By arranging a groove and a shielding portion protruding into the groove between adjacent sub-pixels in the display device, the charge generation layer of the light-emitting functional layer can be disconnected at the protrusion of the shielding portion relative to the edge of the groove, which is helpful to reduce the probability of crosstalk between adjacent sub-pixels.

For example, the display device further includes a cover plate located at the light-exiting side of the display panel.

For example, the display device can be a display, such as an organic light-emitting diode display, etc., or any product or component having display function and including the display, such as a TV, a digital camera, a mobile phone, a watch, a tablet computer, a notebook computer, a navigator, etc., without being limited in the present embodiment.

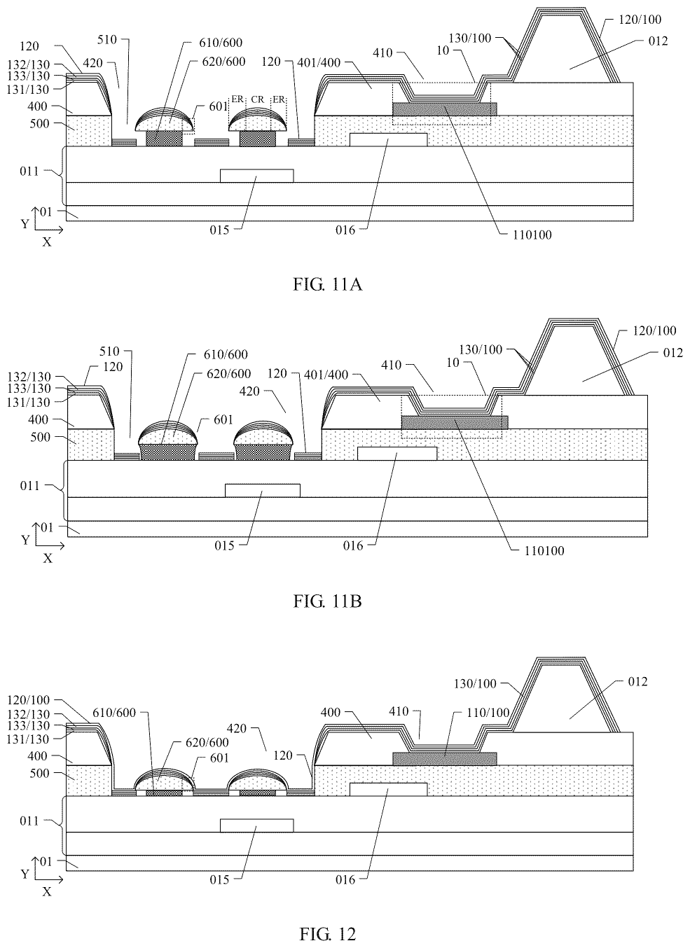

FIG. 11A is a partial cross-sectional structural view of a display substrate provided by an example of another embodiment of the present disclosure, and FIG. 11B is a partial cross-sectional structural view of a display substrate provided by another example of another embodiment of the present disclosure. The display substrate shown in FIG. 11A can have the same first display region A1 and second display region A2 as the display substrate shown in FIG. 1C. As shown in FIGS. 11A-11B, the display substrate includes a base substrate 01 and a plurality of sub-pixels 10 in the first display region A1 of the base substrate 01. The sub-pixel 10 includes an organic light-emitting element 100, the organic light-emitting element 100 includes a light-emitting functional layer 130 and a first electrode 110 and a second electrode 120 located at both sides of the light-emitting functional layer 130 along the direction perpendicular to the base substrate 01, the first electrode 110 is located between the light-emitting functional layer 130 and the base substrate 01, and the light-emitting functional layer 130 includes a plurality of film layers. For example, the plurality of film layers includes a charge generation layer 133.

As shown in FIG. 11A, the display substrate further includes a plurality of isolation structures 600, and at least one isolation structure 600 is arranged between adjacent sub-pixels 10. The isolation structure 600 includes a first sub-isolation structure 610 and a second sub-isolation structure 620 which are stacked, and the first sub-isolation structure 610 is located at one side of the second sub-isolation structure 620 facing the base substrate 01. In the arrangement direction of adjacent sub-pixels 10, the size of the first sub-isolation structure 610 in the isolation structure 600 between the adjacent sub-pixels 10 is less than the size of the second sub-isolation structure 620, so that the second sub-isolation structure 620 includes a part protruding relative to the edge of the first sub-isolation structure 610. For example, the material of the first sub-isolation structure 610 and the material of the second sub-isolation structure 620 both include the same element, or the material of the first sub-isolation structure 610 and the material of the second sub-isolation structure 620 both include metal. For example, the material of the first sub-isolation structure 610 includes an inorganic non-metallic material or a metallic material or metal oxide, and the material of the second sub-isolation structure 620 includes an organic material.

As shown in FIG. 11B, a slope angle between at least part of a side surface of the first sub-isolation structure 610 and a plane parallel to a contact surface of the first sub-isolation structure 610 and the second sub-isolation structure 620 is greater than 60 degrees and less than 120 degrees, and/or a slope angle between at least part of a side surface of the second sub-isolation structure 620 and the plane parallel to the contact surface of the first sub-isolation structure 610 and the second sub-isolation structure 620 is greater than 60 degrees and less than 120 degrees. For example, the slope angle between at least part of the side surface of the first sub-isolation structure 610 and the plane parallel to the contact surface of the first sub-isolation structure 610 and the second sub-isolation structure 620 is greater than 70 degrees and less than 110 degrees, and/or the slope angle between at least part of the side surface of the second sub-isolation structure 620 and the plane parallel to the contact surface of the first sub-isolation structure 610 and the second sub-isolation structure 620 is greater than 70 degrees and less than 110 degrees. For example, the slope angle between at least part of the side surface of the first sub-isolation structure 610 and the plane parallel to the contact surface of the first sub-isolation structure 610 and the second sub-isolation structure 620 is greater than 80 degrees and less than 100 degrees, and/or the slope angle between at least part of the side surface of the second sub-isolation structure 620 and the plane parallel to the contact surface of the first sub-isolation structure 610 and the second sub-isolation structure 620 is greater than 80 degrees and less than 100 degrees.

The slope angle between at least part of the side surface of the first sub-isolation structure and the plane parallel to the contact surface of the first sub-isolation structure and the second sub-isolation structure can be an included angle between the surface of the first sub-isolation structure away from the base substrate and the side surface of the first sub-isolation structure, and can also be an included angle between the surface of the first sub-isolation structure facing the base substrate and the side surface of the first sub-isolation structure; the slope angle between at least part of the side surface of the second sub-isolation structure and the plane parallel to the contact surface of the first sub-isolation structure and the second sub-isolation structure can be an included angle between the surface of the second sub-isolation structure away from the base substrate and the side surface of the second sub-isolation structure, and can also be an included angle between the surface of the second sub-isolation structure facing the base substrate and the side surface of the second sub-isolation structure. The side surface of the first sub-isolation structure can refer to a surface of the first sub-isolation structure having a certain included angle with the base substrate, and the side surface of the second sub-isolation structure can refer to a surface of the second sub-isolation structure having a certain included angle with the base substrate.

The difference between the examples shown in FIG. 11A and FIG. 11B lies in the positional relationship and the angular relationship between the first sub-isolation structure 610 and the second sub-isolation structure 620.

As shown in FIGS. 11A-11B, at least one film layer among the plurality of film layers included in the light-emitting functional layer 130 is disconnected at the isolation structure 600. For example, the light-emitting functional layer 130 includes a charge generation layer 133, and the charge generation layer 133 is disconnected at the edge of the isolation structure 600.

In the embodiment of the present disclosure, the isolation structure is arranged between adjacent sub-pixels in the display substrate. By adjusting the relative positional relationship between the first sub-isolation structure and the second sub-isolation structure, or adjusting the angle of the side surface of the first sub-isolation structure and the angle of the side surface of the second sub-isolation structure, at least one film layer of the light-emitting functional layer can be disconnected at the protrusion of the second sub-isolation structure relative to the edge of the first sub-isolation structure or at the edge of the isolation structure, which is helpful to reduce the probability of crosstalk between adjacent sub-pixels. In the embodiment of the present disclosure, by arranging the isolation structure between adjacent sub-pixels in the display substrate, the charge generation layer can be disconnected at the edge of the isolation structure, which is helpful to reduce the probability of crosstalk between adjacent sub-pixels.

The base substrate 01 and the organic light-emitting element 100 in the present embodiment can have the same features as the base substrate 01 and the organic light-emitting element 100 in the embodiments shown in FIGS. 1A-9B, and details will not be repeated here. Other film layers 011 in the present example can have the same features as other film layers 011 in the embodiment shown in FIGS. 1A-9B, and details will not be repeated here.

For example, the material of the first sub-isolation structure 610 is different from the material of the second sub-isolation structure 620.

For example, the material of the first sub-isolation structure 610 includes an inorganic non-metallic material or a metallic material, and the material of the second sub-isolation structure 620 includes an organic material.

For example, as shown in FIG. 11A, the plurality of sub-pixels 10 can include two adjacent sub-pixels 10 arranged along the X direction. For example, the plurality of isolation structures 600 provided between two adjacent sub-pixels 10 are arranged along the X direction. For example, at least one edge of the second sub-isolation structure 620 arranged between two adjacent sub-pixels 10 protrudes relative to the edge of the first sub-isolation structure 610 in the X direction, so as to form an isolation protrusion 601; the isolation protrusion 601 in the second sub-isolation structure 620 is suspended, so that the charge generation layer 133 of the sub-pixel 10 is disconnected at a position close to the at least one edge. For example, the isolation protrusion 601 extends in a direction parallel to the base substrate 01. For example, the orthographic projection of the isolation protrusion 601 on the base substrate 01 does not overlap with the orthographic projection of the first sub-isolation structure 610 on the base substrate 01.

For example, the first light-emitting layers 131 (the second light-emitting layers 132) of adjacent sub-pixels can overlap on the isolation structure 600. However, it is not limited thereto. For example, the first light-emitting layers 131 (the second light-emitting layers 132) of adjacent sub-pixels can be arranged at intervals on the isolation structure 600; alternatively, only the first light-emitting layer 131 (the second light-emitting layer 132) of one sub-pixel of the adjacent sub-pixels may be disposed on the isolation structure 600.

For example, part of the film layers of the light-emitting functional layer 130 and the second electrode 120 can be disposed on the isolation structure 600. For example, all of the film layers of the light-emitting functional layer 130 and the second electrode 120 can be disposed on the isolation structure 600.

For example, a first orthographic projection of at least one film layer in the light-emitting functional layer 130 on the base substrate 01 is continuous, and a second orthographic projection of the at least one film layer in the light-emitting functional layer 130 on a plane perpendicular to the base substrate 01 is discontinuous; alternatively, the first orthographic projection of at least one film layer in the light-emitting functional layer 130 on the base substrate 01 and the second orthographic projection of the at least one film layer in the light-emitting functional layer 130 on the plane perpendicular to the base substrate 01 are discontinuous, and the width of the gap at the discontinuous position of the first orthographic projection is less than the width of the gap at the discontinuous position of the second orthographic projection.

For example, at least one film layer in the light-emitting functional layer 130 can be a charge generation layer 133, and the first orthographic projection of the charge generation layer 133 on the base substrate 01 is continuous, and the second orthographic projection of the charge generation layer 133 on the plane perpendicular to the base substrate 01 is discontinuous. For example, the charge generation layer 133 can include a part located in the groove 210 and a part not located in the groove 210, and these two parts are disconnected at the edge of the groove 210. For example, the first orthographic projections of these two parts on the base substrate 01 can be connected or overlapped, and the first orthographic projections are continuous. For example, the distances between these two parts and the base substrate 01 are different, and the second orthographic projections of these two parts on the XY plane are discontinuous.

For example, at least one film layer in the light-emitting functional layer 130 can be a charge generation layer 133, the first orthographic projection of the charge generation layer 133 on the base substrate 01 and the second orthographic projection of the charge generation layer 133 on the plane perpendicular to the base substrate 01 are discontinuous, and the width of the gap at the discontinuous position of the first orthographic projection is less than the width of the gap at the discontinuous position of the second orthographic projection. For example, the charge generation layer 133 can include a part located on the isolation structure 600 and a part not located on the isolation structure 600, and these two parts are disconnected at the edge of the isolation structure 600. For example, there is a gap between the first orthographic projections of these two parts on the base substrate 01, and the first orthographic projections are disconnected. For example, the distances between these two parts and the base substrate 01 are different, the second orthographic projections of these two parts on the XY plane are discontinuous, and there is a gap between the second orthographic projections of these two parts on the XY plane.

For example, at least part of the film layers, located at one side of the charge generation layer 133 facing the base substrate 01, in the light-emitting functional layer 130, is disconnected at the isolation structure 600. For example, all of the film layers located at one side of the charge generation layer 133 facing the base substrate 01 and in the light-emitting functional layer 130 are disconnected at the isolation structure 600.

For example, the color of light emitted by the first light-emitting layer 131 is the same as the color of light emitted by the second light-emitting layer 132.

For example, the light-emitting functional layer 130 includes a light-emitting layer (a first light-emitting layer or a second light-emitting layer), and the area of the orthographic projection of at least one disconnected film layer in the light-emitting functional layer 130 on the base substrate 01 is greater than the area of the orthographic projection of the light-emitting layer (the first light-emitting layer or the second light-emitting layer) on the base substrate 01. For example, the disconnected film layer can be a common layer, and the light-emitting layer can be a patterned film layer formed by a fine metal mask.

For example, the light-emitting functional layer 130 includes at least one light-emitting layer (first light-emitting layer or second light-emitting layer), and at least one light-emitting layer and at least one other film layer are included in the film layers disconnected at the isolation structure 600. For example, the area of the orthographic projection of the at least one other film layer which is disconnected on the base substrate 01 is greater than the area of the orthographic projection of the at least one light-emitting layer which is disconnected on the base substrate 01. For example, the area of a part of the isolation structure 600 covered by the at least one other film layer which is disconnected is greater than the area of a part of the isolation structure 600 covered by the at least one light-emitting layer which is disconnected. For example, the at least one other film layer which is disconnected completely covers the isolation structure 600, and the at least one light-emitting layer which is disconnected covers only part of the isolation structure 600.

For example, at least one film layer among the plurality of film layers included in the light-emitting functional layer 130 and the second electrode 120 overlap in projection on the base substrate 01 with the isolation structure 600.

For example, at least one film layer among the plurality of film layers included in the light-emitting functional layer 130 at least partially covers a part of the side surface of the isolation structure 600. For example, the film layer described above can cover the side surface of the first sub-isolation structure 610 and/or cover the side surface of the second sub-isolation structure 620.

For example, as shown in FIG. 11A, two isolation structures 600 can be arranged between adjacent sub-pixels 10, and in each isolation structure 600, at least one edge of the second sub-isolation structure 620 protrudes relative to the edge of the first sub-isolation structure 610 in the X direction. For example, two isolation structures 600 can be arranged between adjacent sub-pixels 10, and two edges of the second sub-isolation structure 620 respective in the two isolation structures 600 both protrude relative to the edge of a corresponding first sub-isolation structure 610 in the X direction; alternatively, two edges of the second sub-isolation structure 620 in one isolation structure 600 protrude relative to the edge of the first sub-isolation structure 610 in the X direction, and one edge of the second sub-isolation structure 620 in the other isolation structure 600 protrudes relative to the edge of the first sub-isolation structure 610 in the X direction; alternatively, only one edge of the second sub-isolation structure 620 in the two isolation structures 600 protrudes relative to the edge of the first sub-isolation structure 610 in the X direction, which is not limited in the embodiment of the present disclosure and can be set according to actual product requirements. The embodiment of the present disclosure is not limited to the case of setting two isolation structures between adjacent sub-pixels, but can also include the case of setting one isolation structure or three or more isolation structures between adjacent sub-pixels.

For example, in the case where the isolation structure 600 is not provided between the two adjacent sub-pixels 10, the charge generation layer 133 in the light-emitting functional layer 130 of the two adjacent sub-pixels 10 can be connected or a whole-layer film layer. Because the charge generation layer 133 has a high conductivity, for a display device with high resolution, the high conductivity of the charge generation layer 133 easily leads to crosstalk between adjacent sub-pixels 10.

In the display substrate provided by the embodiment of the present disclosure, by setting the isolation structure between the two adjacent sub-pixels, at least one film layer (e.g., a charge generation layer) in the light-emitting functional layer formed at the edge of the isolation structure can be disconnected. And in this case, at least one film layer in the light-emitting functional layers of two adjacent sub-pixels is arranged at intervals, so that the resistance between the light-emitting functional layers of adjacent sub-pixels can be increased, thereby reducing the probability of crosstalk between the two adjacent sub-pixels without affecting the normal display of the sub-pixels.

For example, as shown in FIG. 11A, the distance between a surface of the isolation structure 600 facing the base substrate 01 and the base substrate 01 is less than the distance between a surface of the first electrode 110 facing the base substrate 01 and the base substrate 01.

For example, as shown in FIG. 11A, an organic layer 500 is disposed between the first electrode 110 and the base substrate 01, and the first electrode 110 is in contact with a surface of the organic layer 500.

For example, as shown in FIG. 11A, the material of the first sub-isolation structure 610 includes an inorganic material or a metallic material, and the material of the second sub-isolation structure 620 includes an organic material.

For example, the material of the first sub-isolation structure 610 can be one or a combination of silicon oxide and silicon nitride. But not limited to, the material of the first sub-isolation structure 610 can also be metal or metal oxide.

For example, in the direction perpendicular to the base substrate 01, the thickness of the first sub-isolation structure 610 can be greater than the thickness of the light-emitting functional layer 130, so that both the light-emitting functional layer 130 and the second electrode 120 are disconnected at the part of the second sub-isolation structure 620 protruding relative to the edge of the first sub-isolation structure 610, that is, at the isolation protrusion 601.

For example, the second sub-isolation structure 620 can be made of photosensitive polyimide.

For example, the second sub-isolation structure 620 is made of the same material as the organic layer 500. For example, the organic layer 500 can adopt the same material as the organic layer 500 shown in FIGS. 1A-9B, and details will not be repeated here.

For example, the second sub-isolation structure 620 and the organic layer 500 can be formed in the same step patterning process.

For example, as shown in FIG. 11A, the second sub-isolation structure 620 includes a central region and edge regions located at both sides of the central region, which are distributed along the arrangement direction of two sub-pixels 10 adjacent to the second sub-isolation structure 620, and along the direction perpendicular to the base substrate 01, the thickness of the central region of the second sub-isolation structure 620 is greater than the thickness of the edge region of the second sub-isolation structure 620.

For example, as shown in FIG. 11A, the second sub-isolation structure 620 includes a central region CR and an edge region ER surrounding the central region CR, and in the direction perpendicular to the base substrate 01, the thickness of the central region CR of the second sub-isolation structure 620 is greater than the thickness of the edge region ER of the second sub-isolation structure 620. The thickness of the central region can refer to an average thickness of the second sub-isolation structure in the central region or the maximum thickness of the second sub-isolation structure in the central region; the thickness of the second sub-isolation structure in the edge region can refer to an average thickness of the second sub-isolation structure in the edge region or the maximum thickness of the second sub-isolation structure in the edge region. For example, the average thickness of the second sub-isolation structure in the central region is greater than the average thickness of the second sub-isolation structure in the edge region, or the maximum thickness of the second sub-isolation structure in the central region is greater than the maximum thickness of the second sub-isolation structure in the edge region.

For example, in the direction pointing from the center of the second sub-isolation structure 620 to the edge of the second sub-isolation structure 620, the thickness of the second sub-isolation structure 620 can gradually decrease.

For example, the surface of the second sub-isolation structure 620 away from the base substrate 01 has a smooth transition. For example, the second sub-isolation structure 620 includes an upper surface and a side surface, both of which are continuous smooth surfaces.

For example, as shown in FIGS. 11A-11B, the slope angle of the surface, away from the first sub-isolation structure 610, of the part of the second sub-isolation structure 620 protruding relative to the edge of first sub-isolation structure 610 is less than the slope angle of at least part of the side surface of the first sub-isolation structure 610 and a plane parallel to the contact surface of the first sub-isolation structure 610 and the second sub-isolation structure 620.

For example, a side edge of the first sub-isolation structure 610 can be a curved edge or a straight edge, and for example, the side edge of the first sub-isolation structure 610 can be bent towards the center of the first sub-isolation structure 610. For example, the included angle between the side edge of the first sub-isolation structure 610 and the surface of the first sub-isolation structure 610 away from the base substrate 01 can be in the range of 60-90 degrees. For example, the included angle between the side edge of the first sub-isolation structure 610 and the surface of the first sub-isolation structure 610 close to the base substrate 01 can be in the range of 60-90 degrees. The included angle between the curved edge and a surface can refer to an included angle between the surface and the tangent at the intersection point of the curved edge and the surface. But not limited thereto, the included angle between the curved edge and a surface can also refer to the included angle between the tangent at the midpoint of the curved edge and the surface. For example, the included angle between the side edge of the second sub-isolation structure 620 and the surface of the second sub-isolation structure 620 close to the base substrate 01 can be in the range of 15-70 degrees.

For example, as shown in FIG. 11A, the organic layer 500 includes a plurality of organic layer openings 510, and the isolation structure 600 is located in the organic layer opening 510. In the embodiment of the present disclosure, the organic layer opening is arranged in the organic layer, and the isolation structure is arranged in the organic layer opening, so that the charge generation layers of adjacent sub-pixels are disconnected at the isolation protrusion of the isolation structure, which is helpful to reduce the probability of crosstalk between adjacent sub-pixels.

For example, the isolation structure 600 is spaced apart from the sidewall of the organic layer opening 510. For example, there is a gap between the isolation structure 600 and the pixel defining portion; for example, the gap can be 2 microns or more than 2 microns, the width of the isolation structure 600 can be 3 microns or more than 3 microns, the widths of the pixel defining portions at both sides are 4 microns or more than 4 microns, and the thickness of the isolation structure 600 is less than the thickness of the pixel defining portion.

For example, there is a certain space between the isolation structure 600 and the organic layer 500. For example, the minimum size of the space between the isolation structure 600 and the organic layer 500 is not less than 2 microns.

For example, in the case where one isolation structure 600 is disposed in one organic layer opening 510, the isolation structure 600 can be located in the middle of the organic layer opening 510. For example, in the case where a plurality of isolation structures 600 are disposed in one organic layer opening 510, the plurality of isolation structures 600 can be uniformly distributed. For example, one isolation structure 600 can be arranged between adjacent sub-pixels, the isolation structure 600 is close to one of the adjacent sub-pixels, and at least part of the light-emitting layer in the sub-pixel close to the isolation structure 600 is located on the isolation structure 600, while the light-emitting layer in the sub-pixel away from the isolation structure 600 may not cover the isolation structure 600.

For example, as shown in FIG. 11A, the greatest size of the isolation structure 600 in the X direction may be not less than 3 microns.

For example, as shown in FIG. 11A, in the direction perpendicular to the base substrate 01, the thickness of the first sub-isolation structure 610 can be less than the thickness of the organic layer 500. For example, the ratio of the thickness of the first sub-isolation structure 610 to the thickness of the organic layer 500 can be in the range of 0.1-0.9. For example, the ratio of the thickness of the first sub-isolation structure 610 to the thickness of the organic layer 500 can be in the range of 0.2-0.8. For example, the ratio of the thickness of the first sub-isolation structure 610 to the thickness of the organic layer 500 can be in the range of 0.3-0.7. For example, the ratio of the thickness of the first sub-isolation structure 610 to the thickness of the organic layer 500 can be in the range of 0.4-0.6. For example, the ratio of the thickness of the first sub-isolation structure 610 to the thickness of the organic layer 500 can be 0.5.

For example, as shown in FIG. 11A, in the direction perpendicular to the base substrate 01, the ratio of the thickness of the isolation structure 600 to the thickness of the organic layer 500 can be in the range of 0.8-1.2. For example, the ratio of the thickness of the isolation structure 600 to the thickness of the organic layer 500 can be in the range of 0.9-1.1. For example, the thickness of the isolation structure 600 and the thickness of the organic layer 500 can be equal. The embodiment of the present disclosure is not limited thereto, and for example, the thickness of the isolation structure 600 can be greater than the thickness of the organic layer 500.

For example, as shown in FIG. 11A, the pixel defining pattern 400 is located at one side of the organic layer 500 away from the base substrate 01. For example, the first opening 410 in the pixel defining pattern 400 can have the same features as the first opening 410 shown in FIGS. 1A-9B, and details will not be repeated here.

For example, as shown in FIG. 11A, the pixel defining pattern 400 further includes a plurality of second openings 420, the second opening is configured to expose the isolation structure 600, and a gap is provided between the isolation structure 600 and the pixel defining portion 401 of the pixel defining pattern 400.

For example, the second opening 420 is configured to expose at least part of the organic layer opening 510 and the isolation structure 600. For example, the orthographic projection of the second opening 420 of the pixel defining pattern 400 on the base substrate 01 can coincide with the orthographic projection of the organic layer opening 510 of the organic layer 500 on the base substrate 01. For example, the second opening 420 can completely expose the organic layer opening 510.

For example, as shown in FIG. 11A, the first conductive layer pattern 015 in the display substrate includes a first power signal line and a data line, the second conductive layer pattern 016 includes a second power signal line, and the second sub-isolation structure 620 is arranged in the same layer as the second conductive layer pattern 016. The first conductive layer pattern 015 and the second conductive layer pattern 016 in other film layers 011 in the embodiment of the present disclosure can have the same features as the first conductive layer pattern 015 and the second conductive layer pattern 016 shown in FIGS. 3 and 5A-5D, and details will not be repeated here.

For example, the shape of the orthographic projection of the isolation structure 600 on the base substrate 01 can be the same as the shape of the orthographic projection of the groove 210 on the base substrate 01 as shown in FIGS. 10A-10E. For example, the extending direction of the orthographic projection of the isolation structure 600 on the base substrate 01 can be different from the extending direction of at least one of the first power signal line, the data line and the second power signal line.

For example, as shown in FIG. 11A, the surface of the second sub-isolation structure 620 away from the base substrate 01 is a curved surface, and the curved surface is bent toward the first sub-isolation structure 610. For example, the first sub-isolation structure 610 and the second sub-isolation structure 620 form a mushroom-shaped isolation structure. For example, when the second sub-isolation structure 620 made of an organic material is formed through processes, such as exposure and development, etc., the surface of the second sub-isolation structure 620 away from the base substrate 01 is a curved surface.

For example, the first sub-isolation structure 610 includes at least one film layer, the first electrode 110 includes at least one electrode layer, and one film layer of the first sub-isolation structure 610 is arranged in the same layer as one electrode layer of the first electrode 110.

For example, FIG. 12 is a partial cross-sectional structural view of a display substrate provided by an example of another embodiment of the present disclosure. The display substrate in the example shown in FIG. 12 is different from the display substrate shown in FIG. 11A in that the thickness of the first sub-isolation structure 610 in the display substrate shown in FIG. 12 is smaller, and for example, the ratio of the thickness of the first sub-isolation structure 610 to the thickness of the light-emitting functional layer 130 is in the range of 0.7-1.5. The base substrate 01 and the organic light-emitting element 100 in the display substrate shown in FIG. 12 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The materials of the first sub-isolation structure 610 and the second sub-isolation structure 620 in the isolation structure 600 in the display substrate shown in FIG. 12 can be the same as the materials of the first sub-isolation structure 610 and the second sub-isolation structure 620 in the isolation structure 600 shown in FIG. 11A, and details will not be repeated here. The planarization layer 500 and the pixel defining pattern 400 shown in FIG. 12 can have the same features as the planarization layer 500 and the pixel defining pattern 400 shown in FIG. 11A, and details will not be repeated here.

For example, as shown in FIG. 12, for example, the ratio of the thickness of the first sub-isolation structure 610 to the thickness of the light-emitting functional layer 130 is in the range of 0.8-1.3. The ratio of the thickness of the first sub-isolation structure 610 to the thickness of the light-emitting functional layer 130 is in the range of 0.9-1.1. For example, the ratio of the thickness of the first sub-isolation structure 610 to the thickness of the light-emitting functional layer 130 is 1. In an example of the embodiment of the present disclosure, by setting the thickness of the first sub-isolation structure to be equivalent to the thickness of the light-emitting functional layer, the charge generation layer can be disconnected at the edge of the isolation structure, and at the same time, the second electrode may not be disconnected at the edge of the isolation structure as much as possible, so that the second electrode has better electrical characteristics and the brightness uniformity of the display substrate is improved.

For example, the thickness of the first sub-isolation structure 610 can be in the range of 100-10000 angstroms. For example, the thickness of the first sub-isolation structure 610 can be in the range of 200-5000 angstroms. For example, the thickness of the first sub-isolation structure 610 can be in the range of 300-1500 angstroms.

For example, as shown in FIG. 12, at least one edge of the first sub-isolation structure 610 at one side in the X direction shrinks by 0.1 micron or more than 0.1 micron relative to a corresponding edge of the second sub-isolation structure 620, so as to form an undercut structure. For example, the size of the isolation protrusion 601 in the X direction may be not less than 0.1 micron. For example, the size of the isolation protrusion 601 in the X direction may be not less than 0.2 micron.

For example, as shown in FIG. 12, the thickness of the second sub-isolation structure 620 can be in the range of 0.5-3 microns. For example, the thickness of the second sub-isolation structure 620 can be in the range of 0.8-1.6 microns. For example, the thickness of the second sub-isolation structure 620 can be in the range of 1-1.2 microns.

For example, as shown in FIG. 12, the slope angle of the surface, away from the first sub-isolation structure 610, of the part of the second sub-isolation structure 620 protruding relative to the edge of first sub-isolation structure 610 can be in the range of 15-70 degrees. For example, the slope angle of the edge of the curved surface of the isolation protrusion 601 of the second sub-isolation structure 620 can be in the range of 15-70 degrees. For example, the slope angle of the edge of the curved surface of the isolation protrusion 601 of the second sub-isolation structure 620 is in the range of 20-60 degrees. For example, the slope angle of the edge of the curved surface of the isolation protrusion 601 of the second sub-isolation structure 620 is in the range of 30-45 degrees. The pattern of the curved surface cut by the XY plane is a curved line, and the slope angle of the curved surface of the isolation protrusion 601 can refer to an included angle between the tangent at the endpoint of the curved line and a straight line parallel to the X direction, or an included angle between the tangent at the midpoint of the curved line of the isolation protrusion 601 and the straight line parallel to the X direction. The slope angle of the curved surface of the isolation protrusion of the second sub-isolation structure is set relatively small, which is helpful to reduce the probability of the second electrode being disconnected at the isolation protrusion.

In the embodiment of the present disclosure, by setting the thickness of the first sub-isolation structure and the thickness of the second sub-isolation structure, setting the size of the isolation protrusion of the second sub-isolation structure relative to the edge of the first sub-isolation structure in the direction parallel to the base substrate, and setting the slope angle of the curved surface of the second isolation structure, part of the material of the light-emitting functional layer can be filled in the undercut structure, and on the basis of disconnecting the charge generation layer, the isolation structure may not disconnect the second electrode as much as possible, thus ensuring that the second electrode has good electrical characteristics.

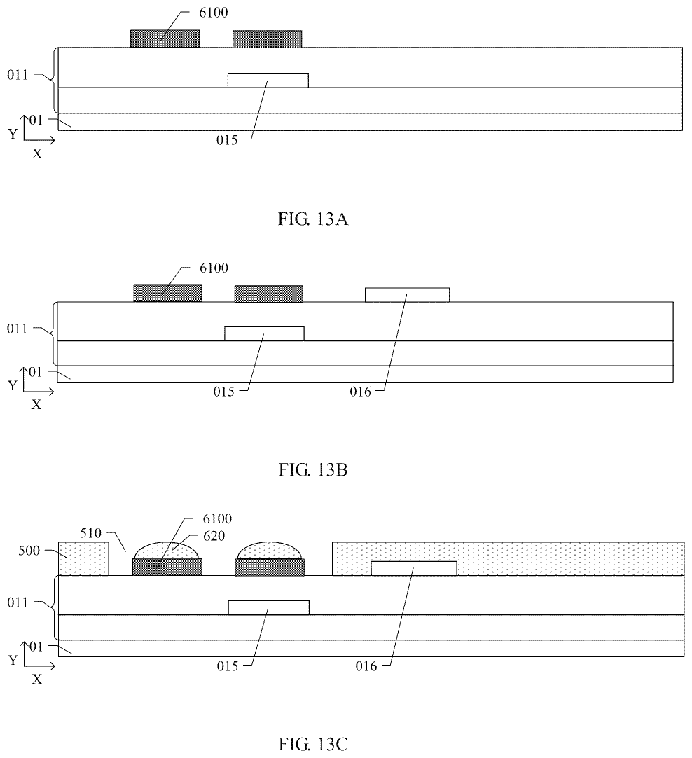

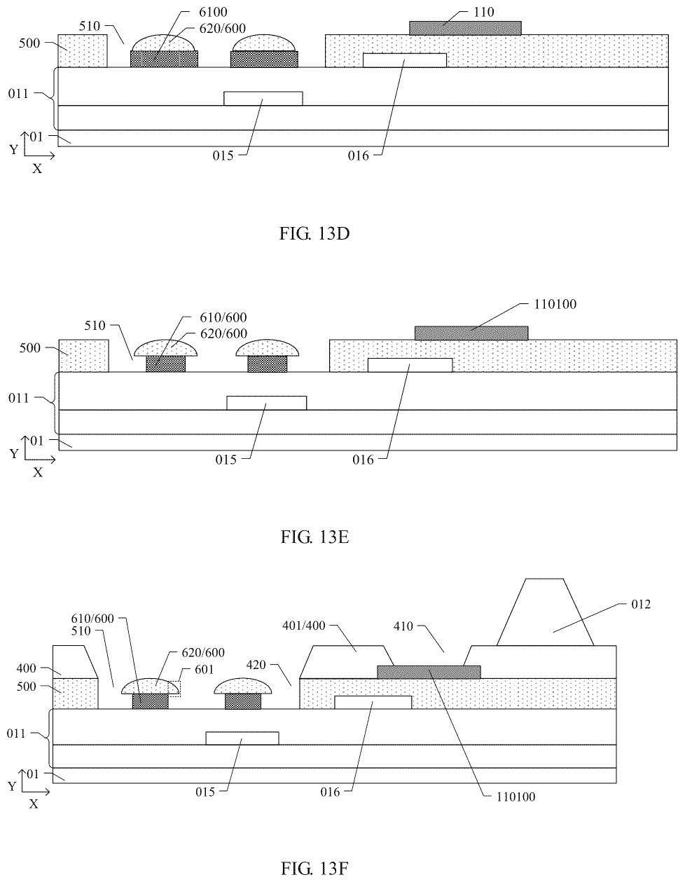

For example, FIGS. 13A-13F are flow charts of a manufacturing method of a display substrate before the formation of the structure shown in FIG. 11A. For example, as shown in FIGS. 11A and 13A, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here.

For example, as shown in FIGS. 11A and 13A, the process flow of forming other film layers 011 on the base substrate 01 can be the same as the process flow of forming other film layers 011 in the display substrate shown in FIG. 5A, or the same as the process flow of forming other film layers 011 in the display substrate shown in FIG. 4A, and details will not be repeated here.

For example, as shown in FIGS. 11A and 13A, a first sub-isolation structure layer is formed on other film layers 011, and the first sub-isolation structure layer is patterned to form a first sub-isolation structure pattern 6100. For example, the first sub-isolation structure layer can be dry etched or wet etched to form the first sub-isolation structure pattern 6100.

For example, as shown in FIGS. 11A and 13B, after the first sub-isolation structure pattern 6100 is formed, a second conductive layer pattern 016 can be formed by patterning. For example, the material of the first sub-isolation structure pattern 6100 is different from the material of the second conductive layer pattern 016. For example, the material of the first sub-isolation structure pattern 6100 can include any one or more of silicon nitride, silicon oxide or silicon oxynitride, and the material of the second conductive layer pattern 016 can include a metallic material. However, the embodiment of the present disclosure is not limited thereto. For example, the first sub-isolation structure pattern and the second conductive layer pattern can also be formed in the same step patterning process, and in this case, the material of the first sub-isolation structure pattern can include a metallic material.

For example, as shown in FIGS. 11A and 13C, an organic material layer is formed on the first sub-isolation structure pattern 6100 and the second conductive layer pattern 016, and the organic material layer is patterned to form an organic layer opening 510 and a second sub-isolation structure 620 located on the first sub-isolation structure pattern 6100. For example, a photoresist layer is formed on the first sub-isolation structure pattern 6100 and the second conductive layer pattern 016, and the organic material layer at a position in the organic layer opening 510 other than the position of the first sub-isolation structure pattern 6100 is etched away after photoresist coating, exposure and development.

For example, as shown in FIGS. 11A and 13D, a first electrode 110 is formed by patterning on the organic layer 500. The process method of forming the first electrode 110 can be the same as the process method of forming the first electrode 110 shown in FIG. 5B, and details will not be repeated here.

For example, as shown in FIGS. 11A and 13E, the first sub-isolation structure pattern 6100 is wet etched (the etching solution has little influence on the second sub-isolation structure 620), so that the edge of the first sub-isolation structure pattern 6100 shrinks relative to the edge of the second sub-isolation structure 620 to form an undercut structure. For example, after the first sub-isolation structure pattern 6100 is wet etched, a first sub-isolation structure 610 and an isolation structure 600 are formed.

For example, as shown in FIGS. 11A and 13E, after the isolation structure 600 is formed, a pixel defining film is formed on the organic layer 500 and the isolation structure 600, and the pixel defining film is patterned to form a pixel defining pattern 400. The pixel defining pattern 400 includes a first opening 410 exposing the first electrode 110 and a second opening 420 exposing the isolation structure 600. For example, the material of the second sub-isolation structure 620 is different from the material of the pixel defining portion 401 in the pixel defining pattern 400, so as to prevent the second sub-isolation structure 620 from being influenced in the process of patterning to form the second opening 420.

FIG. 14 is a partial cross-sectional structural view of a display substrate provided by an example of another embodiment of the present disclosure. The display substrate in the example shown in FIG. 14 is different from the display substrate shown in FIG. 12 in that the first sub-isolation structure 610 and the second sub-isolation structure 620 in the display substrate shown in FIG. 14 are integrally formed. The base substrate 01 and the organic light-emitting element 100 in the display substrate shown in FIG. 14 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 and the pixel defining pattern 400 shown in FIG. 14 can have the same features as those of the planarization layer 500 and the pixel defining pattern 400 shown in FIG. 11A, and details will not be repeated here.

For example, as shown in FIG. 14, the material of the isolation structure 600 can be the same as the material of the planarization layer 500. The isolation structure 600 shown in FIG. 14 can have the same size and quantity relationship as the isolation structure 600 in any example shown in FIGS. 11A-12, and details will not be repeated here.

For example, FIG. 14 illustratively shows that there is a gap between the isolation structure 600 and the planarization layer 500, but it is not limited thereto. The isolation structure 600 can also be an integrated structure with the planarization layer 500, that is, the isolation structure 600 can be a part of the planarization layer 500, and the planarization layer 500 includes two isolation structures 600 at both sides of the organic layer opening 510 in the X direction, respectively, which are configured to disconnect the charge generation layer.

The materials of the first sub-isolation structure and the second sub-isolation structure in the display substrate provided by this example are the same, and the charge generation layer can be isolated without increasing the number of masks and reducing the productivity.

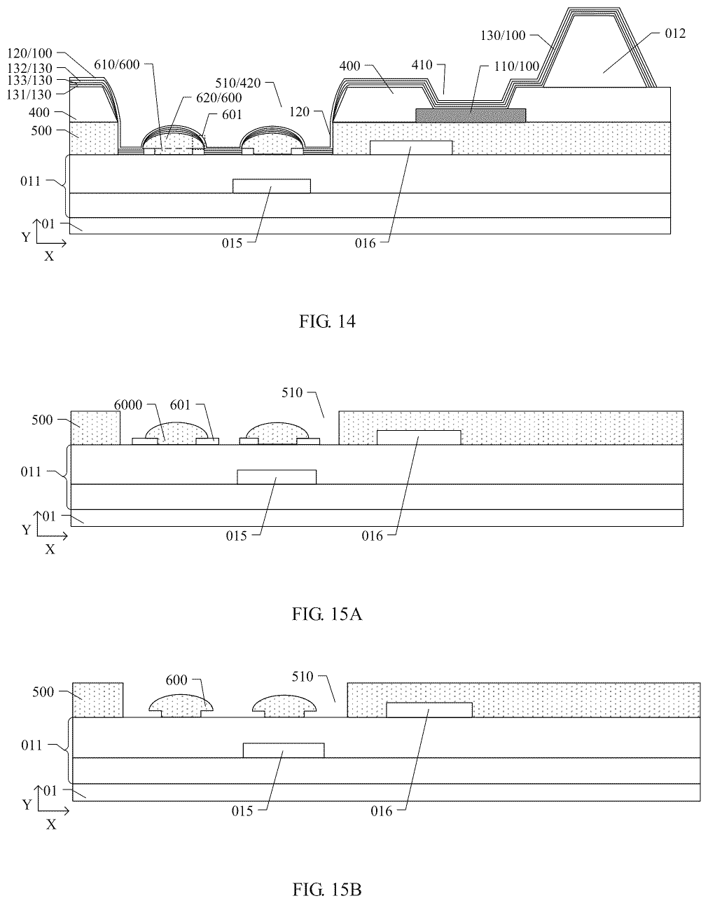

For example, FIGS. 15A-15B are flow charts of a manufacturing method of a display substrate before the formation of the structure shown in FIG. 14. For example, the process flow and process method of forming the base substrate 01 and other film layers 011 in the display substrate as shown in FIGS. 14 and 15A can be the same as the process flow and process method of forming the base substrate 01 and other film layers 011 in the display substrate as shown in FIG. 4A, or can be the same as the process flow and process method of forming the base substrate 01 and other film layers 011 in the display substrate as shown in FIG. 5A, and details will not be repeated here.

For example, as shown in FIGS. 14 and 15A, the manufacturing method of the display substrate includes patterning to form a plurality of inorganic material patterns 601 on other film layers 011. For example, after forming the inorganic material patterns 601, an organic material layer is formed, and the organic material layer is patterned to form an organic layer opening 510 and an isolation structure pattern 6000 located in the organic layer opening 510. For example, as shown in FIG. 15A, in the X direction, at least one edge of each isolation structure pattern 6000 covers the inorganic material pattern 601. For example, in the X direction, both edges of each isolation structure pattern 6000 cover the inorganic material patterns 601.

For example, as shown in FIG. 15A, in the X direction, the edge of the inorganic material pattern 601 covered by the isolation structure pattern 6000 protrudes relative to the edge of the isolation structure pattern 6000 covering the inorganic material pattern 601, or the edge of the inorganic material pattern 601 covered by the isolation structure pattern 6000 is flush with the edge of the isolation structure pattern 6000 covering the inorganic material pattern 601.

For example, FIG. 15A illustratively shows that the inorganic material patterns 601 covered by two adjacent isolation structure patterns 6000 are separated from each other, but it is not limited thereto. For example, the inorganic material patterns 601 located between two isolation structure patterns 6000 can be an integrated structure, that is, the two isolation structure patterns 6000 share the inorganic material pattern 601 located therebetween.

For example, as shown in FIGS. 14 and 15B, the inorganic material pattern 601 is wet etched (the etching solution has little influence on the isolation structure pattern 6000), so as to etch away the inorganic material pattern 601, and thus, the isolation structure pattern 6000 forms an isolation structure 600 with an undercut structure. The embodiment of the present disclosure is not limited thereto, and the inorganic material pattern may not be completely etched away, as long as the isolation structure pattern forms an undercut structure and the undercut structure can disconnect the charge generation layer.

For example, as shown in FIGS. 14 and 15B, in the X direction, a plurality of isolation structures 600 can be arranged between adjacent sub-pixels, and the maximum size of each isolation structure 600 can be the same as the minimum size of the gap between adjacent isolation structures 600. For example, in the X direction, the maximum size of each isolation structure 600 and the minimum size of the gap between adjacent isolation structures 600 can both be 10 microns. Of course, the embodiment of the present disclosure is not limited thereto, and in the X direction, the maximum size of each isolation structure 600 and the minimum size of the gap between adjacent isolation structures 600 may not be equal. For example, the size of the isolation structure may be larger, or the size of the gap may be larger.

For example, as shown in FIGS. 14 and 15B, in the X direction, the size of the isolation protrusion 601 of the second sub-isolation structure 620 can be in the range of 1-3 microns.

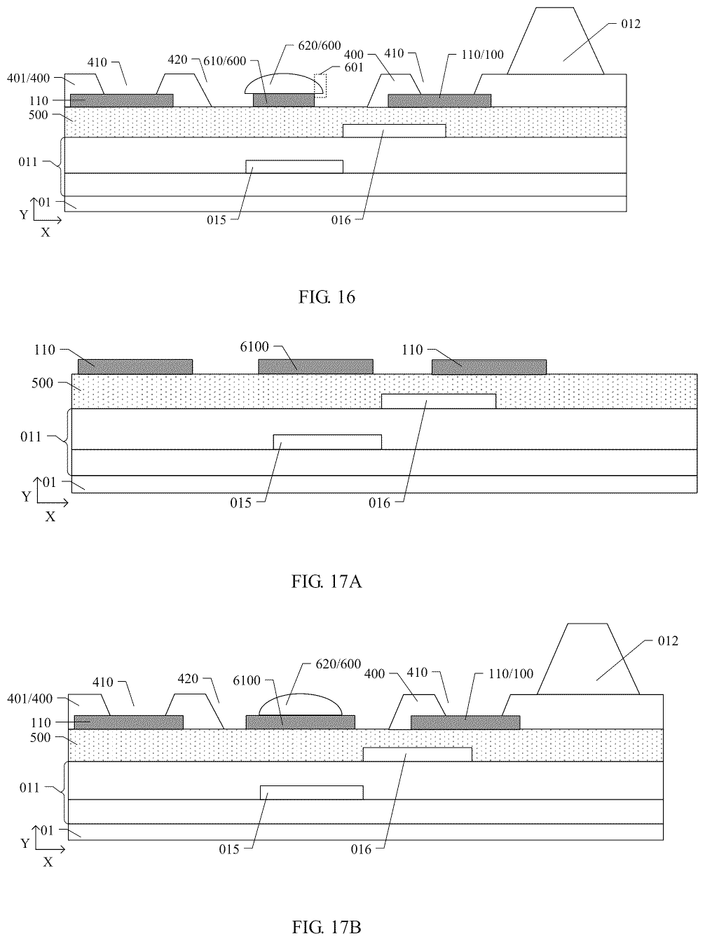

FIG. 16 is a partial cross-sectional structural view of a display substrate provided by an example of another embodiment of the present disclosure. The display substrate in the example shown in FIG. 16 is different from the display substrates shown in FIGS. 11A-15B in that both the isolation structure 600 and the first electrode 110 are disposed on the planarization layer 500. The base substrate 01 and the organic light-emitting element 100 in the display substrate shown in FIG. 16 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The shapes and thicknesses of the first sub-isolation structure 610 and the second sub-isolation structure 620 shown in FIG. 16 and the relationship of the sizes thereof in the direction parallel to the base substrate can be the same as the shapes and thicknesses of the first sub-isolation structure 610 and the second sub-isolation structure 620 in the display substrates shown in FIGS. 11A-15B and the relationship of the sizes thereof in the direction parallel to the base substrate, and details will not be repeated here.

For example, as shown in FIG. 16, the second opening 420 of the pixel defining pattern 400 exposes the isolation structure 600 and part of the planarization layer 500. For example, a gap is provided between the isolation structure 600 and the edge of the second opening 420.

For example, as shown in FIG. 16, the first sub-isolation structure 610 is arranged in the same layer as the first electrode 110. For example, the thickness of the first sub-isolation structure 610 can be the same as the thickness of the first electrode 110. For example, the first sub-isolation structure 610 is made of the same material as the first electrode 110, so as to save process steps. For example, the first electrode 110 can include multiple film layers, and the first sub-isolation structure 610 can also include the same multiple film layers as the first electrode 110. For example, the first electrode 110 can include multiple film layers, and the first sub-isolation structure 610 can include a film layer which is the same as one film layer in the first electrode 110.

For example, as shown in FIG. 16, the second sub-isolation structure 620 and the pixel defining portion 401 of the pixel defining pattern 400 are arranged in the same layer and made of the same material. For example, as shown in FIG. 16, the surface of the second sub-isolation structure 610 away from the base substrate 01 can be a curved surface.

For example, as shown in FIG. 16, one isolation structure 600 can be arranged between adjacent sub-pixels, but it is not limited thereto, and two or more isolation structures can be arranged therebetween, which can be set according to the product size and requirements.

For example, as shown in FIG. 16, the maximum distance between the surface of the second sub-isolation structure 620 away from the base substrate 01 and the base substrate 01 can be equal to the maximum distance between the surface of the pixel defining portion 401 away from the base substrate 01 and the base substrate 01.

For example, as shown in FIG. 16, the size of the second sub-isolation structure 620 in the X direction is less than the size of the first electrode 110 in the X direction.

For example, the first sub-isolation structure 610 and the second sub-isolation structure 620 can also be an integrated structure, and the materials of the first sub-isolation structure 610 and the second sub-isolation structure 620 adopts the material of the pixel defining portion 401.

For example, the first sub-isolation structure 610 and the second sub-isolation structure 620 are an integrated structure, and the isolation structure 600 can be a part of the pixel defining portion 401 of the pixel defining pattern 400. For example, the first opening 401 is formed at one side of one pixel defining portion 401 in the X direction, and the isolation structure 600 including a protrusion is formed at the other side of the pixel defining portion 401 in the X direction, so as to form a second opening 420. In an example of one embodiment of the present disclosure, by using a part of the pixel defining portion of the pixel defining pattern as an isolation structure, process steps can be saved.

For example, the thickness of the first sub-isolation structure 610, the size of the protrusion of the second sub-isolation structure 620 relative to the edge of the first sub-isolation structure 610, and the angle of the edge of the curved surface of the second sub-isolation structure 620 can be set, so that the charge generation layer is disconnected at the edge of the isolation structure 600, and the second electrode is not disconnected at the edge of the isolation structure 600.

For example, FIGS. 17A-17B are flow charts of a manufacturing method of a display substrate before the formation of the structure shown in FIG. 16. For example, as shown in FIGS. 16 and 17A, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here.

For example, as shown in FIGS. 16 and 17A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 16 and 17A, an electrode layer is formed on the planarization layer 500, and the electrode layer is patterned to form a first electrode 110 and a first sub-isolation structure pattern 6100. For example, the shape and size of the first electrode 110 can be the same as the shape and size of the first sub-isolation structure pattern 6100.

For example, as shown in FIGS. 16 and 17B, a pixel defining film is formed on the first electrode 110 and the first sub-isolation structure pattern 6100, and the pixel defining film is patterned to form a pixel defining pattern 400 and a second sub-isolation structure 620. The pixel defining pattern 400 includes a first opening 410 exposing the first electrode 110 and a second opening 420 exposing the first sub-isolation structure pattern 6100, and the second sub-isolation structure 620 is located on the first sub-isolation structure pattern 6100 exposed by the first opening 420. For example, after the pixel defining pattern 400 is formed, the spacers 012 are formed by patterning.

For example, as shown in FIG. 17B, in the X direction, the size of the first sub-isolation structure pattern 6100 is greater than the size of the second sub-isolation structure 620. For example, in the X direction, the first sub-isolation structure pattern 6100 has a protrusion relative to at least one edge of the second sub-isolation structure 620. For example, in the X direction, the first sub-isolation structure pattern 6100 has protrusions relative to two edges of the second sub-isolation structure 620. Of course, the present example is not limited thereto, and the edge of the first sub-isolation structure pattern 6100 can also be flush with the edge of the second sub-isolation structure 620.

For example, as shown in FIGS. 16 and 17B, the first sub-isolation structure pattern 6100 is wet etched (the etching solution has little influence on the second sub-isolation structure 620), so that the edge of the first sub-isolation structure pattern 6100 shrinks relative to the edge of the second sub-isolation structure 620 to form an undercut structure. For example, after the first sub-isolation structure pattern 6100 is wet etched, a first sub-isolation structure 610 and an isolation structure 600 are formed.

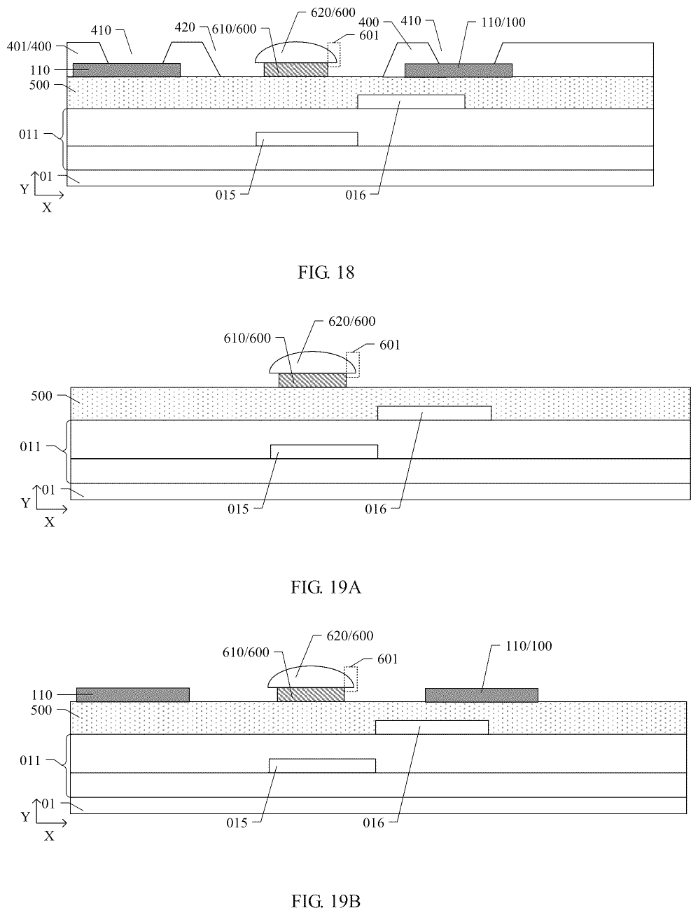

FIG. 18 is a partial cross-sectional structural view of a display substrate provided by an example of another embodiment of the present disclosure. The display substrate in the example shown in FIG. 18 is different from the display substrate shown in FIGS. 16-17B in that the materials of the first sub-isolation structure 610 and the first electrode 110 are different. The base substrate 01 and the organic light-emitting element 100 in the display substrate shown in FIG. 18 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The shapes and thicknesses of the first sub-isolation structure 610 and the second sub-isolation structure 620 shown in FIG. 18 and the relationship of the sizes thereof in the direction parallel to the base substrate can be the same as the shapes and thicknesses of the first sub-isolation structure 610 and the second sub-isolation structure 620 in the display substrates shown in FIGS. 11A-17B and the relationship of the sizes thereof in the direction parallel to the base substrate, and details will not be repeated here.

For example, as shown in FIG. 18, the material of the first sub-isolation structure 610 can include any one or more of silicon nitride, silicon oxide or silicon oxynitride, and the material of the second sub-isolation structure 620 can be the same as the material of the pixel defining portion 401.

For example, FIGS. 19A-19B are flow charts of a manufacturing method of a display substrate before the formation of the structure shown in FIG. 18. For example, as shown in FIGS. 18 and 19A, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here.

For example, as shown in FIGS. 18 and 19A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 18 and 19A, a first sub-isolation structure layer is formed on the planarization layer 500, and for example, the first sub-isolation structure layer is deposited on the planarization layer 500. For example, the thickness of the first sub-isolation structure layer can be in the range of 300-10000 angstroms. For example, after the first sub-isolation structure layer is formed, the first sub-isolation structure layer is patterned to form a first sub-isolation structure pattern. For example, the first sub-isolation structure layer is dry etched to form the first sub-isolation structure pattern. For example, a second sub-isolation structure layer is formed on the first sub-isolation structure pattern. For example, the thickness of the second sub-isolation structure layer can be in the range of 0.5-3 microns. For example, after photoresist coating, exposure and development on the second sub-isolation structure layer, a second sub-isolation structure 620 is formed on the first sub-isolation structure pattern.

For example, as shown in FIG. 19A, after the second sub-isolation structure 620 is formed, the first sub-isolation structure pattern is wet etched (the etching solution has little influence on the second sub-isolation structure), so that the edge of the first sub-isolation structure pattern shrinks relative to the edge of the second sub-isolation structure to form an undercut structure (i.e., isolation structure 600); and the undercut structure includes the edges of the first sub-isolation structure 610 and the second sub-isolation structure 620. For example, the size of the isolation protrusion 601 of the second sub-isolation structure 620 protruding relative to the edge of the first sub-isolation structure 610 in the X direction may be not less than 0.2 micron.

For example, as shown in FIGS. 18 and 19B, after the isolation structure 600 is formed, a first electrode 110 is formed by patterning on the planarization layer 500. In the present example, the process method of forming film layers, such as the first electrode and the subsequent pixel defining pattern, etc., can be the same as the process method of forming film layers, such as the first electrode and the subsequent pixel defining pattern, etc., in the display substrate shown in FIGS. 1A-5D, and details will not be repeated here.

For example, as shown in FIG. 18, a gap is provided between the isolation structure 600 and the pixel defining portion 401 of the pixel defining pattern 400. For example, the thickness of the isolation structure 600 can be less than the thickness of the pixel defining portion 401.

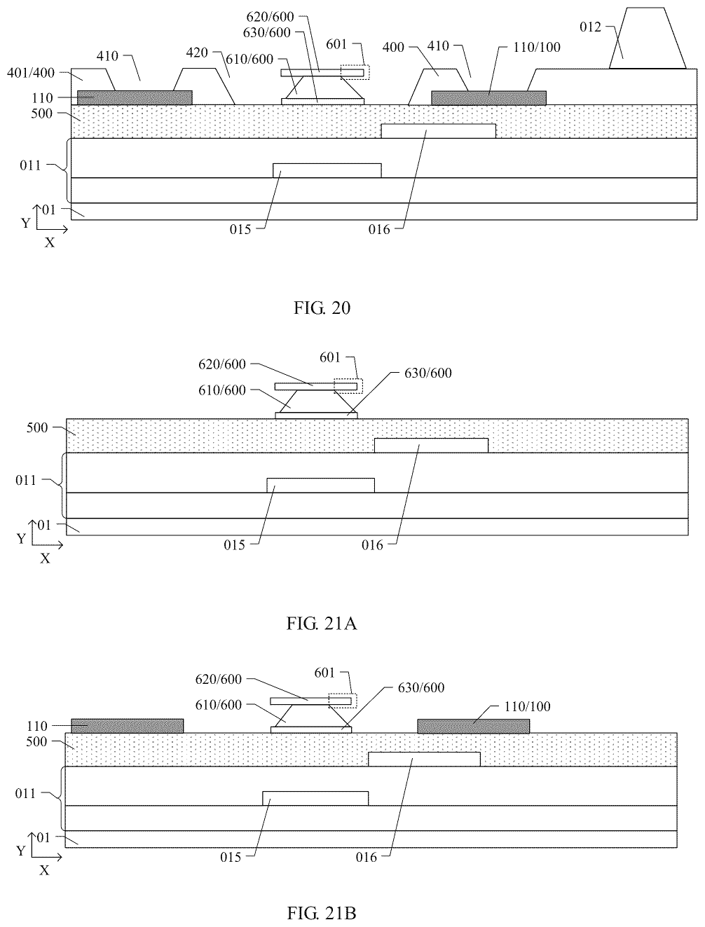

FIG. 20 is a partial cross-sectional structural view of a display substrate provided by an example of another embodiment of the present disclosure. The display substrate in the example shown in FIG. 20 is different from the display substrate shown in FIG. 16 in that the number of stacked layers of the isolation structure is different. The base substrate 01 and the organic light-emitting element 100 in the display substrate shown in FIG. 20 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 in the display substrate shown in FIG. 20 can have the same features as the planarization layer 500 in the display substrate shown in FIG. 16, and details will not be repeated here.

For example, as shown in FIG. 20, each isolation structure 600 further includes a third sub-isolation structure 630 stacked with the second sub-isolation structure 620 and the first sub-isolation structure 610, and the third sub-isolation structure 630 is located between the first sub-isolation structure 610 and the base substrate 01; in the arrangement direction of adjacent sub-pixels 100 (e.g., X direction as shown in the figure), in the isolation structure 600 between adjacent sub-pixels 100, the size of the third sub-isolation structure 630 is greater than the maximum size of the first sub-isolation structure 610.

For example, as shown in FIG. 20, in the X direction, the ratio of the size of the second sub-isolation structure 620 to the size of the third sub-isolation structure 630 can be in the range of 0.8-1.2. For example, in the X direction, the ratio of the size of the second sub-isolation structure 620 to the size of the third sub-isolation structure 630 can be in the range of 0.9-1.1. For example, in the X direction, the size of the second sub-isolation structure 620 and the size of the third sub-isolation structure 630 can be equal.

For example, as shown in FIG. 20, the pixel defining pattern 400 includes a second opening 420, and the second opening 420 is configured to expose the isolation structure 600. For example, there is a certain space between the isolation structure 600 and the edge of the second opening 420.

For example, as shown in FIG. 20, in the direction perpendicular to the base substrate 01, the thickness of the second sub-isolation structure 620 and the thickness of the third sub-isolation structure 630 are both less than the thickness of the first sub-isolation structure 610.

For example, as shown in FIG. 20, in the direction perpendicular to the base substrate 01, the thickness of the isolation structure 600 can be less than the thickness of the pixel defining portion 401 of the pixel defining pattern 400. But not limited thereto, the thickness of the isolation structure 600 can be greater than or equal to the thickness of the pixel defining portion 401.

For example, as shown in FIG. 20, the third sub-isolation structure 630 is disposed in the same layer as the first electrode 110. For example, the third sub-isolation structure 630 and the first electrode 110 are both disposed on the surface of the planarization layer 500.

For example, as shown in FIG. 20, the material of the second sub-isolation structure 620 is the same as the material of the third sub-isolation structure 630, and the material of the second sub-isolation structure 620 is different from the material of the first sub-isolation structure 630. For example, the materials of the first sub isolation structure 610 and the second sub isolation structure 620 are both inorganic materials. For example, the material of the first sub-isolation structure 610 can be silicon nitride, and the materials of the second sub-isolation structure 620 and the third sub-isolation structure 630 can be silicon oxide. For example, the material of the first sub-isolation structure 610 can be aluminum, and the materials of the second sub-isolation structure 620 and the third sub-isolation structure 630 can be titanium. The materials of two components being different can refer to that the materials of the two components are different in density, or the materials of the two components are different in refractive index, or the materials of the two components are different in hydrophilicity, or the materials of the two components are different in chemical activity with a certain solvent, etc.

For example, as shown in FIG. 20, the cross section of the first sub-isolation structure 610 cut by a plane parallel to the XY plane can be a trapezoid, the upper base of the trapezoid is in contact with a surface of the second sub-isolation structure 620 and the lower base of the trapezoid is in contact with a surface of the third sub-isolation structure 630. Of course, the embodiment of the present disclosure is not limited thereto, and the cross-section of the first sub-isolation structure 610 cut by a plane parallel to the XY plane can also be a rectangle.

For example, as shown in FIG. 20, the cross sections of the second sub-isolation structure 620 and the third sub-isolation structure 630 cut by the plane parallel to the XY plane can both be rectangular.

For example, the ratio of the sum of the thicknesses of the first sub-isolation structure 610 and the third sub-isolation structure 630 to the thickness of the light-emitting functional layer can be in the range of 0.8-1.2. For example, the ratio of the sum of the thicknesses of the first sub-isolation structure 610 and the third sub-isolation structure 630 to the thickness of the light-emitting functional layer can be in the range of 0.9-1.1. By setting the sum of the thicknesses of the first sub-isolation structure 610 and the third sub-isolation structure 630 relatively small, the charge generation layer can be disconnected at the position of the isolation protrusion 601 of the second sub-isolation structure 620, while the second electrode is not disconnected at the position of the isolation protrusion 601 and remains continuous. Of course, the embodiment of the present disclosure is not limited thereto, and the sum of the thicknesses of the first sub-isolation structure 610 and the third sub-isolation structure 630 can be greater than the thickness of the light-emitting functional layer, so that both the charge generation layer and the second electrode are disconnected at the position of the isolation protrusion 601 of the second sub-isolation structure 620.

For example, at least one of the first sub-isolation structure 610, the second sub-isolation structure 620 and the third sub-isolation structure 630 includes at least one film layer.

For example, FIGS. 21A-21B are flow charts of a manufacturing method of a display substrate before the formation of the structure shown in FIG. 20. For example, as shown in FIGS. 20 and 21A, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here.

For example, as shown in FIGS. 20 and 21A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 20 and 21A, a third sub-isolation structure layer, a first sub-isolation structure layer and a second sub-isolation structure layer are sequentially formed on the planarization layer 500, and then a three-layer isolation structure pattern is formed by dry etching. Subsequently, the first sub-isolation structure pattern located in the middle layer is wet etched (the etching selectivity ratio of the etching solution to the material of the first sub-isolation structure pattern is greater than the etching selectivity ratio of the etching solution to the materials of the second sub-isolation structure pattern and the third sub-isolation structure pattern), so that the edge of the first sub-isolation structure pattern shrinks relative to the edge of the second sub-isolation structure pattern to form an undercut structure at the edge of the second sub-isolation structure pattern and the edge of the first sub-isolation structure pattern, thus forming the isolation structure 600.

For example, as shown in FIGS. 20 and 21B, after the isolation structure 600 is formed, a first electrode 110 is formed by patterning on the planarization layer 500. In the present example, the process method of forming film layers, such as the first electrode and the subsequent pixel defining pattern, etc., can be the same as the process method of forming film layers, such as the first electrode and the subsequent pixel defining pattern, etc., in the display substrate shown in FIGS. 1A-5D, and details will not be repeated here.

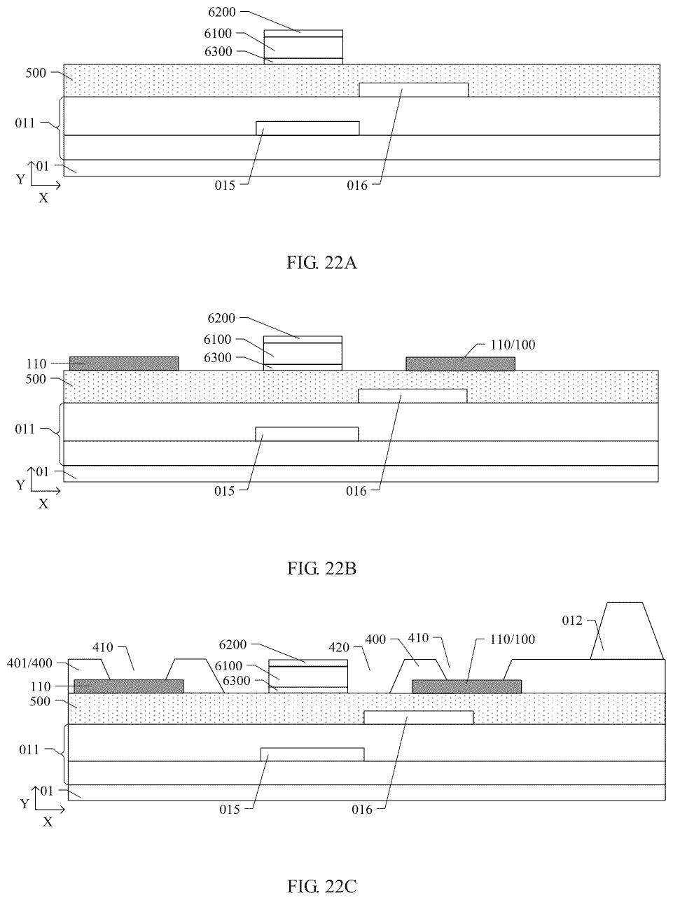

For example, FIGS. 22A-22C are flow charts of another manufacturing method of a display substrate before the formation of the structure shown in FIG. 20. The manufacturing method of the display substrate shown in FIGS. 22A-22C is different from the manufacturing method of the display substrate shown in FIGS. 21A-21B in that the step of forming the isolation structure 600 with the features of undercut structure is after forming the pixel defining pattern 400. For example, as shown in FIGS. 20 and 22A, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here. For example, as shown in FIGS. 20 and 22A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 20 and 22A, a third sub-isolation structure layer, a first sub-isolation structure layer and a second sub-isolation structure layer are sequentially formed on the planarization layer 500, and then a third sub-isolation structure pattern 6300, a first sub-isolation structure pattern 6100 and a second sub-isolation structure pattern 6200 are formed by dry etching. For example, the orthographic projections of the third sub-isolation structure pattern 6300, the first sub-isolation structure pattern 6100 and the second sub-isolation structure pattern 6200 on the base substrate 01 are completely coincident.

For example, as shown in FIGS. 20 and 22B, after the third sub-isolation structure pattern 6300, the first sub-isolation structure pattern 6100 and the second sub-isolation structure pattern 6200 are formed, a first electrode 110 is formed by patterning on the planarization layer 500. The process method of forming the first electrode in the present example can be the same as the process method of forming the first electrode in the display substrate shown in FIGS. 1A-5D, and details will not be repeated here.

For example, as shown in FIGS. 20 and 22C, after the first electrode 110 is formed, a pixel defining film is formed on the first electrode 110, and the pixel defining film is patterned to form a pixel defining pattern 400. The pixel defining pattern 400 includes a first opening 410 exposing the first electrode 110, and a second opening 420 exposing the third sub-isolation structure pattern 6300, the first sub-isolation structure pattern 6100 and the second sub-isolation structure pattern 6200.

For example, as shown in FIGS. 20 and 22C, after the pixel defining pattern 400 and the spacers 012 are formed, by using a mask exposing the stacked structure of the sub-isolation structure patterns, the first sub-isolation structure pattern 6100 in the exposed stacked structure of the sub-isolation structure patterns is wet etched, so that the edge of the first sub-isolation structure pattern 6100 shrinks relative to the edge of the second sub-isolation structure pattern 6200 to form an undercut structure, thereby forming the isolation structure 600. The subsequent process steps of forming film layers, such as a light-emitting functional layer, etc., can be the same as the process steps of forming film layers, such as a light-emitting functional layer, etc., in the examples shown in FIGS. 4B and 7, and details are not repeated here.

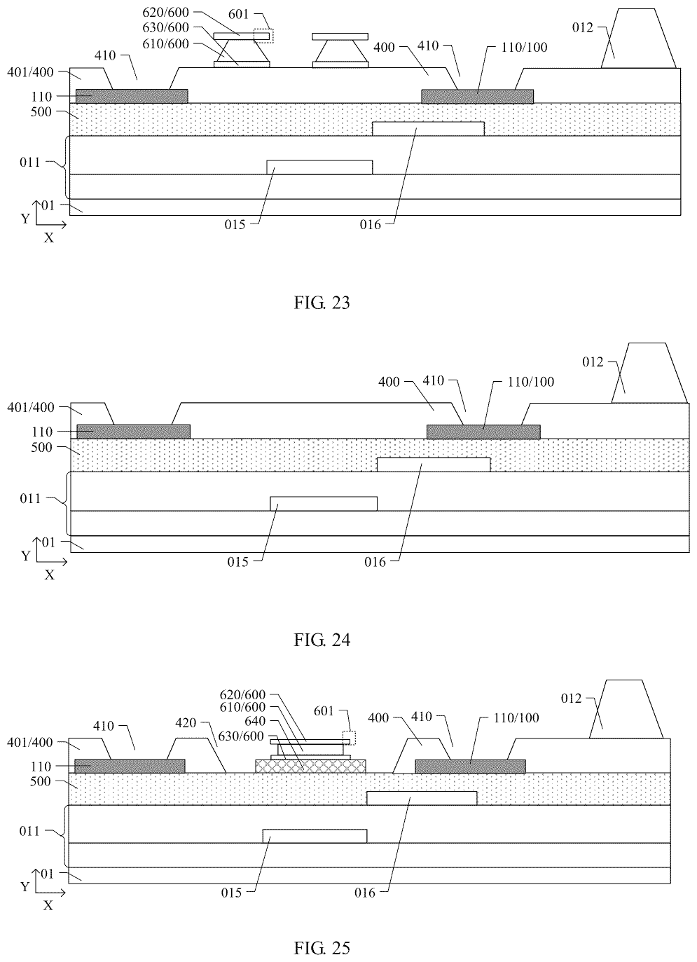

FIG. 23 is a partial cross-sectional structural view of a display substrate provided by an example of another embodiment of the present disclosure. The display substrate in the example shown in FIG. 23 is different from the display substrate shown in FIG. 20 in that the position of the isolation structure is different. The base substrate 01 and the organic light-emitting element 100 in the display substrate shown in FIG. 23 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 in the display substrate shown in FIG. 23 can have the same features as the planarization layer 500 in the display substrate shown in FIG. 20, and details will not be repeated here.

For example, as shown in FIG. 23, the pixel defining pattern 400 includes a plurality of first openings 410, the plurality of first openings 410 are arranged in one-to-one correspondence with the plurality of sub-pixels 100 to define light-emitting regions of the plurality of sub-pixels, and the first openings 410 are configured to expose the first electrodes 110. For example, as shown in FIG. 23, the part of the pixel defining pattern 400 other than the first opening 410 is a pixel defining portion 401, and the isolation structure 600 is located at one side of the pixel defining portion 401 of the pixel defining pattern 400 away from the base substrate 01.

For example, as shown in FIG. 23, each isolation structure 600 includes a first sub-isolation structure 610, a second sub-isolation structure 620 and a third sub-isolation structure 630 which are stacked, and the third sub-isolation structure 630 is located between the first sub-isolation structure 610 and the base substrate 01; in the arrangement direction of adjacent sub-pixels 100 (e.g., X direction as shown in the figure), in the isolation structure 600 between adjacent sub-pixels 100, the size of the third sub-isolation structure 630 is greater than the maximum size of the first sub-isolation structure 610. The isolation structure 600 in the display substrate shown in FIG. 23 can have the same features as the isolation structure 600 in the display substrate shown in FIG. 20, and details will not be repeated here.

For example, FIG. 24 is a flow chart of a manufacturing method of a display substrate before the formation of the structure shown in FIG. 23. For example, as shown in FIGS. 23 and 24, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here. For example, as shown in FIGS. 23 and 24, the process flow of forming other film layers 011, the planarization layer 500 and the first electrode 110 on the base substrate 01 can be the same as the process flow of forming other film layers 011, the planarization layer 500 and the first electrode 110 in the display substrate shown in FIG. 5A, and can also be the same as the process flow of forming other film layers 011, the planarization layer 500 and the first electrode 110 in the display substrate shown in FIG. 4A, and details will not be repeated here.

For example, as shown in FIGS. 23 and 24, after the first electrode 110 is formed, a pixel defining film is formed on the planarization layer 500 and the first electrode 110, and the pixel defining film is patterned to form a pixel defining pattern 400 having a plurality of first openings 110 exposing the plurality of first electrodes 110.

For example, as shown in FIG. 23 and FIG. 24, after the pixel defining pattern 400 and the spacers 012 are formed, a third sub-isolation structure layer, a first sub-isolation structure layer and a second sub-isolation structure layer are sequentially formed on the pixel defining portion 401, and then a three-layer isolation structure pattern is formed by dry etching. Subsequently, the first sub-isolation structure pattern located in the middle layer is wet etched (the etching selectivity ratio of the etching solution to the material of the first sub-isolation structure pattern is greater than the etching selectivity ratio of the etching solution to the materials of the second sub-isolation structure pattern and the third sub-isolation structure pattern), so that the edge of the first sub-isolation structure pattern shrinks relative to the edge of the second sub-isolation structure pattern to form an undercut structure at the edge of the second sub-isolation structure pattern and the edge of the first sub-isolation structure pattern, thus forming the isolation structure 600.

FIG. 25 is a partial cross-sectional structural view of a display substrate provided by an example of another embodiment of the present disclosure. The display substrate in the example shown in FIG. 25 is different from the display substrate shown in FIG. 20 in that the stacked structure included in the isolation structure is different. For example, as shown in FIG. 25, the pixel defining pattern 400 includes a first opening 410 configured to expose the first electrode 110 and a second opening 420 configured to expose the isolation structure 600, the isolation structure 600 further includes a blocking portion 640 located between the third sub-isolation structure 630 and the base substrate 01, and the blocking portion 640 is arranged in the same layer as the first electrode 110. The blocking portion can block the isolation structure from the planarization layer, and prevent the planarization layer from being damaged in the process of forming the isolation structure.

For example, the first electrode 110 can include a plurality of film layers, and the barrier 640 can be made of an inorganic material. For example, the material of the blocking portion 640 can be the same as the material of at least one of the first sub-isolation structure, the second sub-isolation structure and the third sub-isolation structure.

The base substrate 01 and the organic light-emitting element 100 in the display substrate shown in FIG. 25 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 in the display substrate shown in FIG. 25 can have the same features as the planarization layer 500 in the display substrate shown in FIG. 20, and details will not be repeated here.

For example, as shown in FIG. 25, in the direction perpendicular to the base substrate 01, the ratio of the thickness of the blocking portion 640 to the thickness of the first electrode 110 can be in the range of 0.8-1.2. For example, the ratio of the thickness of the blocking portion 640 to the thickness of the first electrode 110 can be in the range of 0.9-1.1. The thickness of the blocking portion 640 can be equal to the thickness of the first electrode 110.

For example, as shown in FIG. 25, the shape and size of the blocking portion 640 can be the same as the shape and size of the first electrode 110, but it is not limited thereto, and the shape and size of the blocking portion can be set according to the actual requirements of the product.

For example, as shown in FIG. 25, the blocking portion 640 is not covered by the pixel defining portion 401 of the pixel defining pattern 400, and the orthographic projection of the blocking portion 640 on the base substrate 01 does not overlap with the orthographic projection of the pixel defining portion 401 on the base substrate 01. For example, a certain space is provided between the isolation structure 600 and the pixel defining portion 401 of the pixel defining pattern 400. Of course, the present example is not limited thereto, and the blocking portion 640 can be covered by the pixel defining portion 401.

For example, as shown in FIG. 25, the isolation structure 600 is located between adjacent sub-pixels 100, and in the arrangement direction of the adjacent sub-pixels 100, the size of the blocking portion 640 can be greater than the size of the third sub-isolation structure 620.

For example, as shown in FIG. 25, in the direction perpendicular to the base substrate 01, the sum of the thicknesses of the first sub-isolation structure 610, the third sub-isolation structure 630 and the blocking portion 640 can be greater than the thickness of the light-emitting functional layer, so that both the charge generation layer and the second electrode are disconnected at the isolation protrusion 601 of the second sub-isolation structure 620.

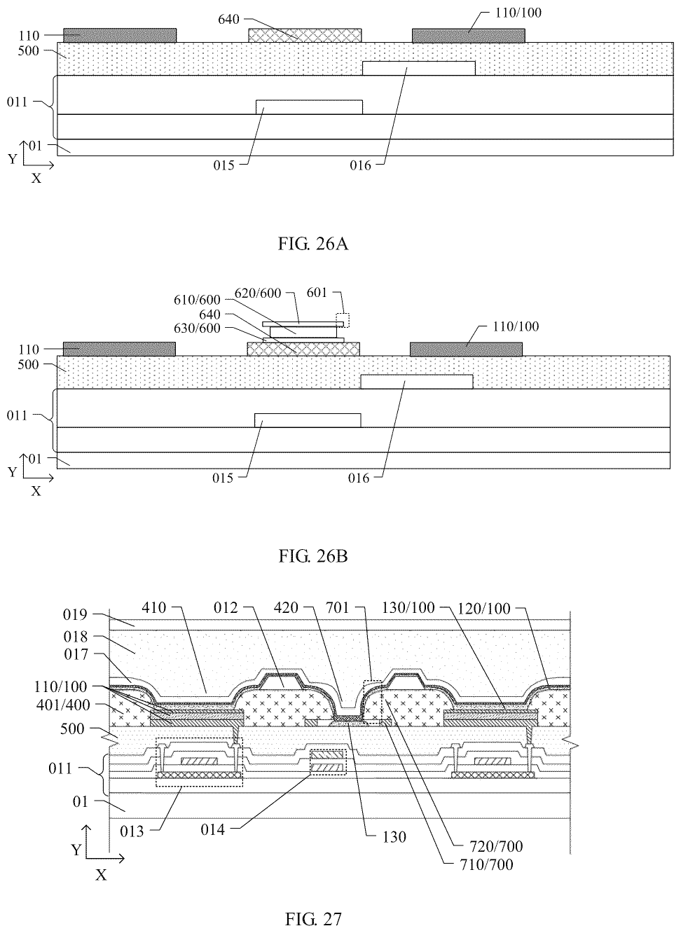

For example, FIGS. 26A-26B are flow charts of a manufacturing method of a display substrate before the formation of the structure shown in FIG. 25. For example, as shown in FIGS. 25 and 26A, the manufacturing method of the display substrate can include manufacturing a base substrate 01 on a glass carrier. The base substrate 01 formed in the present example can have the same features as the base substrate 01 formed in the display substrate shown in FIGS. 4A and 5A, and details will not be repeated here.

For example, as shown in FIGS. 25 and 26A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 25 and 26A, an electrode layer is formed on the planarization layer 500, and the electrode layer is patterned to form the first electrode 110. For example, the blocking portion 640 can be formed before the first electrode 110 is formed, or can be formed after the first electrode 110 is formed.

For example, as shown in FIGS. 25 and 26B, a third sub-isolation structure layer, a first sub-isolation structure layer and a second sub-isolation structure layer are sequentially formed on the blocking portion 640, and then a three-layer isolation structure pattern is formed by dry etching. Subsequently, the first sub-isolation structure pattern located in the middle layer is wet etched (the etching selectivity ratio of the etching solution to the material of the first sub-isolation structure pattern is greater than the etching selectivity ratio of the etching solution to the materials of the second sub-isolation structure pattern and the third sub-isolation structure pattern), so that the edge of the first sub-isolation structure pattern shrinks relative to the edge of the second sub-isolation structure pattern to form an undercut structure at the edge of the second sub-isolation structure pattern and the edge of the first sub-isolation structure pattern, thus forming the isolation structure 600.

For example, as shown FIGS. 25 and 26B, the material of the blocking portion 640 is different from the materials of the first sub-isolation structure 610, the second sub-isolation structure 620 and the third sub-isolation structure 630, so as to prevent the blocking portion 640 from being influenced in the process of forming the first sub-isolation structure 610, the second sub-isolation structure 620 and the third sub-isolation structure 630.

For example, as shown in FIGS. 25 and 26B, after the isolation structure 600 is formed, a pixel defining film is formed on the isolation structure 600 and the first electrode 110, and the pixel defining film is patterned to form a first opening 410 exposing the first electrode 110 and a second opening 420 exposing the isolation structure 600.

In the present example, the process method of forming film layers after the pixel defining film is formed can be the same as the process method of forming film layers after the pixel defining film is formed in the display substrate as shown in FIGS. 1A-5D, and details will not be repeated here.

For example, the arrangement manner of the plurality of sub-pixels in the display substrates shown in FIGS. 11A-26B can be the same as the arrangement manner of the plurality of sub-pixels in the display substrates shown in FIGS. 10A-10E, and the isolation structure 600 shown in FIGS. 11A-26B can be located at the position of the groove 210 shown in FIGS. 10A-10E. For example, the isolation structures 600 shown in FIGS. 11A-26B can have the same arrangement manner as the grooves 210 shown in FIGS. 10A-10E, and the isolation structures 600 shown in FIGS. 11A-26B can replace the grooves 210 shown in FIGS. 10A-10E.

For example, in the case where the isolation structure is located in the planarization layer, the pixel defining portion between adjacent sub-pixels can be retained or removed; and in the case where the isolation structure is located in the second opening of the pixel defining pattern, the pixel defining portion between adjacent sub-pixels can be retained.

Another embodiment of the present disclosure provides a display device, which includes any of the display substrates shown in FIGS. 11A-26B. By arranging an isolation structure between adjacent sub-pixels in the display device, the charge generation layer can be disconnected at the edge of the isolation structure, which is helpful to reduce the probability of crosstalk between adjacent sub-pixels.

For example, the display device further includes a cover plate located at the light-exiting side of the display panel.

For example, the display device can be a display, such as an organic light-emitting diode display, etc., or any product or component having display function and including the display, such as a TV, a digital camera, a mobile phone, a watch, a tablet computer, a notebook computer, a navigator, etc., without being limited in the present embodiment.

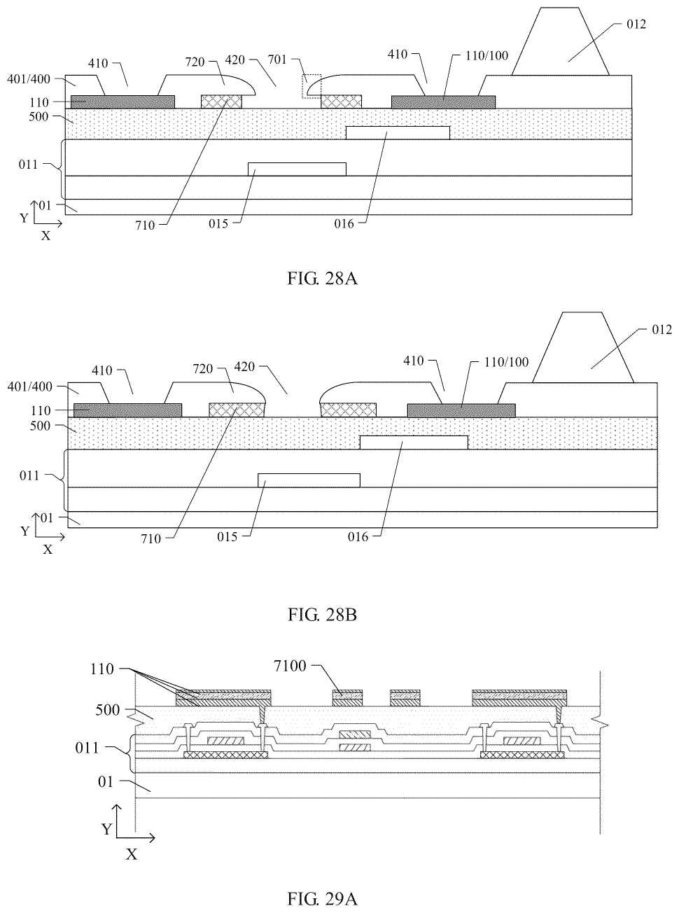

FIG. 27 is a partial cross-sectional structural view of a display substrate provided by an example of another embodiment of the present disclosure, FIG. 28A is a partial cross-sectional structural view of a display substrate provided by another example of another embodiment of the present disclosure, and FIG. 28B is a partial cross-sectional structural view of a display substrate provided by another example of another embodiment of the present disclosure. The display substrate shown in FIG. 27 can have the same first display region A1 and second display region A2 as the display substrate shown in FIG. 1C. As shown in FIGS. 27 to 28B, the display substrate includes a base substrate 01 and a plurality of sub-pixels 10 in the first display region A1 of the base substrate 01. The sub-pixel 10 includes an organic light-emitting element 100, the organic light-emitting element 100 includes a light-emitting functional layer 130 and a first electrode 110 and a second electrode 120 located at both sides of the light-emitting functional layer 130 along the direction perpendicular to the base substrate 01, the first electrode 110 is located between the light-emitting functional layer 130 and the base substrate 01, and the light-emitting functional layer 130 includes a plurality of film layers. For example, the plurality of film layers includes a charge generation layer 133 (which can be the charge generation layer 133 as shown in FIG. 1 or FIG. 11A). The display substrate further includes an isolation portion 700, the isolation portion 700 includes a first sub-isolation portion 710 and a second sub-isolation portion 720 which are stacked, and the first sub-isolation portion 710 is located between the second sub-isolation portion 720 and the base substrate 01. For example, the material of the first sub-isolation portion 710 includes an inorganic non-metallic material or a metallic material, and the material of the second sub-isolation portion 720 includes an organic material.

As shown in FIGS. 27 and 28A, the second sub-isolation portion 720 includes a protrusion 701 protruding relative to the edge of the first sub-isolation portion 710, and the protrusion 701 is located between adjacent sub-pixels 100.

As shown in FIG. 28B, a slope angle between at least part of a side surface of the first sub-isolation portion 710 and a plane parallel to contact surfaces of the first sub-isolation portion 710 and the second sub-isolation portion 720 is greater than 60 degrees and less than 120 degrees, and/or a slope angle between at least part of a side surface of the second sub-isolation portion 720 and the plane parallel to the contact surfaces of the first sub-isolation portion 710 and the second sub-isolation portion 720 is greater than 60 degrees and less than 120 degrees.

For example, the slope angle between at least part of the side surface of the first sub-isolation portion 710 and the plane parallel to the contact surfaces of the first sub-isolation portion 710 and the second sub-isolation portion 720 is greater than 70 degrees and less than 110 degrees, and/or the slope angle between at least part of the side surface of the second sub-isolation portion 720 and the plane parallel to the contact surfaces of the first sub-isolation portion 710 and the second sub-isolation portion 720 is greater than 70 degrees and less than 110 degrees. For example, the slope angle between at least part of the side surface of the first sub-isolation portion 710 and the plane parallel to the contact surfaces of the first sub-isolation portion 710 and the second sub-isolation portion 720 is greater than 80 degrees and less than 100 degrees, and/or the slope angle between at least part of the side surface of the second sub-isolation portion 720 and the plane parallel to the contact surfaces of the first sub-isolation portion 710 and the second sub-isolation portion 720 is greater than 80 degrees and less than 100 degrees.

The slope angle between at least part of the side surface of the first sub-isolation portion and the plane parallel to the contact surfaces of the first sub-isolation structure and the second sub-isolation portion can be an included angle between the surface of the first sub-isolation portion away from the base substrate and the side surface of the first sub-isolation portion, and can also be an included angle between the surface of the first sub-isolation portion facing the base substrate and the side surface of the first sub-isolation portion; the slope angle between at least part of the side surface of the second sub-isolation portion and the plane parallel to the contact surfaces of the first sub-isolation portion and the second sub-isolation portion can be an included angle between the surface of the second sub-isolation portion away from the base substrate and the side surface of the second sub-isolation portion, and can also be an included angle between the surface of the second sub-isolation portion facing the base substrate and the side surface of the second sub-isolation portion. The side surface of the first sub-isolation portion can refer to a surface of the first sub-isolation portion having a certain included angle with the base substrate, and the side surface of the second sub-isolation portion can refer to a surface of the second sub-isolation portion having a certain included angle with the base substrate.

The difference between the examples shown in FIG. 28A and FIG. 28B lies in the positional relationship and the angular relationship between the first sub-isolation portion 710 and the second sub-isolation portion 720.

As shown in FIGS. 27-28B, at least one film layer among the plurality of film layers included in the light-emitting functional layer 130 is disconnected at the isolation portion 700. For example, the light-emitting functional layer 130 includes a charge generation layer 133, and the charge generation layer 133 is disconnected at the edge of the isolation portion 700.

In the embodiment of the present disclosure, the isolation portion is arranged between adjacent sub-pixels in the display substrate, by adjusting the relative positional relationship between the first sub-isolation structure and the second sub-isolation portion, or adjusting the angle of the side surface of the first sub-isolation portion and the angle of the side surface of the second sub-isolation portion, at least one film layer of the light-emitting functional layer can be disconnected at the protrusion of the second sub-isolation portion relative to the edge of the first sub-isolation portion or at the edge of the isolation portion, which is helpful to reduce the probability of crosstalk between adjacent sub-pixels.

In the embodiment of the present disclosure, by arranging the isolation portion between adjacent sub-pixels in the display substrate, the charge generation layer can be disconnected at the edge of the isolation portion, which is helpful to reduce the probability of crosstalk between adjacent sub-pixels.

The base substrate 01 and the organic light-emitting element 100 in the present embodiment can have the same features as the base substrate 01 and the organic light-emitting element 100 in the embodiments shown in FIGS. 1A-9B, and details will not be repeated here. Other film layers 011 in the present example can have the same features as other film layers 011 in the embodiment shown in FIGS. 1A-9B, and details will not be repeated here. The planarization layer 500 in the present example can have the same features as the planarization layer 500 shown in FIGS. 16-26B, and details will not be repeated here.

For example, as shown in FIG. 27, the plurality of sub-pixels 10 can include two adjacent sub-pixels 10 arranged along the X direction. For example, the plurality of isolation portions 700 provided between two adjacent sub-pixels 10 are arranged along the X direction. For example, FIG. 27 illustratively shows that at least one group of isolation portions are arranged between adjacent sub-pixels 100, and each group of isolation portions includes two isolation portions 700 arranged at intervals. The two isolation portions 700 are arranged along the arrangement direction of the adjacent sub-pixels 100 (e.g., the X direction) and are arranged at intervals, and the protrusions 701 of the two isolation portions 700 are close to each other. But it is not limited thereto, and three or more isolation portions that are spaced apart from each other can be arranged between adjacent sub-pixels 100. For example, the edge of the first sub-isolation portion 710 shrinks relative to the edge of the second sub-isolation portion 720 covering the first sub-isolation portion 710 to form an undercut structure, and the protrusion 701 of the second sub-isolation portion 720 is suspended.

For example, in the case where the isolation portion 700 is not provided between the two adjacent sub-pixels 10, a common film layer (e.g., including a charge generation layer) in the light-emitting functional layers 130 of the two adjacent sub-pixels 10 is a whole-layer film layer. Because the charge generation layer has a high conductivity, for a display device with high resolution, the high conductivity of the charge generation layer easily leads to crosstalk between adjacent sub-pixels 10.

In the display substrate provided by the embodiment of the present disclosure, by setting the isolation portion between the two adjacent sub-pixels, the charge generation layer formed at the protrusion of the isolation portion can be disconnected. And in this case, the charge generation layers of the two adjacent sub-pixels are arranged at intervals, so that the resistance between the light-emitting functional layers of adjacent sub-pixels can be increased, thereby reducing the probability of crosstalk between the two adjacent sub-pixels without affecting the normal display of the sub-pixels.

For example, as shown in FIG. 27, along the arrangement direction of the adjacent sub-pixels 10, the gap between two first sub-isolation portions 710 in the two isolation portions 700 is greater than the gap between two second sub-isolation portions 720 in the two isolation portions 700.

For example, as shown in FIG. 27, there is a gap between the first sub-isolation portion 710 and the film layer disconnected at the position between two isolation portions 700, and the orthographic projection of the disconnected film layer on the base substrate 01 overlaps or contacts with the orthographic projection of the second sub-isolation portion 720 on the base substrate 01.

For example, as shown in FIG. 27, in the direction perpendicular to the base substrate 01, the maximum thickness of the second sub-isolation portion 720 is greater than the maximum thickness of the first sub-isolation portion 710. For example, the average thickness of the second sub-isolation portion 720 is greater than the average thickness of the first sub-isolation portion 710.

For example, as shown in FIG. 27, in the direction perpendicular to the base substrate 01, the thickness of the protrusion 701 is less than the thickness of a part of the second sub-isolation portion 720 other than the protrusion 701. For example, the difference between the thickness of the protrusion 701 and the thickness of the part of the second sub-isolation portion 720 other than the protrusion 701 can be the thickness of the first sub-isolation portion 710.

For example, as shown in FIG. 28B, the surface of the protrusion 701 away from the base substrate 01 includes a curved surface, and the curved surface is bent toward the first sub-isolation portion 710, and the slope angle of the curved surface of the protrusion 701 is in the range of 15-70 degrees. For example, the slope angle of the curved surface of the protrusion 701 is in the range of 30-60 degrees. For example, the slope angle of the curved surface of the protrusion 701 is in the range of 40-50 degrees. For example, the slope angle of the curved surface of the protrusion 701 is smaller than the included angle between the side surface of the first sub-isolation portion 710 and the base substrate 01. For example, a side edge of the first sub-isolation portion 710 can be a curved edge or a straight edge, and for example, the side edge of the first sub-isolation portion 710 can be bent towards the center of the first sub-isolation portion 710. For example, the included angle between the side edge of the first sub-isolation portion 710 and the surface of the first sub-isolation portion 710 away from the base substrate 01 can be in the range of 60-90 degrees. For example, the included angle between the side edge of the first sub-isolation portion 710 and the surface of the first sub-isolation portion 710 close to the base substrate 01 can be in the range of 60-90 degrees. The included angle between the curved edge and a surface can refer to an included angle between the surface and the tangent at the intersection point of the curved edge and the surface. But not limited thereto, it can also refer to the included angle between the tangent at the midpoint of the curved edge and the surface.

For example, as shown in FIG. 27, in the light-emitting functional layer 130, the film layer located at one side of the charge generation layer 133 facing the base substrate 01 is disconnected at the isolation portion 710.

For example, as shown in FIG. 27, the color of light emitted by the first light-emitting layer is the same as the color of light emitted by the second light-emitting layer. For example, in the same sub-pixel, the color of light emitted by the first light-emitting layer is the same as the color of light emitted by the second light-emitting layer, and in at least two adjacent sub-pixels, the colors of light emitted by the light-emitting layers are different.

For example, as shown in FIG. 27, the light-emitting functional layer 130 includes a light-emitting layer (a first light-emitting layer or a second light-emitting layer), and the area of the orthographic projection of at least one disconnected film layer in the light-emitting functional layer 130 on the base substrate 01 is greater than the area of the orthographic projection of the light-emitting layer (the first light-emitting layer or the second light-emitting layer) on the base substrate 01. For example, the disconnected film layer can be a common layer, and the light-emitting layer can be a patterned film layer formed by a fine metal mask.

For example, the light-emitting functional layer 130 includes at least one light-emitting layer (first light-emitting layer or second light-emitting layer), and at least one light-emitting layer and at least one other film layer are included in the film layers disconnected at the isolation portion 700. For example, the area of the orthographic projection of the at least one other film layer which is disconnected on the base substrate 01 is greater than the area of the orthographic projection of the at least one light-emitting layer which is disconnected on the base substrate 01. For example, the area of a part of the isolation portion 700 covered by the at least one other film layer disconnected is greater than the area of a part of the isolation portion 700 covered by the at least one light-emitting layer disconnected. For example, the at least one other film layer disconnected completely covers the isolation portion 700, and the at least one light-emitting layer disconnected covers only part of the isolation portion 700.

For example, at least one film layer among the plurality of film layers included in the light-emitting functional layer 130 and the second electrode 120 overlap in projection on the base substrate 01 with the isolation portion 700.

For example, at least one film layer among the plurality of film layers included in the light-emitting functional layer 130 at least partially covers a part of the side surface of the isolation portion 700. For example, the film layer described above can cover the side surface of the first sub-isolation portion 710 and/or cover the side surface of the second sub-isolation portion 720.

For example, as shown in FIG. 27, in the direction perpendicular to the base substrate 01, the thickness of the first sub-isolation portion 710 is less than the thickness of the second sub-isolation portion 720.

For example, as shown in FIG. 27, in the arrangement direction of adjacent sub-pixels, e.g., the X direction, in the isolation portion 700 between the adjacent sub-pixels, the size of the protrusion 701 can be greater than the size of the first sub-isolation portion 710. But it is not limited thereto, and the size of the protrusion in the above arrangement direction can be less than or equal to the size of the first sub-isolation portion.

For example, at least one film layer among the plurality of film layers in the light-emitting functional layer 130 is disconnected at an edge of the isolation portion 700 facing one of the adjacent sub-pixels, and is not disconnected at an edge facing the other of the adjacent sub-pixel.

For example, the slope angle of at least a part of the second sub-isolation portion 720 facing one of the adjacent sub-pixels is different from the slope angle of at least a part of the second sub-isolation portion 720 facing the other of the adjacent sub-pixel; and/or, at least a part of the second sub-isolation portion 720 facing one of the adjacent sub-pixels has a protrusion, and a part of the second sub-isolation portion 720 facing the other of the adjacent sub-pixel does not have a protrusion.

For example, at the part of the isolation portion where the protrusion is located, the orthographic projection of the first sub-isolation portion on the base substrate falls within the orthographic projection of the second sub-isolation portion on the base substrate.

For example, as shown in FIG. 27, the display substrate further includes a pixel defining pattern 400, the pixel defining pattern 400 includes a plurality of first openings 410, the plurality of first openings 410 are arranged in one-to-one correspondence with the plurality of sub-pixels 100 to define light-emitting regions of the plurality of sub-pixels, and the first openings 410 are configured to expose the first electrodes 110. For example, the pixel defining pattern 400 includes a pixel defining portion 401 surrounding the first opening 410. For example, the pixel defining pattern 400 further includes a second opening 420, and the pixel defining portion 401 surrounds the second opening 420.

For example, as shown in FIGS. 27-28B, the pixel defining pattern 400 includes a pixel defining portion 401 located between a first opening 410 and a second opening 420 which are arranged adjacent to each other, one end of the pixel defining portion 401 is configured to form a first opening 410, the other end of the pixel defining portion 401 includes a second sub-isolation portion 720, and the pixel defining portion 401 is so formed that an included angle between a sidewall of the first opening 410 and a plane parallel to the base substrate 01 is different from an included angle between a sidewall of the second sub-isolation portion 720 and the plane parallel to the base substrate 01. For example, the sidewall of the first opening 410 and the sidewall of the second opening 420 can have different inclination angles or different shapes.

For example, as shown in FIG. 27, the pixel defining pattern 400 includes a second sub-isolation portion 720. For example, the pixel defining portion 401 surrounding the second opening 420 includes a second sub-isolation portion 720, and the second sub-isolation portion 720 is a part of the pixel defining pattern 400, that is, part of the pixel defining portion 401 is also used as the second sub-isolation portion 720.

For example, as shown in FIG. 27, the first electrode 110 includes at least one electrode layer, and the first sub-isolation portion 710 is arranged in the same layer as one electrode layer of the first electrode 110. For example, the first electrode 110 and the first sub-isolation portion 710 may both be disposed on the planarization layer 500. For example, the first electrode 110 can include three electrode layers which are stacked, and the three electrode layers sequentially include indium tin oxide (ITO), silver (Ag) and indium tin oxide (ITO); but not limited thereto, and the three electrode layers can also sequentially include titanium (Ti), aluminum (Al) and titanium (Ti), or molybdenum (Mo), aluminum neodymium alloy (AlNd) and indium tin oxide (ITO).

For example, the first electrode includes at least one electrode layer, the first sub-isolation portion includes at least one film layer, one film layer of the first sub-isolation portion is arranged in the same layer as one electrode layer of the first electrode, and the pixel defining portion is configured to separate the first sub-isolation portion from the first electrode.

For example, the material of the electrode layer, which is arranged in the same layer as a certain film layer of the first sub-isolation portion, of the first electrode is the same as the material of the certain film layer.

For example, in the case where the first electrode 110 includes a plurality of electrode layers, the first sub-isolation portion 710 can be arranged in the same layer as the electrode layer, closest to the base substrate 01, in the first electrode 110.

For example, as shown in FIG. 27, the material of the electrode layer, which is arranged in the same layer as the first sub-isolation portion 710, in the first electrode 110 is the same as the material of the first sub-isolation portion 710. For example, the material of the first sub-isolation portion 710 can be the same as the material of the electrode layer, closest to the base substrate 01, in the first electrode 110, and for example, can be indium tin oxide.

For example, the size of the protrusion of the second sub-isolation portion 720 relative to the first sub-isolation portion 710 can be in the range of 0.1-5 microns. For example, the size of the protrusion of the second sub-isolation portion 720 relative to the first sub-isolation portion 710 can be in the range of 0.2-1 micron.

For example, as shown in FIG. 27, the ratio of the thickness of the first sub-isolation portion 710 to the thickness of the light-emitting functional layer is in the range of 0.7-1.3. For example, the ratio of the thickness of the first sub-isolation portion 710 to the thickness of the light-emitting functional layer is in the range of 0.8-1.2. For example, the ratio of the thickness of the first sub-isolation portion 710 to the thickness of the light-emitting functional layer is in the range of 0.9-1.2.

For example, the thickness of the first sub-isolation portion 710 can be set relatively small, e.g., 1000-5000 angstroms, e.g., 2000-4000 angstroms, so that the charge generation layer formed at the position of the protrusion 701 of the second sub-isolation portion 720 is disconnected, while the second electrode 120 at the position of the protrusion 701 is not disconnected, thus ensuring that the second electrode 120 has better electrical characteristics.

For example, as shown in FIG. 27, the light-emitting functional layer 130 is filled in the undercut structure formed by the first sub-isolation portion 710 and the second sub-isolation portion 720 after being disconnected at the edge of the isolation portion 700, so that the second electrode is not disconnected as much as possible on the basis of disconnecting the charge generation layer by the isolation portion, thus ensuring that the second electrode has good electrical characteristics and ensuring uniformity of brightness. Of course, the embodiment of the present disclosure is not limited thereto, and the thickness of the first sub-isolation portion can also be set relatively large, so that the second electrode is disconnected at the position of the undercut structure of the isolation portion (similar to the disconnection of the second electrode 120 at the position of the undercut structure shown in FIG. 4B).

For example, as shown in FIG. 27, the first sub-isolation portion 710 is spaced apart from the first electrode 110. For example, the pixel defining portion 401 of the pixel defining pattern 400 is configured to separate the first sub-isolation portion 710 from the first electrode 110.

For example, FIG. 28A is a partial cross-sectional structural view of a display substrate provided by an example of another embodiment of the present disclosure. The display substrate in the example shown in FIG. 28A is different from the display substrate shown in FIG. 27 in that the material of the first sub-isolation portion 710 in the display substrate shown in FIG. 28A is different from the material of the first electrode 110. For example, in an example of one embodiment of the present disclosure, the material of the first sub-isolation portion 710 can include any one or more of silicon nitride, silicon oxide or silicon oxynitride.

The base substrate 01 and the organic light-emitting element 100 in the display substrate shown in FIG. 28A can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 in the present example can have the same features as the planarization layer 500 shown in FIGS. 16-26B, and details will not be repeated here. The pixel defining pattern 400 in the present example can have the same features as the pixel defining pattern 400 shown in FIG. 27, and details will not be repeated here.

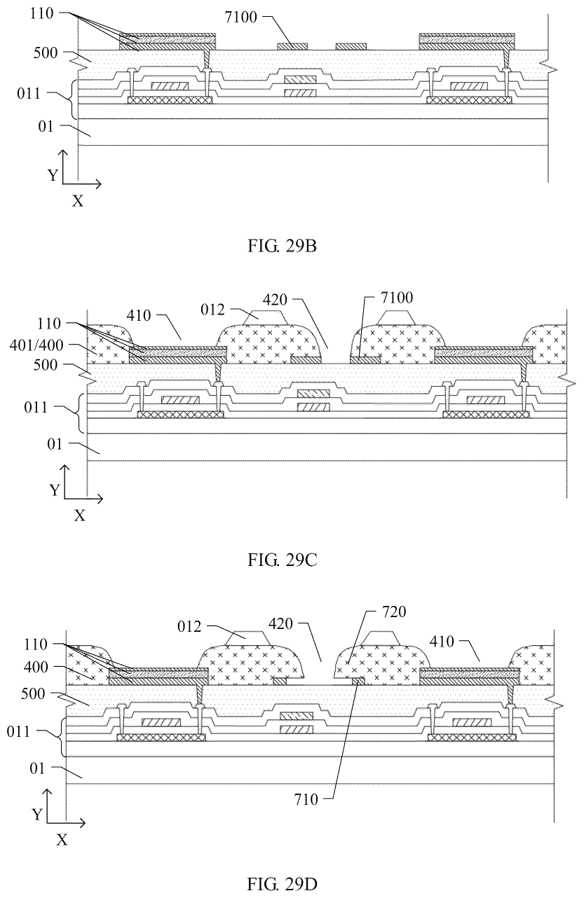

For example, FIGS. 29A-29D are flow charts of a manufacturing method of a display substrate before the formation of the structure shown in FIG. 27. For example, as shown in FIGS. 27 and 29A-29D, the manufacturing method of the display substrate includes: forming a plurality of sub-pixels 100 on a base substrate 01, in which forming the sub-pixels 100 includes sequentially forming a second electrode 120, a light-emitting functional layer 130 and a first electrode 110 which are stacked in a direction perpendicular to the base substrate 01; forming an inorganic layer pattern by patterning on the base substrate 01; forming an organic layer on the inorganic layer pattern, and patterning the organic layer to form an opening pattern 420; etching the inorganic layer pattern to form a first sub-isolation portion 710. The edge of the opening pattern 420 includes a second sub-isolation portion 720 stacked with the first sub-isolation portion 710, the edge of the first sub-isolation portion 710 extends outward relative to the edge of the second sub-isolation portion 720 so that the second sub-isolation portion 720 includes a protrusion 701 protruding relative to the edge of the first sub-isolation portion 710, and the protrusion 701 is located between adjacent sub-pixels 100. After the first sub-isolation portion 710 is formed, a light-emitting functional layer 130 is formed on the second sub-isolation portion 720, the light-emitting functional layer includes a charge generation layer, and the charge generation layer is disconnected at the protrusion 701 of the second sub-isolation portion 720.

For example, as shown in FIGS. 27 and 29A, the manufacturing method of the display substrate can include manufacturing a base substrate 01 on a glass carrier. The base substrate 01 formed in the present example can have the same features as the base substrate 01 formed in the display substrates shown in FIGS. 4A and 5A, and details will not be repeated here. For example, as shown in FIGS. 27 and 29A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 27 and 29A, an electrode layer is formed on the planarization layer 500, and the electrode layer is patterned to form a first electrode 110 and a first sub-isolation portion pattern 7100. For example, two first sub-isolation portion patterns 7100 can be arranged between adjacent first electrodes 110, and the distance between these two first sub-isolation portion patterns 7100 can be in the range of 2-15 microns. For example, as shown in FIG. 29A, both the first electrode 110 and the first sub-isolation portion pattern 7100 include a plurality of film layers which are stacked. For example, as shown in FIG. 29A, both the first electrode 110 and the first sub-isolation portion pattern 7100 include indium tin oxide (ITO), silver (Ag) and indium tin oxide (ITO) which are stacked, but not limited thereto, and can also include titanium (Ti), aluminum (Al) and titanium (Ti) in turn, or molybdenum (Mo) and aluminum-neodymium alloy (AlNd) and indium tin oxide (ITO).

For example, as shown in FIGS. 27 and 29B, the first electrode 110 is shielded by a mask, and the first sub-isolation portion pattern 7100 exposed by the mask is etched to retain one film layer, closest to the base substrate 01, in the first sub-isolation portion pattern 7100. For example, an indium tin oxide layer is retained after the first sub-isolation portion pattern 7100 is etched. For example, in the process of etching the first sub-isolation portion pattern 7100, the etching degree can be controlled to control the thickness of the retained film layer. For example, the thickness of an indium tin oxide layer retained after the first sub-isolation portion pattern 7100 is etched can be in the range of 1000-5000 angstroms. By setting the thickness of this film layer relatively small, it can be ensured that while the charge generation layer is disconnected at the protrusion of the isolation portion, the second electrode is not disconnected at the protrusion; and therefore, the second electrode has better electrical characteristics.

For example, as shown in FIGS. 27 and 29C-29D, the inorganic layer pattern 7100 is located between adjacent sub-pixels 100, and the formed opening pattern 420 exposes the inorganic layer pattern 7100, or the edge of the formed opening pattern 420 is flush with the edge of the inorganic layer pattern 7100; the inorganic layer pattern 7100 is etched so that the edge of the retained part of the inorganic layer pattern 7100 and the edge of the opening pattern 420 form an undercut structure. For example, the retained part of the inorganic layer pattern 7100 is the first sub-isolation portion 710.

For example, as shown in FIGS. 27 and 29C, after the first sub-isolation portion pattern 7100 (also referred as an inorganic layer pattern 7100) is etched and one film layer is retained, a pixel defining film and a spacer layer are formed on the film layer and the first electrode 110, the pixel defining film is patterned to form a pixel defining pattern 400, and the spacer layer is patterned to form spacers 012. For example, as shown in FIG. 29C, the pixel defining pattern 400 includes a first opening 410 exposing the first electrode 110 and a second opening 420 (also referred to as an opening pattern 420). For example, the edge of the second opening 420 can be flush with the edge of the retained film layer of the first sub-isolation portion pattern 7100. Of course, the embodiment of the present disclosure is not limited thereto, and one first sub-isolation portion pattern 7100 can be formed between two adjacent first electrodes 110. After the first sub-isolation portion pattern 7100 is etched and one film layer is retained, a pixel defining pattern 400 having a second opening 420 is formed by patterning on the film layer, the second opening 420 exposes the film layer, and the exposed film layer is wet etched to form a first sub-isolation portion 710.

For example, as shown in FIGS. 27 and 29D, the inorganic layer pattern 7100 is wet etched (the etching solution has little influence on the materials of the pixel defining part 401 and the planarization layer 500), so that the edge of the opening pattern 420 forms a protrusion 701 relative to the edge of the retained part of the inorganic layer pattern 7100. But it is not limited thereto, and the inorganic layer pattern 7100 can also be dry etched.

For example, as shown in FIG. 27, the subsequent process flow of forming film layers, such as encapsulation layers 017-019, etc., can be the same as the process flow of forming film layers, such as encapsulation layers, etc., in the display substrate shown in FIG. 7, and details will not be repeated here.

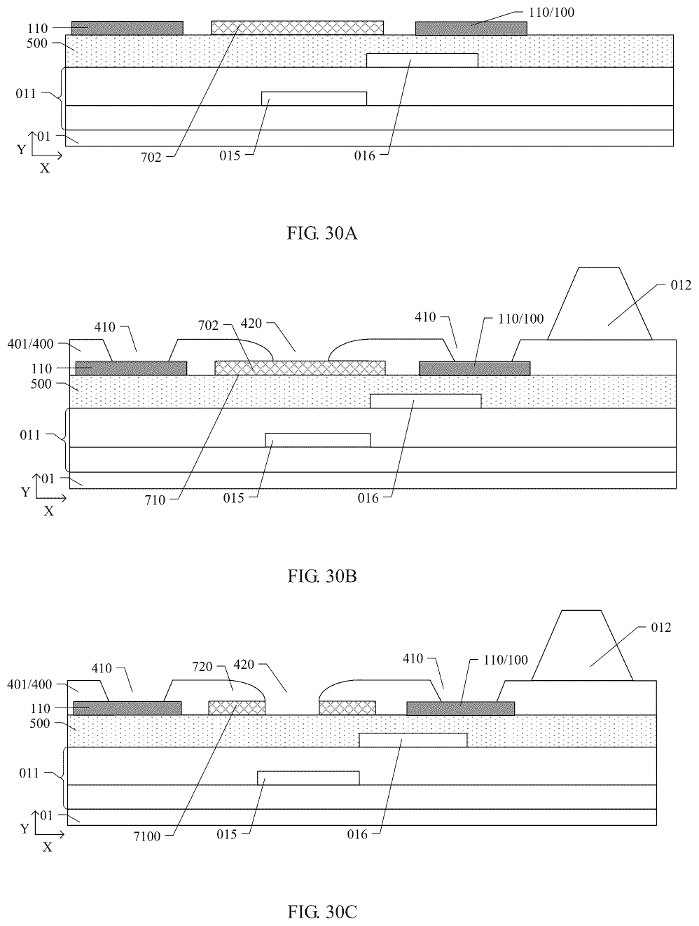

For example, FIGS. 30A-30C are flow charts of a manufacturing method before forming the display substrate shown in FIG. 28A. As shown in FIGS. 28A and 30A, the manufacturing method of the display substrate can include manufacturing a base substrate 01 on a glass carrier. The base substrate 01 formed in the present example can have the same features as the base substrate 01 formed in the display substrates shown in FIGS. 4A and 5A, and details will not be repeated here. For example, as shown in FIGS. 28A and 30A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, a slope angle between at least part of a side surface of the first sub-isolation portion and a plane parallel to the contact surfaces of the first sub-isolation portion and the second sub-isolation portion is greater than 60 degrees and less than 120 degrees, and/or a slope angle between at least part of a side surface of the second sub-isolation portion and the plane parallel to the contact surfaces of the first sub-isolation portion and the second sub-isolation portion is greater than 60 degrees and less than 120 degrees.

For example, as shown in FIGS. 28A and 30A, an inorganic material layer is formed on the planarization layer 500, and the inorganic material layer is patterned to form a first sub-isolation portion material 702. For example, after the first sub-isolation portion material 702 is formed, an electrode layer is formed on the first sub-isolation portion material 702, and the electrode layer is patterned to form a first electrode 110.

For example, as shown in FIG. 30A, one first sub-isolation portion material 702 can be disposed between two adjacent first electrodes 110. For example, a certain space is provided between the first sub-isolation portion material 702 and the first electrode 110. The first electrode 110 in the present example can have the same features as the first electrode 110 shown in FIG. 29A, and details will not be repeated here.

For example, as shown in FIG. 30A, the material of the first sub-isolation portion material 702 is different from that of the first electrode 110. For example, the thickness of the first sub-isolation portion material 702 can be in the range of 1000-5000 angstroms. By setting the thickness of this film layer relatively small, it can be ensured that while the charge generation layer is disconnected at the protrusion of the isolation portion, the second electrode is not disconnected at the protrusion; and therefore, the second electrode has better electrical characteristics. Of course, the thickness of the first sub-isolation portion material 702 can also be set relatively large, so that both the light-emitting functional layer and the second electrode are disconnected at the protrusion of the isolation portion subsequently formed. The embodiment of the present disclosure is not limited thereto. The material of the first sub-isolation portion material 702 can be the same as the material of the first electrode 110, and the first sub-isolation portion material 702 and the first electrode 110 can be formed in the same step patterning process.

For example, as shown in FIGS. 28A and 30B-30C, a pixel defining film and a spacer layer are formed on the first sub-isolation portion material 702 and the first electrode 110, the pixel defining film is patterned to form a pixel defining pattern 400, and the spacer layer is patterned to form spacers 012. For example, as shown in FIGS. 30B-30C, the pixel defining pattern 400 includes a first opening 410 exposing the first electrode 110 and a second opening 420 (also referred to as an opening pattern 420), the second opening 420 exposes a part of the first sub-isolation portion material 702, and the exposed first sub-isolation portion material 702 is etched to form a first sub-isolation portion pattern 7100. For example, as shown in FIGS. 30B-30C, the edge of the second opening 420 can be flush with the edge of the first sub-isolation portion pattern 7100.

For example, as shown in FIGS. 28A and 30C, the edge of the first sub-isolation portion pattern 7100 exposed by the second opening 420 is wet etched, so that the edge of the first sub-isolation portion pattern 7100 shrinks relative to the edge of the pixel defining portion 401 surrounding the second opening 420, so as to form an undercut structure. For example, the edge of the opening pattern 420 forms a protrusion 701 relative to the edge of the retained part of the inorganic layer pattern 7100. For example, the first sub-isolation portion pattern 7100 is wet etched to form the first sub-isolation portion 710.

For example, as shown in FIG. 28A, the subsequent process flow of forming film layers, such as encapsulation layers, etc., can be the same as the process flow of forming film layers, such as encapsulation layers, etc., in the display substrate shown in FIG. 7, and details will not be repeated here.

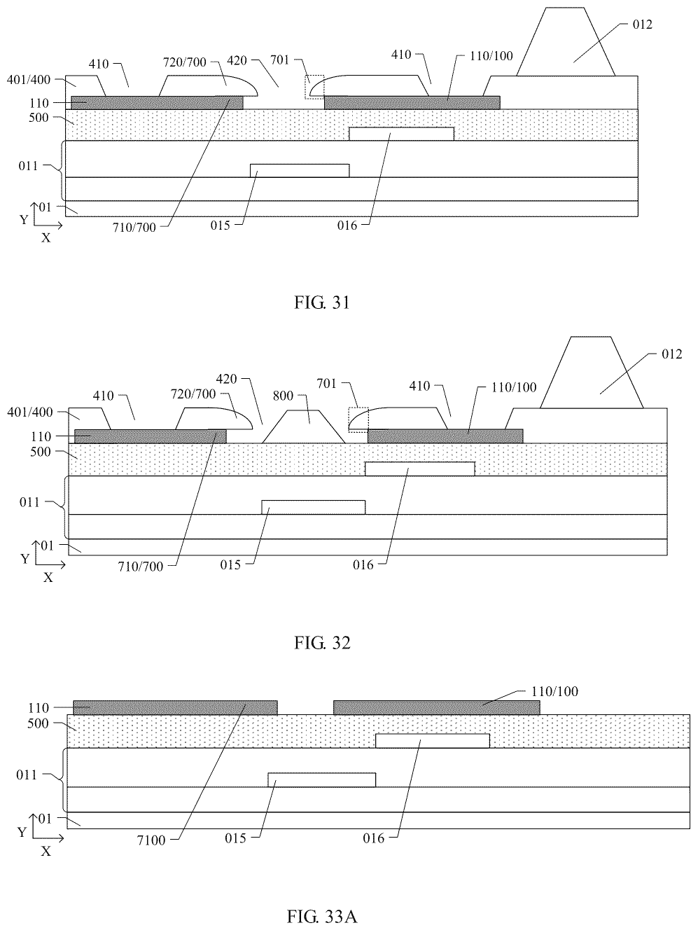

FIG. 31 is a partial cross-sectional structural view of a display substrate provided by an example of another embodiment of the present disclosure. The display substrate in the example shown in FIG. 31 is different from the display substrate shown in FIG. 27 in that the part of the first electrode 110 covered by the second sub-isolation portion 720 includes the first sub-isolation portion 710. The base substrate 01 and the organic light-emitting element 100 in the display substrate shown in FIG. 31 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 in the present example can have the same features as the planarization layers 500 shown in FIGS. 16-26B, and details will not be repeated here.

For example, as shown in FIG. 31, the first electrode 110 and the first sub-isolation portion 710 are an integrated structure, and the pixel defining portion 401 and the second sub-isolation structure 720 are an integrated structure. For example, the first electrode 110 is also used as a first sub-isolation portion 710, and the pixel defining portion 401 is also used as a second sub-isolation structure 720. In the embodiment of the present disclosure, a part of the first electrode and a part of the pixel defining portion is formed as an isolation portion, so that the process can be saved.

For example, as shown in FIG. 31, the pixel defining pattern 400 includes a first opening 410 and a second opening 420, the first opening 410 is configured to expose the first electrode 110, and the second opening 420 exposes a part of the planarization layer 500. For example, the pixel defining pattern 400 includes a pixel defining portion 401 surrounding the first opening 410 and the second opening 420.

For example, as shown in FIG. 31, the pixel defining portion 401 located on the first electrode 110 of a certain sub-pixel extends to a sub-pixel adjacent to the certain sub-pixel, and the edge of the pixel defining portion 01 is closer to the sub-pixel adjacent to the certain sub-pixel than the edge of the first electrode 110 of the certain sub-pixel is.

For example, as shown in FIG. 31, in two adjacent sub-pixels, the distance between the edges, close to each other, of two first electrodes 110 is greater than the distance between the edges, close to each other, of two pixel defining portions 401 located on the two first electrodes 110.

FIG. 32 is a partial cross-sectional structural view of a display substrate provided by an example of another embodiment of the present disclosure. The display substrate in the example shown in FIG. 32 is different from the display substrate shown in FIG. 31 in that a spacing structure 800 is arranged between two protrusions 701 which are close to each other and located between two adjacent sub-pixels. The base substrate 01 and the organic light-emitting element 100 in the display substrate shown in FIG. 32 can have the same features as the base substrate 01 and the organic light-emitting element 100 in the embodiments shown in FIGS. 1A-9B, and details will not be repeated here. Other film layers 011 in the present example can have the same features as other film layers 011 in the embodiments shown in FIGS. 1A-9B, and details will not be repeated here. The planarization layer 500 in the present example can have the same features as the planarization layers 500 shown in FIGS. 16-26B, and details will not be repeated here.

For example, as shown in FIG. 32, a spacing structure 800 is arranged between two protrusions 701 close to each other, the spacing structure 800 is spaced apart from the protrusions 701, and the material of the spacing structure 800 is the same as the material of the second sub-isolation portion 720. For example, in the case where the display substrate is applied to a display product with a low pixel per inch, the distance between adjacent sub-pixels is set relatively large, and the etching amount of the first electrode can be reduced by setting the spacing structure.

For example, as shown in FIG. 32, in the direction perpendicular to the base substrate 01, the ratio of the thickness of the spacing structure 800 to the thickness of the isolation portion 700 can be in the range of 0.8-1.2. For example, the ratio of the thickness of the spacing structure 800 to the thickness of the isolation portion 700 can be in the range of 0.9-1.1. For example, the thickness of the spacing structure 800 can be the same as the thickness of the isolation portion 700.

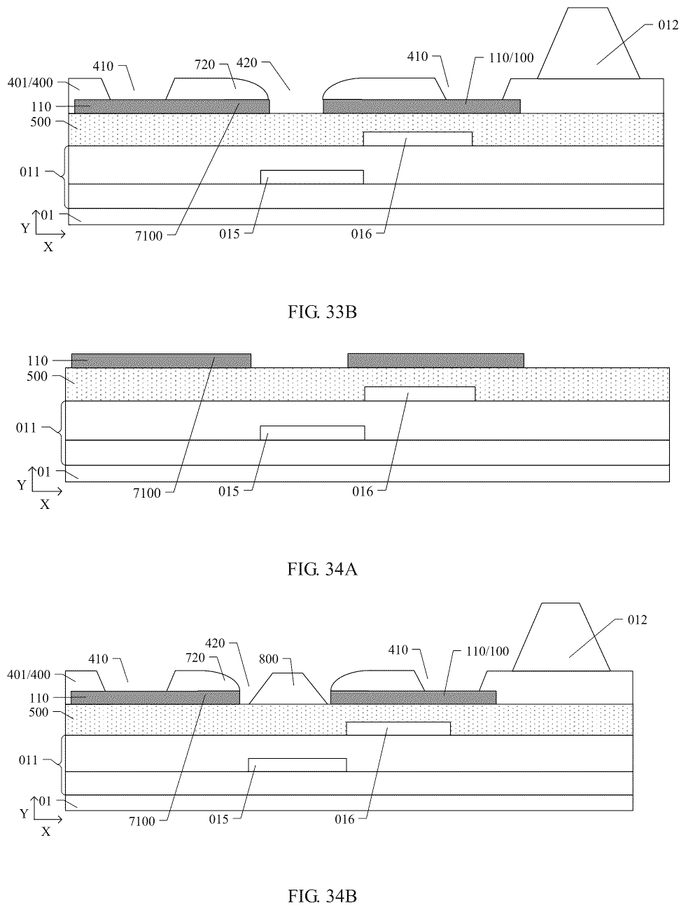

For example, FIGS. 33A-33B are flow charts of a manufacturing method of a display substrate before the formation of the structure shown in FIG. 31. For example, as shown in FIGS. 31 and 33A, the manufacturing method of the display substrate can include manufacturing a base substrate 01 on a glass carrier. The base substrate 01 formed in the present example can have the same features as the base substrate 01 formed in the display substrates shown in FIGS. 4A and 5A, and details will not be repeated here. For example, as shown in FIGS. 31 and 33A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 31 and 33A, an electrode layer is formed on the planarization layer 500, the electrode layer is patterned to form an inorganic layer pattern, and the inorganic layer pattern includes a first electrode 110.

For example, as shown in FIGS. 31 and 33B, a pixel defining film and a spacer layer are formed on the first electrode 110, the pixel defining film is patterned to form a pixel defining pattern 400, and the spacer layer is patterned to form spacers 012.

For example, as shown in FIGS. 31 and 33B, the pixel defining pattern 400 includes a first opening 410 exposing the first electrode 110 and a second opening 420 (also referred to as an opening pattern 420), the second opening 420 exposes the planarization layer 500, and the second opening 420 is located between adjacent sub-pixels. For example, the edge of the second opening 420 can be flush with the edge of the first electrode 110.

For example, as shown in FIGS. 31 and 33B, etching the inorganic layer pattern exposed by the second opening 420 includes etching the part of the first electrode 110 close to the edge of the second opening 420 so that the edge of the first electrode 110 and the edge of the second opening 420 form an undercut structure.

For example, FIGS. 34A-34B are flow charts of a manufacturing method of a display substrate before the formation of the structure shown in FIG. 32. For example, as shown in FIGS. 32 and 34A, the manufacturing method of the display substrate can include manufacturing a base substrate 01 on a glass carrier. The base substrate 01 formed in the present example can have the same features as the base substrate 01 formed in the display substrates shown in FIGS. 4A and 5A, and details will not be repeated here. For example, as shown in FIGS. 32 and 34A, the process flow of forming other film layers 011 and the planarization layer 500 on the base substrate 01 can be the same as the process flow of forming other film layers 011 and the planarization layer 500 in the display substrate shown in FIG. 5A, and can also be the same as the process flow of forming other film layers 011 and the planarization layer 500 in the display substrate shown in FIG. 4A, and details will not be repeated here.

For example, as shown in FIGS. 32 and 34A, an electrode layer is formed on the planarization layer 500, the electrode layer is patterned to form an inorganic layer pattern, and the inorganic layer pattern includes a first electrode 110.

For example, as shown in FIGS. 32 and 34B, a pixel defining film and a spacer layer are formed on the first electrode 110, the pixel defining film is patterned to form a pixel defining pattern 400, and the spacer layer is patterned to form spacers 012.

For example, as shown in FIGS. 32 and 34B, the pixel defining pattern 400 includes a first opening 410 exposing the first electrode 110, a second opening 420 (also referred to as an opening pattern 420) and a spacing structure 800, the second opening 420 exposes the planarization layer 500, the second opening 420 is located between adjacent sub-pixels, and the spacing structure 800 is located in the second opening 420. For example, the edge of the second opening 420 can be flush with the edge of the first electrode 110.

For example, as shown in FIGS. 32 and 34B, etching the inorganic layer pattern exposed by the second opening 420 includes etching the part of the first electrode 110 close to the edge of the second opening 420 so that the edge of the first electrode 110 and the edge of the second opening 420 form an undercut structure.

For example, the arrangement manner of the plurality of sub-pixels in the display substrates shown in FIGS. 27-34B can be the same as the arrangement manner of the plurality of sub-pixels in the display substrates shown in FIGS. 10A-10E, and the isolation portion 700 shown in FIGS. 27-34B can be located at the position of the groove 210 shown in FIGS. 10A-10E. For example, the isolation portions 700 shown in FIGS. 27-34B can have the same arrangement manner as the grooves 210 shown in FIGS. 10A-10E, and the isolation portions 700 shown in FIGS. 27-34B can replace the grooves 210 shown in FIGS. 10A-10E.

For example, the isolation portion is located in the second opening of the pixel defining pattern, and the pixel defining portion between adjacent sub-pixels can be retained.

Another embodiment of the present disclosure provides a display device, which includes any of the display substrates shown in FIGS. 27-34B. By arranging an isolation portion between adjacent sub-pixels in the display device, the charge generation layer can be disconnected at the edge of the isolation portion, which is helpful to reduce the probability of crosstalk between adjacent sub-pixels.

For example, the display device further includes a cover plate located at the light-exiting side of the display panel.

For example, the display device can be a display, such as an organic light-emitting diode display, etc., or any product or component having display function and including the display, such as a TV, a digital camera, a mobile phone, a watch, a tablet computer, a notebook computer, a navigator, etc., without being limited in the present embodiment.

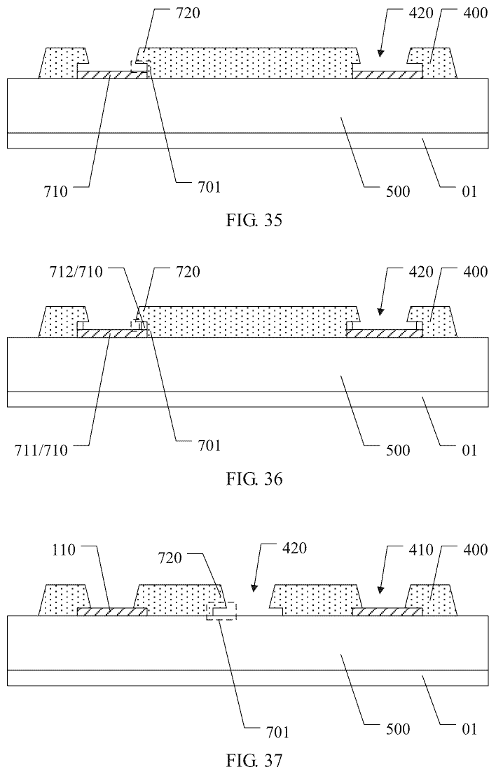

At least one embodiment of the present disclosure further provides a display substrate. FIG. 35 is a structural view of another display substrate provided by an embodiment of the present disclosure. As shown in FIG. 35, the display substrate includes a base substrate 01 and a plurality of sub-pixels (not shown); the plurality of sub-pixels are located on the base substrate 01, and each sub-pixel includes a light-emitting element; each light-emitting element includes a light-emitting functional layer and a first electrode 110 and a second electrode (not shown) located at both sides of the light-emitting functional layer, and the first electrode 110 is located between the light-emitting functional layer and the base substrate 01; the second electrode is at least partially located at one side of the light-emitting functional layer away from the first electrode 110. It should be noted that the specific structures of sub-pixels, light-emitting elements and light-emitting functional layers can be referred to the above-mentioned embodiments, and details will not be repeated here. The embodiment of the present disclosure is different from the embodiments shown in FIGS. 27-34B in that the first sub-isolation portion 710 in the present embodiment includes at least two film layers.

For example, as shown in FIG. 35, the display substrate further includes an isolation portion 700, the isolation portion 700 includes a first sub-isolation portion 710 and a second sub-isolation portion 720 which are stacked, and the first sub-isolation portion 710 is located between the second sub-isolation portion 720 and the base substrate 01.

For example, the first sub-isolation portion 710 includes at least two film layers, and the protrusion 701 protrudes relative to the edge of the film layer, closest to the second sub-isolation portion 720, among the at least two film layers described above; and the at least two film layers include two film layers with different patterns, and/or the at least two film layers include two film layers with different thicknesses.

For example, as shown in FIG. 35, at least one of a plurality of sub-functional film layers in the light-emitting functional layer is disconnected at the position of the isolation portion 700. The display substrate 100 further includes a pixel defining pattern 400; part of the pixel defining pattern 400 is located at one side of the first electrode away from the base substrate 01; and the pixel defining pattern 400 includes a plurality of second openings 420.

As shown in FIG. 35, the second sub-isolation portion 720 includes an inward concave structure, the inward concave structure is located at the edge of the first sub-isolation portion 710 and recessed into the pixel defining pattern 400, and the second sub-isolation portion 720 is a part of the pixel defining pattern 400. Thus, at least one film layer of the light-emitting functional layer is disconnected at the edge of the second sub-isolation portion. Therefore, by arranging the isolation portion between adjacent sub-pixels, the display substrate can avoid crosstalk between adjacent sub-pixels caused by the sub-functional film layer with high conductivity in the light-emitting functional layer.

For example, the thickness of the first sub-isolation portion 710 in the present example is relatively small, and the inward concave structure formed by the second sub-isolation portion 720 is not filled to the full.

On the other hand, the display substrate can avoid crosstalk between adjacent sub-pixels through the isolation portion, so the display substrate can improve the pixel per inch while adopting a Tandem EL design. Therefore, the display substrate has the advantages of long life, low power consumption, high brightness and high resolution, etc.

In some examples, as shown in FIG. 35, the orthographic projection of the inward concave structure on the base substrate 01 overlaps with the orthographic projection of the second sub-isolation portion 720 on the base substrate 01.

FIG. 36 is a structural view of another display substrate provided by an embodiment of the present disclosure. As shown in FIG. 36, the inward concave structure includes a residual structure, and the residual structure can be a film layer 712 in the first sub-isolation portion 710. For example, the first sub-isolation portion 710 includes a film layer 711 and a film layer 712, the protrusion 701 protrudes relative to the edge of the film layer 712, and the patterns of the film layer 711 and the film layer 712 are different.

In some examples, as shown in FIG. 36, the material of the film layer 712 includes a metallic material, metal oxide or an inorganic non-metallic material, and can be, for example, silver or aluminum, and can also include ITO, IZO, etc. The film layer 711 can be a structure in the same layer and having the same material as the first electrode of the light-emitting element, and can include, for example, a multi-layer structure, including ITO/Ag/ITO, etc.

For example, the thickness of the film layer 711 in the present example is relatively small, and does not fill the inward concave structure formed by the second sub-isolation portion 720 to the full. The film layer 712 fills a part, not filled by the film layer 711, of the inward concave structure, but the first sub-isolation portion 710 does not fill the inward concave structure of the second sub-isolation portion 720 to the full, either.

An embodiment of the present disclosure further provides a display substrate.

FIG. 37 is a structural view of another display substrate provided by an embodiment of the present disclosure. The display substrate shown in FIG. 37 provides another pixel isolation structure. As shown in FIG. 37, the display substrate 100 further includes a pixel defining pattern 400 located on the base substrate 01; part of the pixel defining pattern 400 is located at one side of the first electrode 110 away from the base substrate 01; the pixel defining pattern 400 includes a plurality of first opening 410 and a second opening 420; the plurality of first openings 410 are in one-to-one correspondence with the plurality of sub-pixels to define effective light-emitting regions of the plurality of sub-pixels; the first opening 410 is configured to expose the first electrode 110 so that the first electrode 110 is in contact with the light-emitting functional layer 130 subsequently formed. The second opening 420 is located between adjacent first electrodes 110.

As shown in FIG. 37, the pixel defining portion of the pixel defining pattern 400 can be also used as an isolation portion. The isolation portion in the present example may only include the second sub-isolation portion 720, and does not include the first sub-isolation portion in the above examples. Thus, at least one film layer of the light-emitting functional layer is disconnected at the position of the second sub-isolation portion. Therefore, by arranging the second sub-isolation portion between adjacent sub-pixels, the display substrate can avoid crosstalk between adjacent sub-pixels caused by the sub-functional film layer with high conductivity in the light-emitting functional layer.

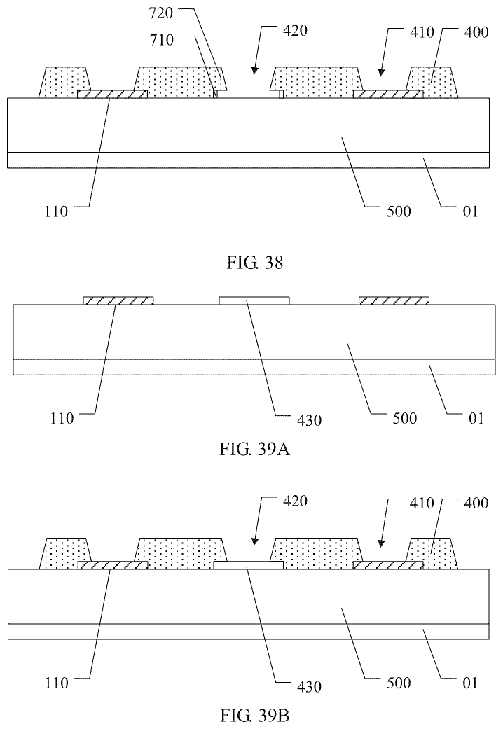

FIG. 38 is a structural view of another display substrate provided by an embodiment of the present disclosure. As shown in FIG. 38, the first sub-isolation portion 710 is arranged in the inward concave structure formed by the second sub-isolation portion 720, and the edge of the second sub-isolation portion 720 extends outward relative to the edge of the first sub-isolation portion 710.

In some examples, as shown in FIG. 38, the material of the first sub-isolation portion 710 includes at least one of metal, metal oxide and organic matter; the metal can be silver, the metal oxide can be indium zinc oxide, and the organic matter can be fluorine-based polymer.

In some examples, in the case where the material of the first sub-isolation portion 710 is a fluorine-based polymer, because the material of the planarization layer includes photoresist, polyimide (PI) resin, acrylic resin, silicon compound or polyacrylic resin, the solvent of the planarization layer is mainly non-fluorinated organic solvent. Although these photoresists may contain a small amount of fluorination, they are not basically soluble in fluorinated solution or perfluoro solvent. Therefore, by utilizing their orthogonal properties (the solution and solvent will not react with each other), the aforementioned pixel partition structure can be formed by etching process.

For example, the above fluorine-based polymer can be a photosensitive fluorine-based polymer, which is a polymer similar to a negative photoresist. Compared with the conventional photoresist, this polymer has a fluorine content of 40-70% and must be dissolved in perfluorinated solvents, such as HFE7100 and HFE7500, etc. However, the perfluorinated solvent cannot dissolve PLN (the fluorine content is insufficient), and fluorine-based polymer cannot dissolve in PLN solvent. These two photoresists and their solvents are orthogonal.

For example, the chemical formula of the above fluorine-based polymer is as follows:

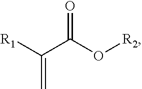

wherein R1 is an alkyl group, H, etc., and R2 is a fluorine-containing group.

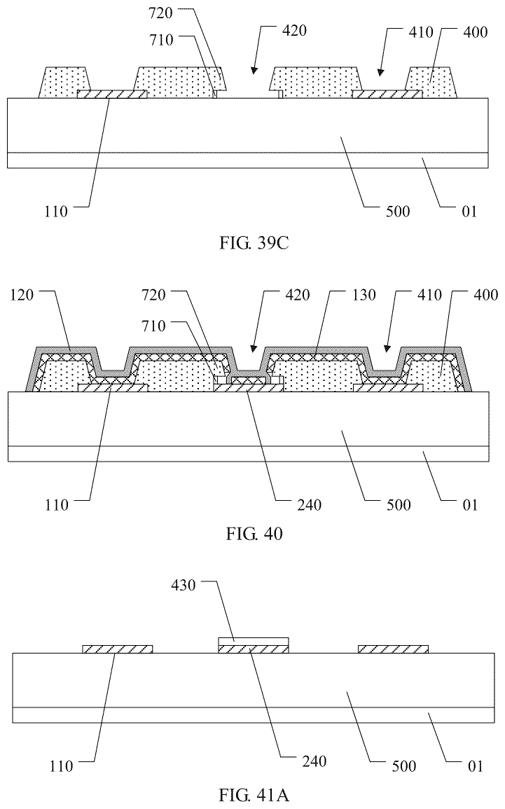

FIGS. 39A-39C are flow charts of another manufacturing method of a display substrate provided by an embodiment of the present disclosure, and the manufacturing method of the display substrate includes the following steps.

As shown in FIG. 39A, a first electrode 110 and a sacrificial structure 430 are formed at one side of the planarization layer 500 away from the base substrate 01. It should be noted that the above-mentioned residual structure (the first sub-isolation portion) can be a part of the sacrificial structure.

As shown in FIG. 39B, a pixel defining pattern 400 is formed at one side of the first electrode 110 and the sacrificial structure 430 away from the base substrate 01. The pixel defining pattern 400 includes a plurality of first openings 410 and a second opening 420; the plurality of first openings 410 are arranged in one-to-one correspondence with the plurality of first electrodes 110; the first opening 410 is configured to expose the first electrode 110, so that the first electrode 110 is in contact with the light-emitting functional layer 130 subsequently formed. The second opening 420 is located between adjacent first electrodes 110, and the sacrificial structure 430 is partially exposed by the second opening 420.

As shown in FIG. 39C, the display substrate is etched by using the pixel defining pattern 400 as a mask, so as to remove the sacrificial structure 430 to form the first sub-isolation portion 710 described above.

FIG. 40 is a structural view of another display substrate provided by an embodiment of the present disclosure. As shown in FIG. 40, the display substrate further includes a protective structure 240 located on the planarization layer 500 and arranged in the same layer as the first electrode 110; the first sub-isolation portion 710 is disposed at one side of the protective structure 240 away from the base substrate 01 and at the edge of the protective structure 240. Therefore, the protective structure 240 can protect the planarization layer 500 in the etching process of manufacturing the first sub-isolation portion 710, and prevent the planarization layer 500 from being etched.

In some examples, as shown in FIG. 40, the display substrate further includes a light-emitting functional layer 130 and a second electrode 120; the light-emitting functional layer 130 is located at one side of the first electrode 110, the pixel defining pattern 400 and the protective structure 240 away from the base substrate 01. Because of the function of the isolation portion, the light-emitting functional layer 130 will be disconnected at the position of the isolation portion, and a fracture will be formed. In this case, the second electrode 120 subsequently formed can be connected to the protective structure 240 through the fracture, and the protective structure 240 can play the role of an auxiliary electrode.

In the display substrate, the second electrode is an electrode shared by the plurality of sub-pixels to provide a cathode signal to the plurality of sub-pixels; even if part of the second electrode in the entire display substrate is disconnected due to the pixel partition structure or other factors, the protective structure, as an auxiliary electrode, can connect the disconnected part of the second electrode with other parts.

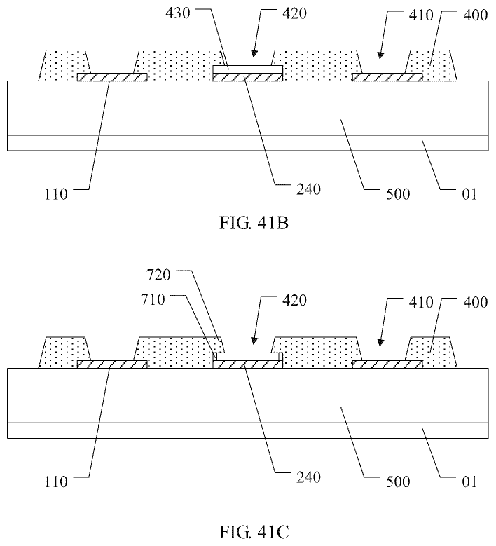

FIGS. 41A-41C are flow charts of another manufacturing method of a display substrate provided by an embodiment of the present disclosure, and the manufacturing method of the display substrate includes the following steps.

For example, as shown in FIG. 41A, a first electrode 110, a protective structure 240 and a sacrificial structure 430 are formed at one side of the planarization layer 500 away from the base substrate 01, and the protective structure 240 is arranged in the same layer as the first electrode 110. The material of the protective structure 240 is the same as the material of the first electrode 110, and the material of the protective structure 240 is different from the material of the sacrificial structure 430.

For example, as shown in FIG. 41B, a pixel defining pattern 400 is formed at one side of the first electrode 110 and the sacrificial structure 430 away from the base substrate 01. The pixel defining pattern 400 includes a plurality of first openings 410 and a second opening 420; the plurality of first openings 410 are arranged in one-to-one correspondence with the plurality of first electrodes 110; the first opening 410 is configured to expose the first electrode 110, so that the first electrode 110 is in contact with the light-emitting functional layer 130 subsequently formed. The second opening 420 is located between adjacent first electrodes 110, and the sacrificial structure 430 is partially exposed by the second opening 420.

For example, as shown in FIG. 41C, the display substrate is etched by using the pixel defining pattern 400 as a mask, so as to remove the sacrificial structure 430 to form the first sub-isolation portion 710 described above.

For example, a light-emitting functional layer 130 and a second electrode 120 are formed at one side of the first electrode 110, the pixel defining pattern 400 and the protective structure 240 away from the base substrate 01. Due to the function of the isolation portion, the light-emitting functional layer 130 will be disconnected at the position of the isolation portion, and a fracture will be formed. In this case, the second electrode 120 subsequently formed can be connected to the protective structure 240 through the fracture, and the protective structure 240 can play the role of an auxiliary electrode.

For example, in the display substrate, the second electrode is an electrode shared by the plurality of sub-pixels to provide a cathode signal to the plurality of sub-pixels; even if part of the second electrode in the entire display substrate is disconnected due to the pixel partition structure or other factors, the protective structure, as an auxiliary electrode, can connect the disconnected part of the second electrode with other parts.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A display substrate, comprising:
a base substrate, at least comprising a first display region;
a plurality of sub-pixels, located in the first display region of the base substrate, wherein each sub-pixel in at least part of the plurality of sub-pixels comprises a light-emitting element, the light-emitting element comprises a light-emitting functional layer and a first electrode and a second electrode located at both sides of the light-emitting functional layer along a direction perpendicular to the base substrate, the first electrode is located between the light-emitting functional layer and the base substrate, and the light-emitting functional layer comprises a plurality of film layers,
wherein the display substrate further comprises an isolation portion, the isolation portion comprises a first sub-isolation portion and a second sub-isolation portion which are stacked, the first sub-isolation portion is located between the second sub-isolation portion and the base substrate, a material of the first sub-isolation portion comprises an inorganic material, and a material of the second sub-isolation portion comprises an organic material;
the second sub-isolation portion comprises a protrusion protruding relative to an edge of the first sub-isolation portion, the protrusion is located between adjacent sub-pixels, at least a part of the second sub-isolation portion facing one of the adjacent sub-pixels is different in shape from at least a part of the second sub-isolation portion facing the other of the adjacent sub-pixels; or, a slope angle between at least part of a side surface of the first sub-isolation portion facing one of the adjacent sub-pixels and a plane parallel to a contact surface of the first sub-isolation portion and the second sub-isolation portion is greater than 60 degrees and less than 120 degrees, and/or a slope angle between at least part of a side surface of the second sub-isolation portion facing one of the adjacent sub-pixels and the plane parallel to the contact surface of the first sub-isolation portion and the second sub-isolation portion is greater than 60 degrees and less than 120 degrees;
at least one film layer among the plurality of film layers is disconnected at the isolation portion.

2. The display substrate according to claim 1, wherein at least one film layer among the plurality of film layers is disconnected at an edge of the isolation portion facing one of the adjacent sub-pixels, and is not disconnected at an edge of the isolation portion facing the other of the adjacent sub-pixels.

3. The display substrate according to claim 1, at least the part of the second sub-isolation portion facing one of the adjacent sub-pixels has a different slope angle from at least the part of the second sub-isolation portion facing the other of the adjacent sub-pixels;
and/or, at least the part of the second sub-isolation portion facing one of the adjacent sub-pixels has the protrusion, and at least the part of the second sub-isolation portion facing the other of the adjacent sub-pixels does not have the protrusion.

4. The display substrate according to claim 1, wherein at least in a part of the isolation portion where the protrusion is located, an orthographic projection of the first sub-isolation portion on the base substrate completely falls within an orthographic projection of the second sub-isolation portion on the base substrate.

5. The display substrate according to claim 1, wherein at least one group of isolation portions arranged at interval are disposed between adjacent sub-pixels, each group of isolation portions comprises two isolation portions, the two isolation portions are arranged along an arrangement direction of the adjacent sub-pixels, and the protrusions of the two isolation portions are close to each other.

6. The display substrate according to claim 5, wherein, in the arrangement direction of the adjacent sub-pixels, a distance between two first sub-isolation portions in the two isolation portions is greater than a distance between two second sub-isolation portions in the two isolation portions.

7. The display substrate according to claim 1, wherein, in the direction perpendicular to the base substrate, a maximum thickness of the second sub-isolation portion is greater than a maximum thickness of the first sub-isolation portion.

8. (canceled)

9. The display substrate according to claim 1, wherein a surface of the protrusion away from the base substrate comprises a curved surface, the curved surface is bent towards the first sub-isolation portion, and a slope angle of the curved surface of the protrusion is in a range of 15-70 degrees.

10. The display substrate according to claim 1, wherein the first sub-isolation portion comprises at least two film layers, the protrusion protrudes relative to an edge of one film layer, closest to the second sub-isolation portion, among the at least two film layers,
the at least two film layers comprise two film layers with different patterns, and/or the at least two film layers comprise two film layers with different thicknesses.

11. The display substrate according to claim 1, further comprising:
a pixel defining pattern, wherein at least the pixel defining pattern located in the first display region comprises a plurality of first openings, one sub-pixel corresponds to at least one first opening, and the light emitting element of the sub-pixel is at least partially located in the at least one first opening corresponding to the sub-pixel, and the at least one first opening is configured to expose the first electrode;
wherein at least part of a pixel defining portion of the pixel defining pattern is also used as the second sub-isolation portion.

12. The display substrate according to claim 11, wherein the first electrode comprises at least one electrode layer, the first sub-isolation portion comprises at least one film layer, one film layer of the first sub-isolation portion is arranged in the same layer as one electrode layer of the first electrode, and the pixel defining portion is configured to separate the first sub-isolation portion from the first electrode.

13-14. (canceled)

15. The display substrate according to claim 1, wherein, in each sub-pixel, the light-emitting functional layer comprises a first light-emitting layer, a charge generation layer and a second light-emitting layer which are stacked, the charge generation layer is located between the first light-emitting layer and the second light-emitting layer, and the charge generation layer is disconnected at the isolation portion.

16-18. (canceled)

19. The display substrate according to claim 1, wherein the light-emitting functional layer comprises at least one light-emitting layer, and at least one light-emitting layer and at least one other film layer are included in film layers of the light-emitting functional layer disconnected at the isolation portion;
an area of an orthographic projection of the at least one other film layer which is disconnected on the base substrate is greater than an area of an orthographic projection of the at least one light-emitting layer which is disconnected on the base substrate; or,
an area of a part, of the at least one other film layer which is disconnected, covering the isolation portion is greater than an area of a part, of the at least one light-emitting layer which is disconnected, covering the isolation portion.

20. The display substrate according to claim 1,
wherein the second electrode and at least one film layer among the plurality of film layers included in the light-emitting functional layer overlap in projection on the base substrate with the isolation portion; and/or,
the base substrate further comprises a second display region, and the first display region surrounds at least part of the second display region.

21-22. (canceled)

23. The display substrate according to claim 1, wherein a ratio of a thickness of the first sub-isolation portion to a thickness of the light-emitting functional layer is in a range of 0.7-1.5, the second electrode is continuous at the protrusion.

24-25. (canceled)

26. The display substrate according to claim 5, wherein a spacing structure is arranged between two protrusions which are close to each other, the spacing structure is spaced apart from the protrusions, and a material of the spacing structure is the same as a material of the second sub-isolation portion.

27. (canceled)

28. The display substrate according to claim 11, wherein the pixel defining pattern comprises a pixel defining portion located between the first opening and a second opening which are arranged adjacent to each other, one end of the pixel defining portion is configured to form the first opening, the other end of the pixel defining portion comprises the second sub-isolation portion, and an included angle between a sidewall of the pixel defining portion formed as a sidewall of the first opening and a plane parallel to the base substrate is different from an included angle between a sidewall of the second sub-isolation portion and the plane parallel to the base substrate.

29. A display device, comprising the display substrate according to claim 1.

30. A manufacturing method of a display substrate, comprising:
forming a plurality of sub-pixels on a base substrate, wherein forming the plurality of sub-pixels comprises sequentially forming a first electrode, a light-emitting functional layer and a second electrode which are stacked in a direction perpendicular to the base substrate;
forming an inorganic layer pattern by patterning on the base substrate;
forming an organic layer on the inorganic layer pattern, and patterning the organic layer to form an opening pattern;
etching the inorganic layer pattern to form a first sub-isolation portion, wherein an edge of the opening pattern comprises a second sub-isolation portion stacked with the first sub-isolation portion, an edge of the first sub-isolation portion extends outward relative to an edge of the second sub-isolation portion so that the second sub-isolation portion comprises a protrusion protruding relative to the edge of the first sub-isolation portion, and the protrusion is located between adjacent sub-pixels, or a slope angle between at least part of a side surface of the first sub-isolation portion and a plane parallel to a contact surface of the first sub-isolation portion and the second sub-isolation portion is greater than 60 degrees and less than 120 degrees, and/or a slope angle between at least part of a side surface of the second sub-isolation portion and the plane parallel to the contact surface of the first sub-isolation portion and the second sub-isolation portion is greater than 60 degrees and less than 120 degrees;
wherein the light-emitting functional layer is formed after the first sub-isolation portion is formed, the light-emitting functional layer comprises a plurality of film layers, and at least one film layer among the plurality of film layers is disconnected at the isolation portion.

31. The manufacturing method according to claim 30, wherein the inorganic layer pattern is located between adjacent sub-pixels, and the opening pattern which is formed exposes a part of the inorganic layer pattern, or an edge of the opening pattern which is formed is flush with an edge of the inorganic layer pattern; etching the inorganic layer pattern so that an edge of a retained part of the inorganic layer pattern extends outward relative to an edge of the opening pattern, wherein the retained part of the inorganic layer is the first sub-isolation portion; or
the inorganic layer pattern comprises the first electrode, and the opening pattern is located between adjacent sub-pixels; etching the inorganic layer pattern comprises: etching a part of the first electrode close to an edge of the opening pattern so that an edge of the first electrode extends outward relative to the edge of the opening pattern.

32. (canceled)
